(19) United States
(12) Patent Application Publication
(10) Pub. No.: US 2025/0391453 A1
(43) Pub. Date: Dec. 25, 2025

(54) STORAGE DEVICE AND PROCESSING DEVICE

(71) Applicant: SONY SEMICONDUCTOR SOLUTIONS CORPORATION, KANAGAWA (JP)

(72) Inventors: LUI SAKAI, KANAGAWA (JP); YUTAKA HIGO, KANAGAWA (JP); MASANORI HOSOMI, KANAGAWA (JP); KEIZO HIRAGA, KANAGAWA (JP)

(21) Appl. No.: 18/878,881

(22) PCT Filed: Apr. 18, 2023
(86) PCT No.: PCT/JP2023/015414

§ 371 Date: Dec. 25, 2024

(30) Foreign Application Priority Data
Jul. 11, 2022 (JP) 2022-110948

(51) Int. Cl. G11C 11/16

(52) U.S. Cl. CPC G11C 11/1655; G11C 11/1657

(57) ABSTRACT

A memory cell capable of reversing magnetization on the basis of voltage drive is achieved without providing a selector element in the memory cell. A storage device includes: a memory cell provided with a magnetoresistive effect element; a word line connected to one end of the magnetoresistive effect element; and a bit line connected to another end of the magnetoresistive effect element. The magnetoresistive effect element may have a voltage controlled magnetic anisotropy (VCMA) effect. A driver configured to apply a reversing voltage for reversing a magnetization direction of the magnetoresistive effect element on the basis of the VCMA effect may be included. The driver may switch a voltage applied to the memory cell such that a reversing voltage is applied to a selected cell while a non-reversing voltage is applied to a non-selected cell, in which the non-reversing voltage does not reverse a magnetization direction of the magnetoresistive effect element.

### TECHNICAL FIELD

The present technology relates to a storage device and a processing device. Specifically, the present technology relates to a storage device and a processing device provided with a voltage controlled magnetoresistive random access memory (VC-MRAM).

### BACKGROUND ART

As a method capable of reducing power consumption as compared with an MRAM using current drive for magnetization reversal of a magnetic tunnel junction (MTJ) element, there is a VC-MRAM using voltage drive for magnetization reversal of the MTJ element. As such a VC-MRAM, for example, a magnetic memory connected between a first wiring line and a second wiring line and including a selector element and a magnetoresistive effect element has been proposed. In this magnetic memory, a voltage for writing data to a memory cell includes a first voltage and a second voltage, a voltage value of the first voltage is lower than a voltage value of the second voltage, and an application period of the first voltage is longer than an application period of the second voltage (see, for example, Patent Document 1).

### CITATION LIST

### Patent Document

Patent Document 1: Japanese Patent Application Laid-Open No. 2019-21356

### SUMMARY OF THE INVENTION

### Problems to be Solved by the Invention

However, in the related art described above, in addition to the magnetoresistive effect element, the memory cell includes a selector element connected in series to the magnetoresistive effect element, for selecting the memory cell. For this reason, there has been a possibility that a configuration of the memory cell used for the VC-MRAM becomes complicated.

The present technology has been made in view of such a situation, and an object of the present technology is to achieve a memory cell capable of reversing magnetization on the basis of voltage drive without providing, in the memory cell, a selector element for selecting the memory cell.

### Solutions to Problems

The present technology has been made to solve the above-described problem, and a first aspect thereof is a storage device including a memory cell provided with a magnetoresistive effect element, a word line connected to one end of the magnetoresistive effect element, and a bit line connected to another end of the magnetoresistive effect element. As a result, an effect is provided that a selector element for selecting the memory cell is removed from the memory cell.

Furthermore, in the first aspect, the magnetoresistive effect element may have a voltage controlled magnetic anisotropy (VCMA) effect. As a result, an effect is provided that a memory cell using voltage drive for magnetization reversal is achieved. Furthermore, in the first aspect, the VCMA effect may be non-linear. As a result, an effect is provided that a reversal probability of a non-selected cell is reduced while a reversing voltage is applied to a selected cell.

Furthermore, in the first aspect, the VCMA effect may have a region having a smaller inclination at a point where a cell voltage applied to the magnetoresistive effect element is low than an inclination at a point where the cell voltage is high. As a result, an effect is provided that a reversal probability of a non-selected cell is reduced while a reversing voltage is applied to a selected cell.

Furthermore, in the first aspect, it is possible to further include a driver configured to apply a reversing voltage for reversing a magnetization direction of the magnetoresistive effect element on the basis of the VCMA effect. As a result, an effect is provided that data is written in the magnetoresistive effect element on the basis of the VCMA effect.

Furthermore, in the first aspect, the driver may switch a voltage applied to the memory cell such that a reversing voltage is applied to a selected cell while a non-reversing voltage is applied to a non-selected cell, in which the non-reversing voltage does not reverse a magnetization direction of the magnetoresistive effect element. As a result, an effect is provided that data is written to the selected cell on the basis of the VCMA effect.

Furthermore, in the first aspect, it is possible to further include: a resistance control circuit configured to control resistance between the word line and the bit line such that cell voltages applied to the magnetoresistive effect element are equal to each other between when the magnetoresistive effect element transitions from a high resistance state to a low resistance state and when the magnetoresistive effect element transitions from a low resistance state to a high resistance state. As a result, an effect is provided that data is written in the magnetoresistive effect element on the basis of the cell voltage applied to the magnetoresistive effect element.

Furthermore, in the first aspect, the resistance control circuit may include a field effect transistor whose ON-resistance changes on the basis of a gate voltage. As a result, an effect is provided that the cell voltages applied to the magnetoresistive effect element are mutually equal between when the magnetoresistive effect element transitions from a high resistance state to a low resistance state and when the magnetoresistive effect element transitions from a low resistance state to a high resistance state.

Furthermore, in the first aspect, the field effect transistor may be provided for each of the word line. As a result, an effect is provided that resistance of a selected word line connected with a selected cell is controlled.

Furthermore, in the first aspect, the field effect transistor may be provided for each of the bit line. As a result, an effect is provided that resistance of a selected bit line connected with a selected cell is controlled.

Furthermore, in the first aspect, it is possible to further include: a gate voltage switching unit configured to switch between a first gate voltage applied to the field effect transistor in a case where the magnetoresistive effect element is subjected to low-resistance writing and a second gate voltage applied to the field effect transistor in a case where the magnetoresistive effect element is subjected to high-resistance writing. As a result, an effect is provided that writing on the magnetoresistive effect element is performed on the basis of switching of the gate voltage.

Furthermore, in the first aspect, the driver may include: a word line driver configured to apply a word line voltage of X/(X+Y) (X and Y are values that do not cause reversal of a magnetization direction of the magnetoresistive effect element) of a write voltage applied between the word line and the bit line, to the word line connected to a selected cell; and a bit line driver configured to apply a bit line voltage having a polarity opposite to the word line voltage and being Y/(X+Y) of the write voltage, to the bit line connected to the selected cell. As a result, an effect is provided that a selected state of the memory cell is set on the basis of the word line voltage and the bit line voltage.

Furthermore, in the first aspect, the word line driver may apply a word line voltage of ½ of the write voltage to the word line connected to a selected cell, and the bit line driver may apply a bit line voltage having a polarity opposite to the word line voltage and being ½ of the write voltage, to the bit line connected to the selected cell. As a result, an effect is provided that a reversal probability of a non-selected cell based on the word line voltage and a reversal probability of a non-selected cell based on the bit line voltage are equalized.

Furthermore, in the first aspect, it is possible to further include: a control circuit configured to control an application timing of the word line voltage applied to the word line connected to the selected cell and an application timing of the bit line voltage applied to the bit line connected to the selected cell, to at least partially overlap with each other. As a result, an effect is provided that a reversing voltage is applied to a selected cell while the reversing voltage is not applied to a non-selected cell.

Furthermore, in the first aspect, in a case where the magnetoresistive effect element is subjected to low-resistance writing, the gate voltage switching unit may apply the first gate voltage to the field effect transistor, the word line driver may apply a word line voltage of ½ of the write voltage to the word line connected to the selected cell, and the bit line driver may apply a bit line voltage having a polarity opposite to the word line voltage and being ½ of the write voltage, to the bit line connected to the selected cell. As a result, an effect is provided that low-resistance writing on the magnetoresistive effect element is performed on the basis of voltage control.

Furthermore, in the first aspect, in a case where the magnetoresistive effect element is subjected to high-resistance writing, the gate voltage switching unit may apply the second gate voltage to the field effect transistor, the word line driver may apply a word line voltage of ½ of the write voltage to the word line connected to the selected cell, and the bit line driver may apply a bit line voltage having a polarity opposite to the word line voltage and being ½ of the write voltage, to the bit line connected to the selected cell. As a result, an effect is provided that high-resistance writing on the magnetoresistive effect element is performed on the basis of voltage control.

Furthermore, in the first aspect, it is possible to further include: a readout circuit configured to detect data stored in the selected cell on the basis of a current flowing through the bit line connected with the selected cell. As a result, an effect is provided that data is read from the selected cell.

Furthermore, in the first aspect, in a case of reading data from the selected cell, the gate voltage switching unit may apply the first gate voltage to the field effect transistor, the word line driver may apply a word line voltage of ½ of the write voltage to the word line connected to the selected cell, the bit line driver may apply a bit line voltage having a polarity opposite to the word line voltage and being ½ of the write voltage, to the bit line connected to the selected cell. The readout circuit may measure a change in a current flowing through the bit line connected with the selected cell, determine that data read from the selected cell is 0 in a case where the current flowing through the bit line does not change, and determine that data read from the selected cell is 1 in a case where the current flowing through the bit line increases. In a case where the data read from the selected cell is determined to be 1, the gate voltage switching unit may apply the second gate voltage to the field effect transistor, the word line driver may apply a word line voltage of ½ of the write voltage to the word line connected to the selected cell, and the bit line driver may apply a bit line voltage having a polarity opposite to the word line voltage and being ½ of the write voltage, to the bit line connected to the selected cell. As a result, an effect is provided that data is read from the selected cell on the basis of destructive reading and original data is written back to the selected cell subjected to destructive reading.

Furthermore, in the first aspect, it is possible to include a stacked structure of a memory cell array in which the memory cells are arranged in a matrix in a row direction and a column direction. As a result, an effect is provided that a storage capacity is increased while suppressing an increase in a plane size of the storage device.

Furthermore, in the first aspect, the word line and the bit line may be provided for every layer of the memory cell array. As a result, an effect is provided that writing can be performed for every layer of the memory cell array using the magnetoresistive effect element.

Furthermore, in the first aspect, the word line and the bit line may be alternately provided for every layer of the memory cell array. As a result, an effect is provided that writing can be performed for every layer of the memory cell array using the magnetoresistive effect element while an increase in the number of layers of word lines and bit lines is suppressed.

Furthermore, a second aspect is a processing device including: a memory cell in which a magnetoresistive effect element having a VCMA effect is provided, and a resistive state is transitioned on the basis of voltage application in which cell voltages are substantially equal in the resistance states different from each other; a word line connected to one end of the magnetoresistive effect element; a bit line connected to another end of the magnetoresistive effect element; and a processing unit configured to perform processing on the basis of a value stored in the memory cell. As a result, an effect is provided that processing can be performed on the basis of a value stored in the magnetoresistive effect element.

Furthermore, in the second aspect, the processing unit may include an analog to digital (AD) converter configured to convert, into a digital value, a current flowing through the bit line via a memory cell selected via the word line. As a result, an effect is provided that calculation can be performed on the basis of a value stored in the magnetoresistive effect element.

Furthermore, in the second aspect, the AD converter converts, into a digital value, a total value of a current flowing through the bit line via each of a plurality of layers of memory cells selected via the word line. As a result, an effect is provided that the AD conversion is performed while a value stored in the memory cell is multi-valued.

Furthermore, in the second aspect, each of the memory cells may store a weight between nodes of a neural network, and the memory cell array may perform multiplication and accumulation (MAC) on the basis of an input of the neural network and the weight. As a result, an effect is provided that MAC calculation can be performed on the basis of a value stored in the magnetoresistive effect element while the stored value at each cross point is multi-valued.

Furthermore, in the second aspect, it is possible to include a memory cell array in which the memory cells are arranged in a matrix in a row direction and a column direction, and the memory cell array may be stacked. As a result, consequently, an effect is provided that a value stored in the memory cell is multi-valued.

Furthermore, in the second aspect, the word line and the bit line may be provided for every layer of the memory cell array. As a result, an effect is provided that writing can be performed for every layer of the memory cell array used for MAC calculation.

Furthermore, in the second aspect, the word line and the bit line may be alternately provided for every layer of the memory cell array. As a result, an effect is provided that writing can be performed for every layer of the memory cell array used for MAC calculation while an increase in the number of layers of word lines and bit lines is suppressed.

### BRIEF DESCRIPTION OF DRAWINGS

FIG. 1 is a diagram illustrating a configuration example of a storage device according to a first embodiment.

FIG. 2 is a diagram illustrating a relationship between a voltage and a perpendicular magnetic anisotropy of the storage device according to the first embodiment.

FIG. 3 is a diagram illustrating writing characteristics based on a perpendicular magnetic anisotropy of the storage device according to the first embodiment.

FIG. 4 is a block diagram illustrating an overall configuration example of the storage device according to the first embodiment.

FIG. 5 is a diagram illustrating a selection example of a memory cell at a time of low-resistance writing in the storage device according to the first embodiment.

FIG. 6 is a diagram illustrating voltage waveforms of individual units at a time of low-resistance writing in the storage device according to the first embodiment.

FIG. 7 is a diagram illustrating a selection example of a memory cell at a time of high-resistance writing in the storage device according to the first embodiment.

FIG. 8 is a diagram illustrating voltage waveforms of individual units at a time of high-resistance writing in the storage device according to the first embodiment.

FIG. 9 is a timing chart illustrating a write timing of the storage device according to the first embodiment.

FIG. 10 is a flowchart illustrating a writing method of the storage device according to the first embodiment.

FIG. 11 is a diagram illustrating a selection example of a memory cell at a time of reading of the storage device according to the first embodiment.

FIG. 12 is a diagram illustrating voltage waveforms of individual units at a time of reading of the storage device according to the first embodiment.

FIG. 13 is a timing chart illustrating a readout timing in a low resistance state of the storage device according to the first embodiment.

FIG. 14 is a timing chart illustrating a readout timing in a high resistance state of the storage device according to the first embodiment.

FIG. 15 is a flowchart illustrating a readout method of the storage device according to the first embodiment.

FIG. 16 is a diagram illustrating a modification of voltage waveforms of individual units at a time of low-resistance writing in the storage device according to the first embodiment.

FIG. 17 is a diagram illustrating a modification of voltage waveforms of individual units at a time of high-resistance writing in the storage device according to the first embodiment.

FIG. 18 is a diagram illustrating a configuration example of a storage device according to a second embodiment.

FIG. 19 is a diagram illustrating a selection example of a memory cell at a time of low-resistance writing in the storage device according to the second embodiment.

FIG. 20 is a diagram illustrating voltage waveforms of individual units at a time of low-resistance writing in the storage device according to the second embodiment.

FIG. 21 is a diagram illustrating a selection example of a memory cell at a time of high-resistance writing in the storage device according to the second embodiment.

FIG. 22 is a diagram illustrating voltage waveforms of individual units at a time of high-resistance writing in the storage device according to the second embodiment.

FIG. 23 is a diagram illustrating a selection example of a memory cell at a time of reading of the storage device according to the second embodiment.

FIG. 24 is a diagram illustrating voltage waveforms of individual units at a time of reading of the storage device according to the second embodiment.

FIG. 25 is a timing chart illustrating a low-resistance write timing of a storage device according to a third embodiment.

FIG. 26 is a timing chart illustrating a high-resistance write timing of the storage device according to the third embodiment.

FIG. 27 is a timing chart illustrating a modification of the high-resistance write timing of the storage device according to the third embodiment.

FIG. 28 is a flowchart illustrating a writing method of the storage device according to the third embodiment.

FIG. 29 is a diagram illustrating a configuration example of a processing device according to a fourth embodiment.

FIG. 30 is a block diagram illustrating a first example of an overall configuration of the processing device according to the fourth embodiment.

FIG. 31 is a block diagram illustrating a second example of an overall configuration of the processing device according to the fourth embodiment.

FIG. 32 is a cross-sectional view illustrating a first configuration example of a magnetoresistive effect element according to the fourth embodiment.

FIG. 33 is a cross-sectional view illustrating a second configuration example of the magnetoresistive effect element according to the fourth embodiment.

FIG. 34 is a diagram illustrating an input/output example of a signal of the processing device according to the fourth embodiment.

FIG. 35 is a diagram illustrating an example of input/output data and voltage waveforms of individual units at a time of MAC calculation of the processing device according to the fourth embodiment.

FIG. 36 is a flowchart illustrating an example of a MAC calculation method of the processing device according to the fourth embodiment.

FIG. 37 is a timing chart illustrating a MAC calculation timing of the processing device according to the fourth embodiment.

FIG. 38 is a perspective view illustrating an example of a memory cell array according to the fourth embodiment.

FIG. 39 is a diagram illustrating a configuration example of a processing device according to a fifth embodiment.

FIG. 40 is a perspective view illustrating an example of a memory cell array according to a sixth embodiment.

FIG. 41 is a perspective view illustrating an example of a memory cell array according to a seventh embodiment.

FIG. 42 is a perspective view illustrating an example of a memory cell array according to an eighth embodiment.

FIG. 43 is a perspective view illustrating an example of a memory cell array according to a ninth embodiment.

FIG. 44 is a perspective view illustrating an example of a memory cell array according to a tenth embodiment.

FIG. 45 is a perspective view illustrating an example of a memory cell array according to an eleventh embodiment.

FIG. 46 is a perspective view illustrating an example of a memory cell array according to a twelfth embodiment.

FIG. 47 is a diagram illustrating an example of a neural network to which a processing device according to a thirteenth embodiment is applied.

FIG. 48 is a block diagram illustrating an example of a schematic configuration of an imaging device.

FIG. 49 is a block diagram illustrating an example of a schematic configuration of a distance measuring device.

FIG. 50 is a perspective view illustrating an example of an external configuration of a game device.

FIG. 51 is a block diagram illustrating an example of a schematic configuration of the game device.

### MODE FOR CARRYING OUT THE INVENTION

Modes for carrying out the present technology (hereinafter, referred to as embodiments) will be described below. The description will be given in the following order.
1. First embodiment (an example of performing writing on a magnetoresistive effect element on the basis of a divided voltage of a write voltage on a word line side, in the magnetoresistive effect element having one end connected to the word line and another end connected to a bit line)
2. Second embodiment (an example of performing writing on a magnetoresistive effect element on the basis of a divided voltage of a write voltage on a bit line side, in the magnetoresistive effect element having one end connected to a word line and another end connected to the bit line)
3. Third embodiment (an example of performing high-resistance writing after initializing a resistance state of a magnetoresistive effect element)
4. Fourth embodiment (an example in which a memory cell in which writing is performed on a magnetoresistive effect element on the basis of a divided voltage of a write voltage on a word line side is applied to MAC calculation)
5. Fifth embodiment (an example in which a memory cell in which writing is performed on a magnetoresistive effect element on the basis of a divided voltage of a write voltage on a bit line side is applied to MAC calculation)
6. Sixth embodiment (an example in which a word line and a bit line are alternately provided for every layer of a two-layer structure of a memory cell array to be applied to MAC calculation)
7. Seventh embodiment (an example in which a word line and a bit line are alternately provided for every layer of a three-layer structure of a memory cell array to be applied to MAC calculation)
8. Eighth embodiment (an example in which a word line and a bit line are provided for every layer of a three-layer structure of a memory cell array to be applied to MAC calculation)
9. Ninth embodiment (an example in which a word line and a bit line are alternately provided for every layer of a four-layer structure of a memory cell array to be applied to MAC calculation)
10. Tenth embodiment (an example in which a word line and a bit line are provided for every layer of a four-layer structure of a memory cell array to be applied to MAC calculation)
11. Eleventh embodiment (an example in which a word line and a bit line are alternately provided for every layer of a six-layer structure of a memory cell array to be applied to MAC calculation)
12. Twelfth embodiment (an example in which a word line and a bit line are provided for every layer of a six-layer structure of a memory cell array to be applied to MAC calculation)
13. Thirteenth embodiment (an example in which a memory cell provided with a magnetoresistive effect element having a VCMA effect is applied to MAC calculation of a neural network)
14. First application example (imaging device)
15. Second application example (distance measuring device)
16. Third application example (game device)

### 1. First Embodiment

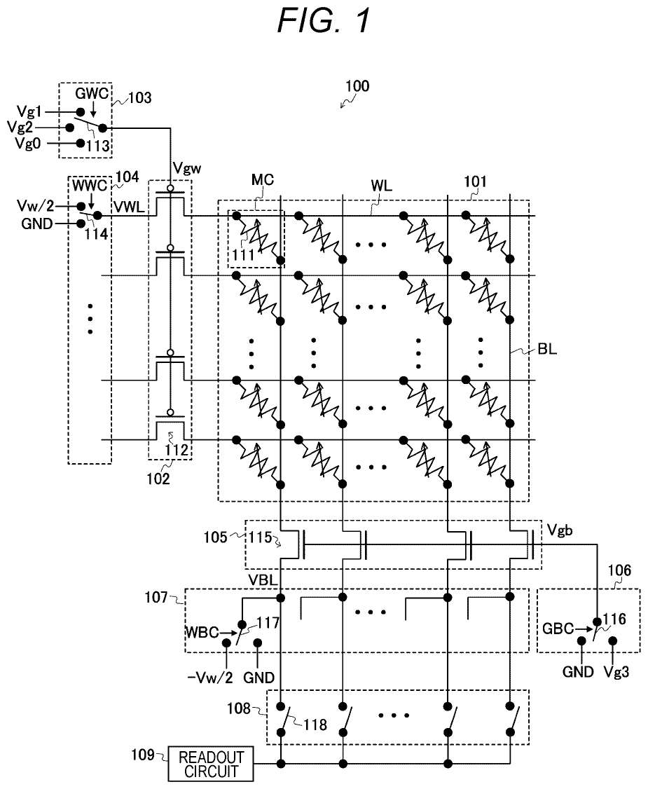

FIG. 1 is a diagram illustrating a configuration example of a storage device according to a first embodiment.

In this figure, a storage device 100 can operate as a VC-MRAM. The storage device 100 includes a memory cell array 101, a word line resistance control circuit 102, gate voltage switching units 103 and 106, and a word line driver 104. Furthermore, the storage device 100 includes a bit line conduction circuit 105, a bit line driver 107, a column selector 108, and a readout circuit 109.

In the memory cell array 101, memory cells MC are arranged in a matrix in a row direction and a column direction. In the row direction, a word line WL is wired for every row. In the column direction, a bit line BL is wired for every column.

The memory cell MC stores data on the basis of a magnetoresistive effect. The memory cell MC includes a magnetoresistive effect element 111. The word line WL is connected to one end of the magnetoresistive effect element 111, and the bit line BL is connected to another end of the magnetoresistive effect element 111. The magnetoresistive effect element 111 has a voltage controlled magnetic anisotropy (VCMA) effect. The VCMA effect of the magnetoresistive effect element 111 may be non-linear. Here, resistance state of the magnetoresistive effect element 111 can take a low resistance state and a high resistance state. At this time, the magnetoresistive effect element 111 can transition between the low resistance state and the high resistance state by reversing a magnetization direction on the basis of the VCMA effect.

The word line resistance control circuit 102 controls resistance of the word line WL such that cell voltage applied to the magnetoresistive effect element 111 are mutually equal between when the magnetoresistive effect element transitions from the high resistance state to the low resistance state and when the magnetoresistive effect element 111 transitions from the low resistance state to the high resistance state. The cell voltage at this time is equal to a reversing voltage. The reversing voltage is a voltage that reverses a magnetization direction of the magnetoresistive effect element 111 on the basis of the VCMA effect. When the magnetoresistive effect element 111 transitions from the high resistance state to the low resistance state, and when the magnetoresistive effect element transitions from the low resistance state to the high resistance state, the reversing voltages are equal to each other. When the reversing voltage is applied to the magnetoresistive effect element 111, a perpendicular magnetic anisotropy of the magnetoresistive effect element 111 becomes 0. The word line resistance control circuit 102 is disposed between the memory cell array 101 and the word line driver 104.

The word line resistance control circuit 102 includes a PMOS transistor 112. The PMOS transistor 112 is provided for every word line WL. ON-resistance of each PMOS transistor 112 changes on the basis of a gate voltage Vgw. The word line resistance control circuit 102 is an example of a resistance control circuit described in the claims.

The gate voltage switching unit 103 switches the gate voltage Vgw between voltages Vg0, Vg1, and Vg2. The voltage Vg0 is set such that each PMOS transistor 112 is turned off. The voltage Vg1 is set such that a cell voltage applied to the magnetoresistive effect element 111 is equal to a reversing voltage in a case where the magnetoresistive effect element 111 is subjected to high-resistance writing. The voltage Vg2 is set such that a cell voltage applied to the magnetoresistive effect element 111 is equal to a reversing voltage in a case where the magnetoresistive effect element 111 is subjected to low-resistance writing.

The gate voltage switching unit 103 includes a resistance state control switch 113. The resistance state control switch 113 switches between the voltages Vg0, Vg1, and Vg2 on the basis of a switching signal GWC. At this time, the switching signal GWC can cause the resistance state control switch 113 to select the voltage Vg0 at a time of non-writing and non-reading. The switching signal GWC can cause the resistance state control switch 113 to select the voltage Vg1 at a time of high-resistance writing and select the voltage Vg2 at a time of low-resistance writing. The resistance state control switch 113 may include a MOS transistor.

The word line driver 104 drives the word line WL so that a reversing voltage can be applied to the magnetoresistive effect element 111 of a selected cell. Here, the word line driver 104 can apply a word line voltage VWL to the word line WL. At this time, the word line driver 104 can switch the word line voltage VWL between voltages Vw/2 and GND. The voltage Vw/2 is ½ of a write voltage Vw. GND is a ground voltage. The write voltage Vw is set such that a reversing voltage is applied to the magnetoresistive effect element 111 of a selected cell while a non-reversing voltage is applied to the magnetoresistive effect element 111 of a non-selected cell. The non-reversing voltage is a voltage that does not reverse the magnetization direction of the magnetoresistive effect element 111.

The word line driver 104 includes a voltage selector switch 114. The voltage selector switch 114 switches between the voltage Vw/2 and GND on the basis of a switching signal WWC. At this time, the switching signal WWC can cause the voltage selector switch 114 to select the voltage Vw/2 for a selected word line and select the voltage GND for a non-selected word line. The voltage selector switch 114 may include a MOS transistor. The word line driver 104 is an example of a driver described in the claims.

The bit line conduction circuit 105 switches a conduction state between the memory cell array 101 and the bit line driver 107 via the bit line BL. The bit line conduction circuit 105 is disposed between the memory cell array 101 and the bit line driver 107.

The bit line conduction circuit 105 includes an NMOS transistor 115. The NMOS transistor 115 is provided for every bit line BL. Each NMOS transistor 115 switches between on and off on the basis of a gate voltage Vgb.

The gate voltage switching unit 106 switches the gate voltage Vgb between voltages Vg3 and GND. The voltage Vg3 is set such that each NMOS transistor 115 is turned on.

The gate voltage switching unit 106 includes a conduction state control switch 116. The conduction state control switch 116 switches between the voltages Vg3 and GND on the basis of a switching signal GBC. At this time, the switching signal GBC can cause the conduction state control switch 116 to select the voltage GND at a time of non-writing and non-reading, and select the voltage Vg3 at a time of writing or reading. The conduction state control switch 116 may include a MOS transistor.

The bit line driver 107 drives the bit line BL such that a reversing voltage can be applied to the magnetoresistive effect element 111 of a selected cell. Here, the bit line driver 107 can apply a bit line voltage VBL to the bit line BL. At this time, the bit line driver 107 can switch the bit line voltage VBL between voltages −Vw/2 and GND. The voltage −Vw/2 is a voltage of −½ of the write voltage Vw. The bit line voltage VBL has a polarity opposite to that of the word line voltage VWL.

The bit line driver 107 includes a voltage selector switch 117. The voltage selector switch 117 switches between the voltages −Vw/2 and GND on the basis of a switching signal WBC. At this time, the switching signal WBC can cause the voltage selector switch 117 to select the voltage −Vw/2 for a selected bit line and select the voltage GND for a non-selected bit line. The voltage selector switch 117 may include a MOS transistor.

The column selector 108 selects a column. The column selector 108 includes a column switch 118. The column switch 118 is provided for every bit line BL. At this time, the column switch 118 can connect a selected bit line to the readout circuit 109 and disconnect a non-selected bit line from the readout circuit 109.

The readout circuit 109 reads data stored in the memory cell MC. At this time, the readout circuit 109 can read data from a selected cell by determining whether or not a current flowing through a selected bit line connected to the selected cell changes when writing to the selected cell is performed. Data reading at this time is destructive reading. Therefore, when data is destructed by reading from the selected cell, original data is written back to the selected cell.

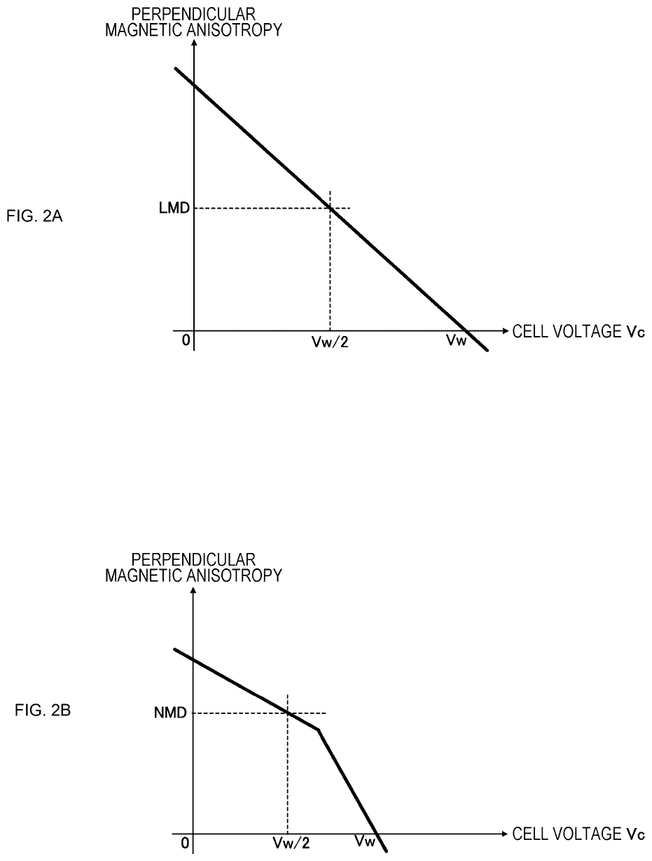

FIG. 2 is a diagram illustrating a relationship between a voltage and a perpendicular magnetic anisotropy of the storage device according to the first embodiment. Note that, “a” of this figure illustrates a linear relationship between a cell voltage Vc applied to the magnetoresistive effect element 111 and the perpendicular magnetic anisotropy. In this figure, “b” illustrates a non-linear relationship between the cell voltage Vc applied to the magnetoresistive effect element 111 and the perpendicular magnetic anisotropy.

In “a” of this figure, in a case where the perpendicular magnetic anisotropy has linearity, the perpendicular magnetic anisotropy decreases linearly with an increase in the cell voltage Vc applied to the magnetoresistive effect element 111. Here, in the memory cell array 101 of FIG. 1, the write voltage Vw is assumed to be applied to a selected cell connected to a selected word line and a selected bit line. At this time, the voltage Vw/2 may be applied to a non-selected cell connected to the selected word line and a non-selected bit line, and the voltage Vw/2 may also be applied to a non-selected cell connected to a non-selected word line and the selected bit line. Therefore, the magnetoresistive effect element 111 needs to have a perpendicular magnetic anisotropy LMD such that magnetization reversal does not occur when the voltage Vw/2 is applied to the magnetoresistive effect element 111.

In “b” of this figure, in a case where the perpendicular magnetic anisotropy has nonlinearity, there is a region where an inclination is small at a point where the cell voltage Vc applied to the magnetoresistive effect element 111 is low as compared with a point where the cell voltage Vc is high. In the case where the perpendicular magnetic anisotropy has nonlinearity, the perpendicular magnetic anisotropy when the cell voltage Vc is Vw/2 can be increased as compared with the case where the perpendicular magnetic anisotropy has linearity. Therefore, when the voltage Vw/2 is applied to the magnetoresistive effect element 111, the magnetoresistive effect element 111 can have a larger perpendicular magnetic anisotropy NMD than the perpendicular magnetic anisotropy LMD of the case where the perpendicular magnetic anisotropy has linearity.

Note that, the magnetoresistive effect element 111 can have a structure in which a tunnel barrier layer is sandwiched between a pin layer and a free layer.

The pin layer is a layer having a magnetic anisotropy and an invariable magnetization direction. The pin layer can be made containing, for example, CoFeB, a CoFeC alloy, a NiFeB alloy, a NiFeC alloy, or the like. Furthermore, the pin layer may have a stacked ferri-pin structure in which a plurality of ferromagnetic layers is stacked with a nonmagnetic layer interposed therebetween. As a material of the ferromagnetic layer constituting a magnetization fixed layer having the stacked ferri-pin structure, Co, CoFe, CoFeB, or the like can be used. Furthermore, as a material of the nonmagnetic layer, Ru, Re, Ir, Os, or the like can be used.

The pin layer can have a configuration in which a magnetization direction is fixed by using antiferromagnetic coupling between an antiferromagnetic layer and a ferromagnetic layer. Examples of a material of the antiferromagnetic layer include magnetic materials such as FeMn alloy, PtMn alloy, PtCrMn alloy, NiMn alloy, IrMn alloy, Nio, and Fe₂O₃. Furthermore, a nonmagnetic element such as Ag, Cu, Au, Al, Si, Bi, Ta, B, C, O, N, Pd, Pt, Zr, Hf, Ir, W, Mo, or Nb can be added to these magnetic bodies.

The tunnel barrier layer applies an electric field to the free layer to impart a voltage control magnetic anisotropy effect. The tunnel barrier layer can be made containing an oxide of at least one element selected from the group of Mg, Al, Ti, Si, Zn, Zr, Hf, Ta, Bi, Cr, Ga, La, Gd, Sr, and Ba, or a nitride of at least one element selected from the group of Mg, Al, Ti, Si, Zn, Zr, Hf, Ta, Bi, Cr, Ga, La, Gd, Sr, and Ba. Furthermore, an insulator, a dielectric, or a semiconductor such as MgF₂, CaF, SrTiO₂, AlLaO₃, or AlNO may be used. These layers may be stacked. Note that a thickness of the tunnel barrier layer is preferably 0.6 nm or more. In order to impart nonlinearity to the perpendicular magnetic anisotropy, a V/Fe/MgO(001)/Fe epitaxial magnetic tunnel junction may be provided.

The free layer is a layer having a magnetic anisotropy and a variable magnetization direction. Furthermore, the free layer is a layer having the VCMA effect. A state in which a magnetization direction of the free layer is the same as a magnetization direction of the pin layer is referred to as a parallel state, while a state in which the magnetization direction of the free layer is different from the magnetization direction of the pin layer is referred to as an antiparallel state. The magnetoresistive effect element 111 is in the low resistance state in the parallel state, and is in the high resistance state in the antiparallel state. The magnetization direction of the free layer can be changed on the basis of voltage application to the magnetoresistive effect element 111.

Furthermore, the free layer can be made containing cobalt iron (CoFe), cobalt iron boron (CoFeB), Fe, iron boride (FeB), or the like. Furthermore, the free layer may contain a transition metal (Hf, Ta, VWe, Ir, Pt, Au, Zr, Nb, Mo, Ru, Rh, Pd, Ag, Ti, V, Cr, Mn, Ni, Cu) or the like. Furthermore, the free layer may contain a nitride or an oxide. Furthermore, iridium (Ir) or osmium (Os) can be used as a material that induces a proximity magnetic moment to a magnetic body. Note that, a heavy metal may be added to the free layer to improve the voltage control magnetic anisotropy effect. In order to cause the magnetoresistive effect element 111 to have the VCMA effect, a thickness of the free layer is preferably 3.0 nm or less.

Furthermore, the free layer may have a stacked structure in which a plurality of ferromagnetic layers is stacked with a nonmagnetic layer interposed therebetween. At this time, two ferromagnetic layers adjacent to each other with the nonmagnetic layer interposed therebetween may be subjected to exchange coupling. The nonmagnetic layer can be made containing Mg, Al, Ti, Si, Zn, Zr, Hf, Ta, Bi, Cr, Ga, La, Gd, Sr, Ba, VWe, Ir, Pt, Au, Nb, Mo, Ru, Rh, Pd, Ag, V, Mn, Ni, Cu, or the like.

The formation of the pin layer, the tunnel barrier layer, and the free layer may be performed by a physical vapor deposition (PVD) method such as a sputtering method, an ion beam deposition method, or a vacuum deposition method, an atomic layer deposition (ALD) method, or a chemical vapor deposition (CVD) method. Furthermore, a reactive ion etching (RIE) method or an ion milling method may be used for patterning the pin layer, the tunnel barrier layer, and the free layer.

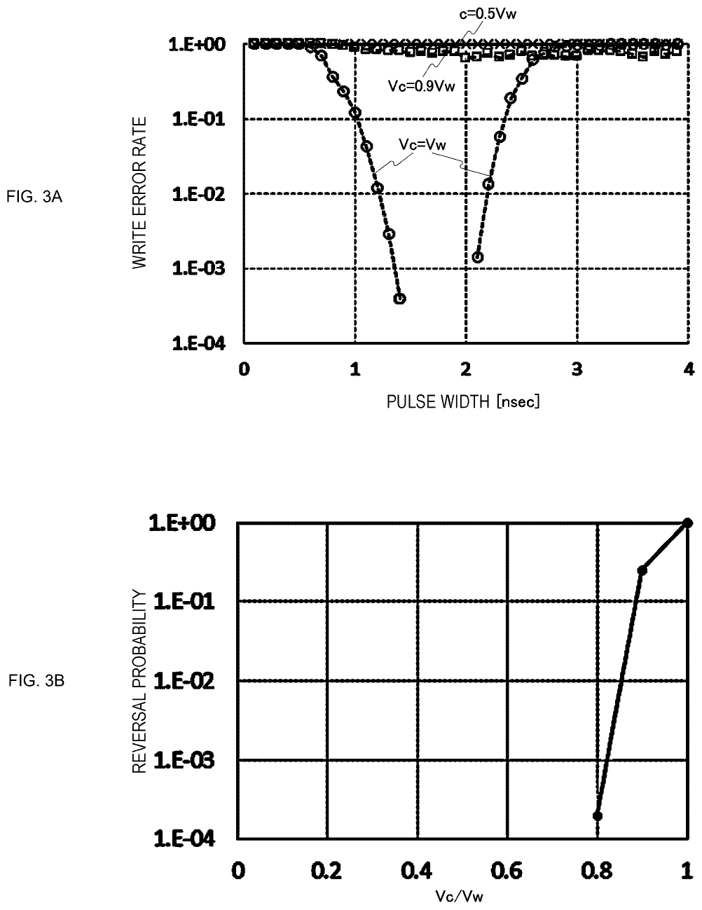

FIG. 3 is a diagram illustrating writing characteristics based on a perpendicular magnetic anisotropy of the storage device according to the first embodiment. Note that “a” of this figure illustrates a relationship between a pulse width of the cell voltage Vc and a write error rate. In this figure, “b” illustrates a relationship between a ratio of the cell voltage Vc to the write voltage Vw and a reversal probability.

In “a” of this figure, in a case where the cell voltage Vc is equal to the write voltage Vw, a pulse width of the write voltage Vw can be set such that the write error rate approaches 0. For example, by setting the pulse width of the write voltage Vw within a range of 1.5 to 2 nsec, the write error rate can be made substantially 0. Whereas, in a case where the cell voltage Vc is 0.5 Vw or 0.9 Vw, the write error rate cannot approach 0 regardless of how the pulse width of the write voltage Vw is set.

In “b” of this figure, in a case where the cell voltage Vc is equal to the write voltage Vw, the reversal probability becomes 1, and writing can be successfully performed. When the cell voltage Vc decreases, the reversal probability rapidly decreases, and the reversal probability becomes almost 0 when the cell voltage Vc becomes smaller than 0.8 Vw. Therefore, even if the cell voltage Vc smaller than 0.8 Vw is applied to a non-selected cell, writing is not performed on a non-selected cell.

At this time, in order to apply the write voltage Vw to a selected cell while preventing writing on a non-selected cell, Vw/2 may be applied to a selected word line and −Vw/2 may be applied to a selected bit line, but the present disclosure is not necessarily limited to this method. For example, X/(X+Y) (X and Y are values that do not cause reversal of the magnetization direction of the magnetoresistive effect element 111) of the write voltage Vw may be applied to the selected word line, and −Y/(X+Y) of the write voltage Vw may be applied to the selected bit line.

Furthermore, a polarity of a voltage applied to the selected word line may be positive while a polarity of a voltage applied to the selected bit line may be negative, or the polarity of the voltage applied to the selected word line may be negative while the polarity of the voltage applied to the selected bit line may be positive. For example, −Vw/2 may be applied to the selected word line, and Vw/2 may be applied to the selected bit line.

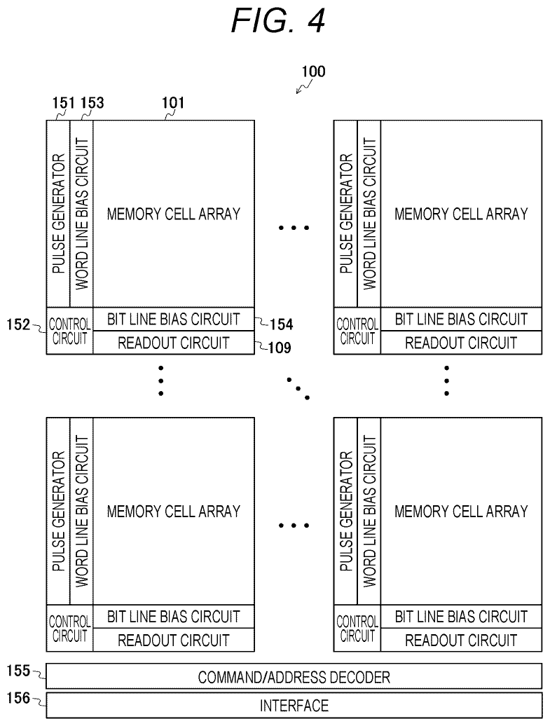

FIG. 4 is a block diagram illustrating an overall configuration example of the storage device according to the first embodiment.

In this figure, the storage device 100 includes a plurality of memory cell arrays 101. The memory cell arrays 101 may be arranged in a matrix in a row direction and a column direction. Each memory cell array 101 is provided with a word line bias circuit 153, a bit line bias circuit 154, the readout circuit 109, a pulse generator 151, and a control circuit 152. Furthermore, the storage device 100 includes a command/address decoder 155 and an interface 156.

The word line bias circuit 153 includes the word line resistance control circuit 102 and the word line driver 104 of FIG. 1. The bit line bias circuit 154 includes the bit line conduction circuit 105 and the bit line driver 107 in FIG. 1.

The pulse generator 151 generates voltages Vw/2, −Vw/2, Vg1, Vg2, and Vg3 in a pulsed manner at a time of writing or reading. Then, the pulse generator 151 supplies the voltage Vw/2 to the word line driver 104, supplies the voltage −Vw/2 to the bit line driver 107, supplies the voltages Vg1 and Vg2 to the gate voltage switching unit 103, and supplies the voltage Vg3 to the gate voltage switching unit 106.

The control circuit 152 performs writing and reading between with each memory cell array 101 on the basis of an instruction from the command/address decoder 155. At this time, the control circuit 152 supplies the switching signal WWC to the word line driver 104, supplies the switching signal WBC to the bit line driver 107, supplies the switching signal GWC to the gate voltage switching unit 103, and supplies the switching signal GBC to the gate voltage switching unit 106.

The command/address decoder 155 analyzes a write command and a read command transmitted from an outside, and designates a write position or a read position on the basis of an address at which writing or reading is performed.

The interface 156 receives a write command, a read command, and write data from an outside, and transmits read data to the outside. The storage device 100 can be connected to a host via the interface 156.

Here, by providing a plurality of memory cell arrays 101 in the storage device 100, it is possible to simultaneously write a plurality of bits to the storage device 100 and simultaneously read a plurality of bits from the storage device 100.

Note that, in the storage device 100, the memory cell array 101 may have a one-layer structure or a stacked structure of a plurality of layers.

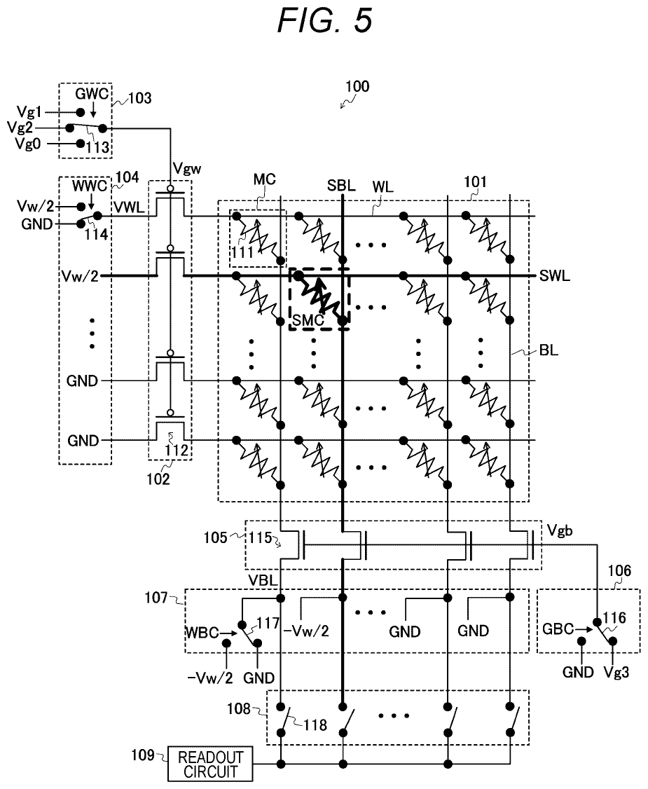

FIG. 5 is a diagram illustrating a selection example of a memory cell at a time of low-resistance writing in the storage device according to the first embodiment.

In this figure, it is assumed that a selected cell SMC has been designated at the time of low-resistance writing. One end of the selected cell SMC is connected to a selected word line SWL, and another end of the selected cell SMC is connected to a selected bit line SBL. At this time, the word line voltage VWL of the selected word line SWL is set to Vw/2, and the bit line voltage VBL of the selected bit line SBL is set to −Vw/2. The gate voltage Vgb of each NMOS transistor 115 is set to the voltage Vg3. At this time, each NMOS transistor 115 is turned on.

The gate voltage Vgw of each PMOS transistor 112 is set to the voltage Vg2. At this time, the write voltage Vw is divided into a voltage to be applied to the ON-resistance of the PMOS transistor 112 connected to the selected word line SWL and the cell voltage Vc to be applied to the selected cell SMC. Then, the gate voltage Vgw is set such that the cell voltage Vc applied to the selected cell SMC in the high resistance state coincides with a reversing voltage when the write voltage Vw is divided at the ON-resistance of the PMOS transistor 112.

Here, in a case where the selected cell SMC is in the high resistance state at the time of low-resistance writing, since the reversing voltage is applied to the selected cell SMC, the selected cell SMC transitions from the high resistance state to the low resistance state. Whereas, in a case where the selected cell SMC is in the low resistance state at the time of low-resistance writing, a voltage dividing ratio of the write voltage Vw to the ON-resistance of the PMOS transistor 112 increases as compared with the case where the selected cell SMC is in the high resistance state. Therefore, the cell voltage Vc applied to the selected cell SMC becomes smaller than the reversing voltage, and the low resistance state of the selected cell SMC is maintained due to the perpendicular magnetic anisotropy of the selected cell SMC.

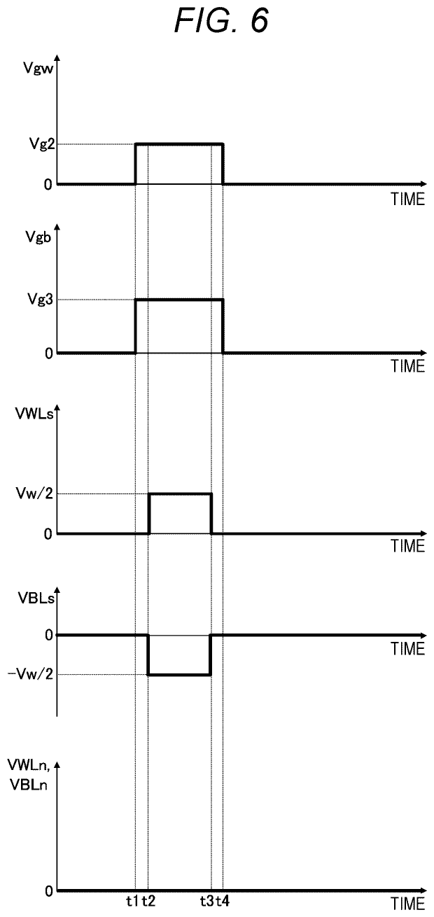

FIG. 6 is a diagram illustrating voltage waveforms of individual units at the time of low-resistance writing in the storage device according to the first embodiment. Note that, VWLs represents a word line voltage of the selected word line SWL, VWLn represents a word line voltage of a non-selected word line, VBLs represents a bit line voltage of the selected bit line SBL, and VBLn represents a bit line voltage of a non-selected bit line.

In this figure, at the time of low-resistance writing, the word line voltage VWLn of a non-selected word line and the bit line voltage VBLn of a non-selected bit line are set to 0. Then, the gate voltage Vgw of the PMOS transistor 112 is set to the voltage Vg2, and the gate voltage Vgb of the NMOS transistor 115 is set to the voltage Vg3 (t1). At this time, the ON-resistance of the PMOS transistor 112 is set such that the cell voltage Vc applied to the selected cell SMC in the high resistance state coincides with the reversing voltage when the write voltage Vw is divided between the ON-resistance and the selected cell SMC in the high resistance state. Furthermore, the NMOS transistor 115 is turned on, and the memory cell array 101 and the bit line driver 107 are conducted via the bit line BL.

Next, the word line voltage VWLs of the selected word line SWL is set to Vw/2, and the bit line voltage VBLs of the selected bit line SBL is set to −Vw/2 (t2). Here, the write voltage Vw supplied via the selected word line SWL and the selected bit line SBL is divided into a voltage to be applied to the ON-resistance of the PMOS transistor 112 connected to the selected word line SWL and the cell voltage Vc to be applied to the selected cell SMC. At this time, the cell voltage Vc applied to the selected cell SMC in the high resistance state coincides with the reversing voltage, and the selected cell SMC transitions from the high resistance state to the low resistance state.

Next, the word line voltage VWLs of the selected word line SWL is set to 0, and the bit line voltage VBLs of the selected bit line SBL is set to 0 (t3). Note that, pulse widths of the word line voltage VWLs and the bit line voltage VBLs are set such that the write error rate becomes 0 as illustrated in “a” of FIG. 3.

Next, the gate voltage Vgw of the PMOS transistor 112 is set to 0, and the gate voltage Vgb of the NMOS transistor 115 is set to 0 (t4).

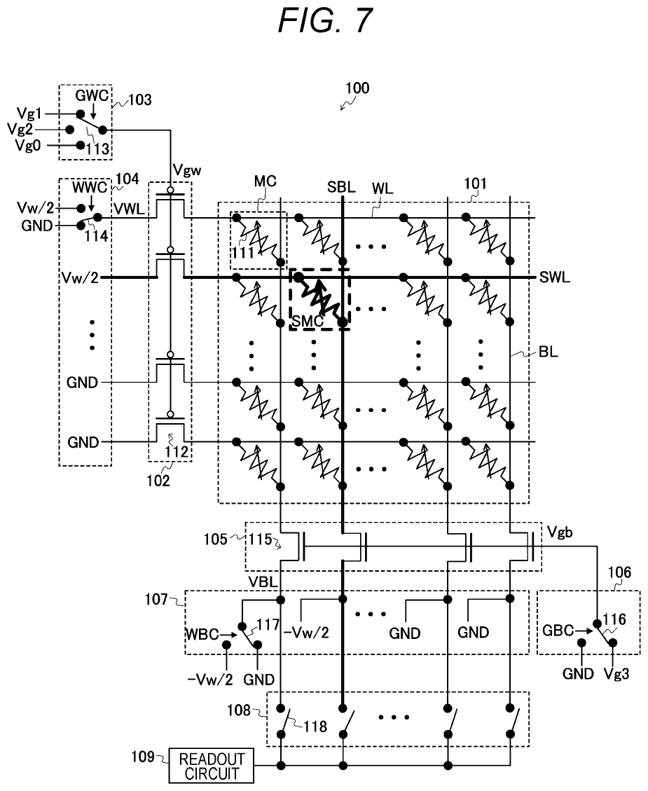

FIG. 7 is a diagram illustrating a selection example of a memory cell at a time of high-resistance writing in the storage device according to the first embodiment.

In this figure, it is assumed that the selected cell SMC has been designated at the time of high-resistance writing. At this time, the word line voltage VWL of the selected word line SWL is set to Vw/2, and the bit line voltage VBL of the selected bit line SBL is set to −Vw/2. The gate voltage Vgb of each NMOS transistor 115 is set to the voltage Vg3. At this time, each NMOS transistor 115 is turned on.

The gate voltage Vgw of each PMOS transistor 112 is set to the voltage Vg1. At this time, the write voltage Vw is divided into a voltage to be applied to the ON-resistance of the PMOS transistor 112 connected to the selected word line SWL and the cell voltage Vc to be applied to the selected cell SMC. Then, the gate voltage Vgw is set such that the cell voltage Vc applied to the selected cell SMC in the low resistance state coincides with a reversing voltage when the write voltage Vw is divided at the ON-resistance of the PMOS transistor 112.

Here, in a case where the selected cell SMC is in the low resistance state, a divided voltage ratio when the write voltage Vw is divided by the selected cell SMC decreases as compared with the case where the selected cell SMC is in the high resistance state. Therefore, in order to equalize the reversing voltage between when the selected cell SMC is in the low resistance state and when the selected cell SMC is in the high resistance state, in a case where the selected cell SMC is in the low resistance state, the ON-resistance of the PMOS transistor 112 is reduced as compared with the case where the selected cell SMC is in the high resistance state. In order to reduce the ON-resistance of the PMOS transistor 112, the gate voltage Vgw of the PMOS transistor 112 is reduced.

Here, in a case where the selected cell SMC is in the low resistance state at the time of high-resistance writing, since the reversing voltage is applied to the selected cell SMC, the selected cell SMC transitions from the low resistance state to the high resistance state. Whereas, in a case where the selected cell SMC is in the high resistance state at the time of high-resistance writing, a voltage dividing ratio of the write voltage Vw to the ON-resistance of the PMOS transistor 112 decreases as compared with the case where the selected cell SMC is in the low resistance state. For this reason, the cell voltage Vc applied to the selected cell SMC becomes larger than the reversing voltage, and an in-plane rotation component appears due to an in-plane magnetic anisotropy of the selected cell SMC. However, this rotation component does not contribute to reversing of the magnetization direction, so that the high resistance state of the selected cell SMC is maintained.

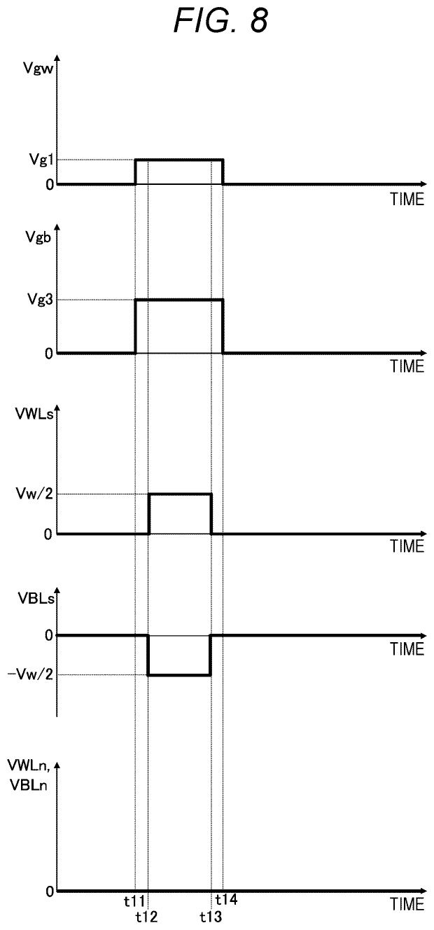

FIG. 8 is a diagram illustrating voltage waveforms of individual units at the time of high-resistance writing in the storage device according to the first embodiment.

In this figure, at the time of high-resistance writing, the word line voltage VWLn of a non-selected word line and the bit line voltage VBLn of a non-selected bit line are set to 0. Then, the gate voltage Vgw of the PMOS transistor 112 is set to the voltage Vg1, and the gate voltage Vgb of the NMOS transistor 115 is set to the voltage Vg3 (t11). At this time, the ON-resistance of the PMOS transistor 112 is set such that the cell voltage Vc applied to the selected cell SMC in the low resistance state coincides with the reversing voltage when the write voltage Vw is divided between the ON-resistance and the selected cell SMC in the low resistance state. Furthermore, the NMOS transistor 115 is turned on, and the memory cell array 101 and the bit line driver 107 are conducted via the bit line BL.

Next, the word line voltage VWLs of the selected word line SWL is set to Vw/2, and the bit line voltage VBLs of the selected bit line SBL is set to −Vw/2 (t12). Here, the write voltage Vw supplied via the selected word line SWL and the selected bit line SBL is divided into a voltage to be applied to the ON-resistance of the PMOS transistor 112 connected to the selected word line SWL and the cell voltage Vc to be applied to the selected cell SMC. At this time, the cell voltage Vc applied to the selected cell SMC in the low resistance state coincides with the reversing voltage, and the selected cell SMC transitions from the low resistance state to the high resistance state.

Next, the word line voltage VWLs of the selected word line SWL is set to 0, and the bit line voltage VBLs of the selected bit line SBL is set to 0 (t13). Note that, pulse widths of the word line voltage VWLs and the bit line voltage VBLs are set such that the write error rate becomes 0 as illustrated in “a” of FIG. 3.

Next, the gate voltage Vgw of the PMOS transistor 112 is set to 0, and the gate voltage Vgb of the NMOS transistor 115 is set to 0 (t14).

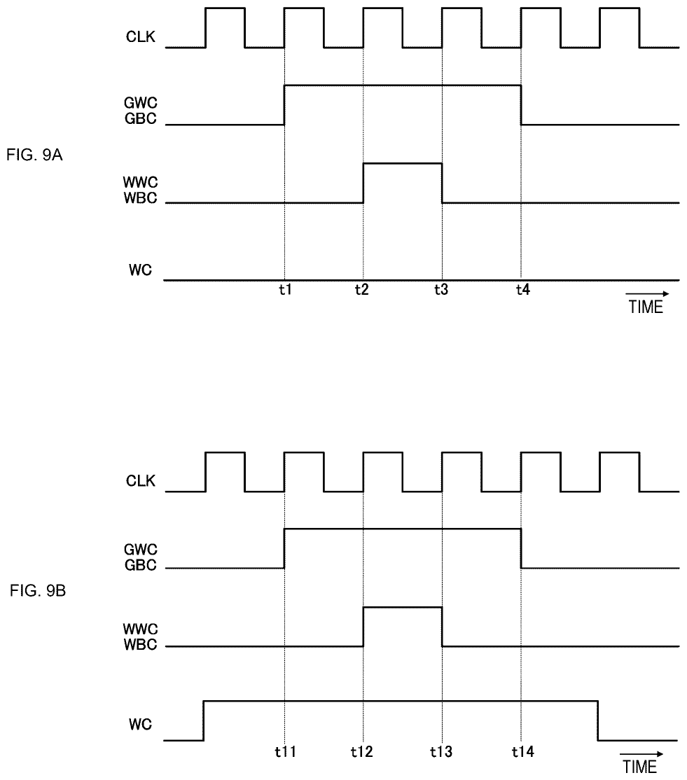

FIG. 9 is a timing chart illustrating a write timing of the storage device according to the first embodiment. Note that, “a” of this figure illustrates a timing of low-resistance writing. In this figure, “b” illustrates a timing of high-resistance writing.

In “a” in of figure, the switching signals GWC, GBC, WWC, and WBC and a control signal WC transition in synchronization with a clock CLK. The control signal WC designates low-resistance writing and high-resistance writing.

At the time of low-resistance writing, the control signal WC is set to a low level (t1 to t4). Then, when the switching signal GWC rises (t1), the gate voltage Vgw of the PMOS transistor 112 is set to the voltage Vg2. Furthermore, when the switching signal GBC rises (t1), the gate voltage Vgb of the NMOS transistor 115 is set to the voltage Vg3.

Next, when the switching signal WWC rises (t2), the word line voltage VWLs of the selected word line SWL is set to Vw/2. Furthermore, when the switching signal WBC rises (t2), the bit line voltage VBLs of the selected bit line SBL is set to −Vw/2.

Next, when the switching signal WWC falls (t3), the word line voltage VWLs of the selected word line SWL is set to 0. Furthermore, when the switching signal WBC falls (t3), the bit line voltage VBLs of the selected bit line SBL is set to 0.

Next, when the switching signal GWC falls (t4), the gate voltage Vgw of the PMOS transistor 112 is set to 0. Furthermore, when the switching signal GBC falls (t4), the gate voltage Vgb of the NMOS transistor 115 is set to 0.

In “b” in of figure, at the time of high-resistance writing, the control signal WC is set to a high level (from t11 to t14). Then, when the switching signal GWC rises (t11), the gate voltage Vgw of the PMOS transistor 112 is set to the voltage Vg1. Furthermore, when the switching signal GBC rises (t11), the gate voltage Vgb of the NMOS transistor 115 is set to the voltage Vg3.

Next, when the switching signal WWC rises (t12), the word line voltage VWLs of the selected word line SWL is set to Vw/2. Furthermore, when the switching signal WBC rises (t12), the bit line voltage VBLs of the selected bit line SBL is set to −Vw/2.

Next, when the switching signal WWC falls (t13), the word line voltage VWLs of the selected word line SWL is set to 0. Furthermore, when the switching signal WBC falls (t13), the bit line voltage VBLs of the selected bit line SBL is set to 0.

Next, when the switching signal GWC falls (t14), the gate voltage Vgw of the PMOS transistor 112 is set to 0. Furthermore, when the switching signal GBC falls (t14), the gate voltage Vgb of the NMOS transistor 115 is set to 0.

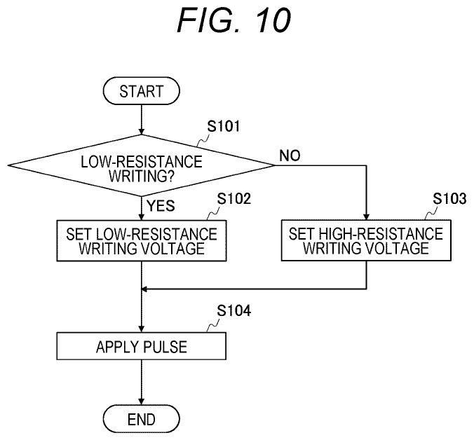

FIG. 10 is a flowchart illustrating a writing method of the storage device according to the first embodiment.

In this figure, the storage device 100 determines whether or not low-resistance writing is performed (S101). In a case of low-resistance writing, the storage device 100 sets a low-resistance writing voltage (S102). In the setting of the low-resistance writing voltage, the gate voltage Vgw of the PMOS transistor 112 is set to the voltage Vg2. At this time, the control signal WC in FIG. 9 is set to a low level.

Whereas, in a case of high-resistance writing, the storage device 100 sets a high-resistance writing voltage (S103). In the setting of the high-resistance writing voltage, the gate voltage Vgw of the PMOS transistor 112 is set to the voltage Vg1. At this time, the control signal WC in FIG. 9 is set to a high level.

Next, the storage device 100 applies a voltage pulse to the selected word line SWL and the selected bit line SBL (S104). In the application of the voltage pulse, over the application period, the word line voltage VWLs of the selected word line SWL is set to Vw/2, and the bit line voltage VBLs of the selected bit line SBL is set to −Vw/2.

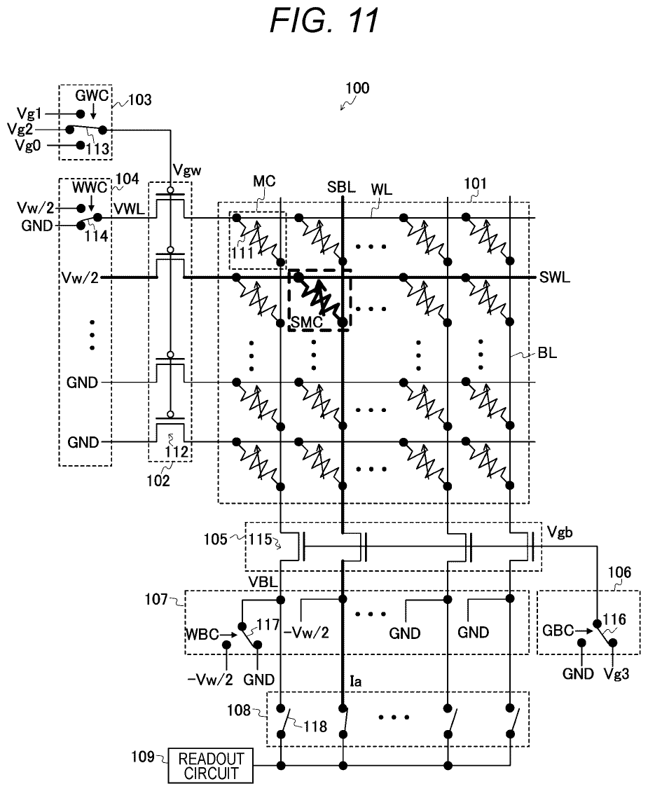

FIG. 11 is a diagram illustrating a selection example of a memory cell at a time of reading of the storage device according to the first embodiment. Note that, in data reading, in addition to a current path between the selected word line SWL and the selected bit line SBL in which the selected cell SMC is interposed, a current path between the selected word line SWL and the selected bit line SBL in which a non-selected cell is interposed is generated. Therefore, a current Ia flowing through the selected bit line SBL at the time of data reading includes not only a current flowing through the selected cell SMC but also a current flowing through the non-selected cell. The current Ia depends not only on a resistance state of the selected cell SMC but also on a resistance state of the non-selected cell. Therefore, in determination of magnitude of the current Ia, the resistance state of the selected cell SMC cannot be accurately determined. Therefore, in order to determine the resistance state of the selected cell SMC, writing is performed on the selected cell SMC, and it is determined whether or not the current Ia changes at that time. In the following description, a method of performing low-resistance writing on the selected cell SMC and determining the resistance state of the selected cell SMC on the basis of a change in the current Ia at that time is taken as an example.

In this figure, it is assumed that the selected cell SMC has been designated at the time of reading. At this time, the selected bit line SBL is connected to the readout circuit 109 via the column switch 118. Furthermore, the word line voltage VWL of the selected word line SWL is set to Vw/2, and the bit line voltage VBL of the selected bit line SBL is set to −Vw/2. Furthermore, the gate voltage Vgb of each NMOS transistor 115 is set to the voltage Vg3, and the gate voltage Vgw of each PMOS transistor 112 is set to the voltage Vg2. At this time, low-resistance writing is performed on the selected cell SMC.

The readout circuit 109 measures the current Ia flowing through the selected bit line SBL at the time of low-resistance writing on the selected cell SMC. Here, in a case where the selected cell SMC is in the high resistance state, when the low-resistance writing on the selected cell SMC is performed, the current Ia flowing through the selected bit line SBL increases. Whereas, in a case where the selected cell SMC is in the low resistance state, the current Ia flowing through the selected bit line SBL does not change even if the low-resistance writing on the selected cell SMC is performed. Therefore, the readout circuit 109 can determine that the selected cell SMC is in the low resistance state in a case where the current Ia flowing through the selected bit line SBL does not change, and can determine that the selected cell SMC has been in the high resistance state in a case where the current Ia flowing through the selected bit line SBL increases. Here, if the low-resistance writing is performed when the selected cell SMC is in the high resistance state, the resistance state of the selected cell SMC changes, and data stored in the selected cell SMC is destructed. Therefore, when it is determined that the selected cell SMC has been in the high resistance state, the high-resistance writing is performed on the selected cell SMC, and original data is written back to the selected cell SMC.

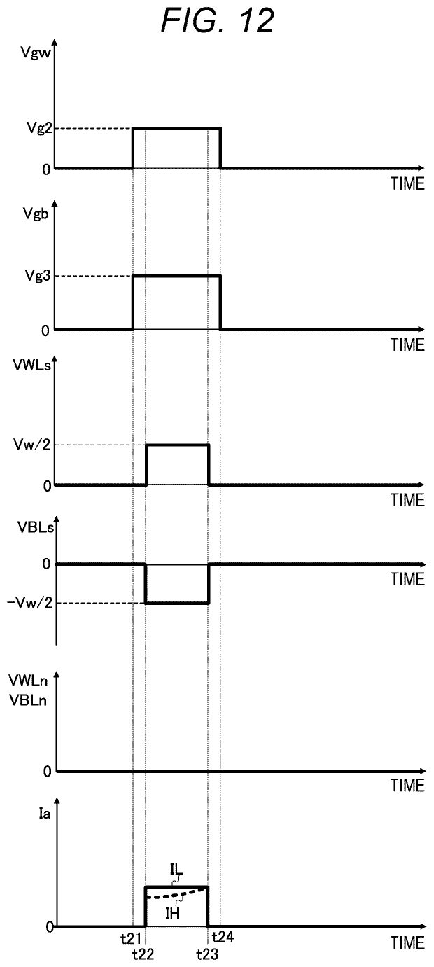

FIG. 12 is a diagram illustrating voltage waveforms of individual units at a time of reading of the storage device according to the first embodiment.

In this figure, at the time of reading, the word line voltage VWLn of a non-selected word line and the bit line voltage VBLn of a non-selected bit line are set to 0. Then, the gate voltage Vgw of the PMOS transistor 112 is set to the voltage Vg2, and the gate voltage Vgb of the NMOS transistor 115 is set to the voltage Vg3 (t21).

Next, the word line voltage VWLs of the selected word line SWL is set to Vw/2, and the bit line voltage VBLs of the selected bit line SBL is set to −Vw/2 (t22). At this time, the readout circuit 109 measures the current Ia flowing through the selected bit line SBL. Here, in a case where the selected cell SMC is in the high resistance state, when the low-resistance writing on the selected cell SMC is performed, the current Ia flowing through the selected bit line SBL increases (IH). Whereas, in a case where the selected cell SMC is in the low resistance state, the current Ia flowing through the selected bit line SBL does not change (IL) even if the low-resistance writing on the selected cell SMC is performed. At this time, the readout circuit 109 determines that the selected cell SMC is in the low resistance state in a case where the current Ia flowing through the selected bit line SBL does not change, and determines that the selected cell SMC has been in the high resistance state in a case where the current Ia flowing through the selected bit line SBL increases.

Next, the word line voltage VWLs of the selected word line SWL is set to 0, and the bit line voltage VBLs of the selected bit line SBL is set to 0 (t23).

Next, the gate voltage Vgw of the PMOS transistor 112 is set to 0, and the gate voltage Vgb of the NMOS transistor 115 is set to 0 (t24).

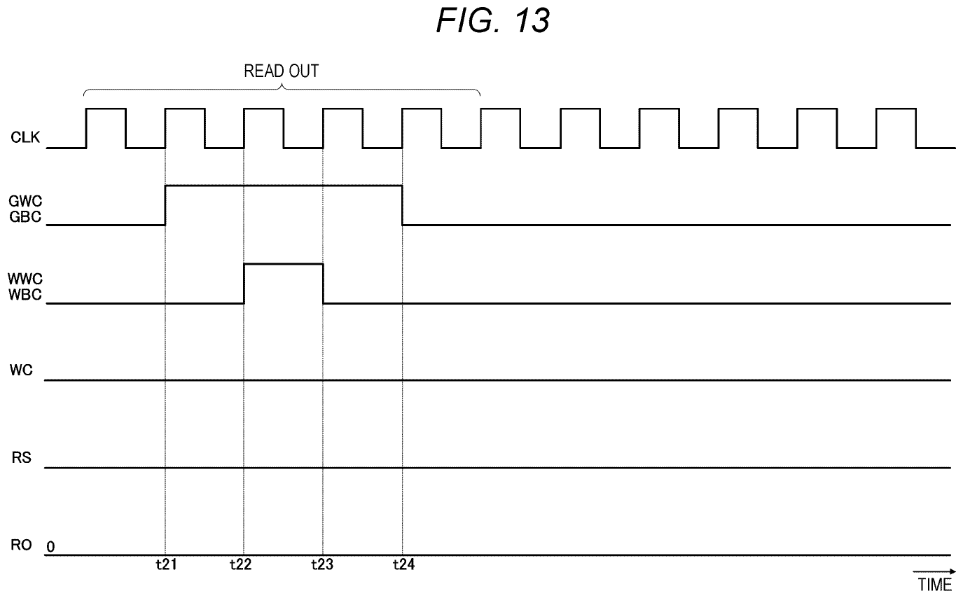

FIG. 13 is a timing chart illustrating a readout timing in the low resistance state of the storage device according to the first embodiment.

In this figure, the control signal WC is set to a low level (from t21 to t24). Then, when the switching signal GWC rises (t21), the gate voltage Vgw of the PMOS transistor 112 is set to the voltage Vg2. Furthermore, when the switching signal GBC rises (t21), the gate voltage Vgb of the NMOS transistor 115 is set to the voltage Vg3.

Next, when the switching signal WWC rises (t22), the word line voltage VWLs of the selected word line SWL is set to Vw/2. Furthermore, when the switching signal WBC rises (t22), the bit line voltage VBLs of the selected bit line SBL is set to −Vw/2.

Next, when the switching signal WWC falls (t23), the word line voltage VWLs of the selected word line SWL is set to 0. Furthermore, when the switching signal WBC falls (t23), the bit line voltage VBLs of the selected bit line SBL is set to 0. Here, in a case where the current Ia flowing through the selected bit line SBL does not change, a read signal RS does not change, and ‘0’ is output as a read output RO.

Next, when the switching signal GWC falls (t24), the gate voltage Vgw of the PMOS transistor 112 is set to 0. Furthermore, when the switching signal GBC falls (t24), the gate voltage Vgb of the NMOS transistor 115 is set to 0.

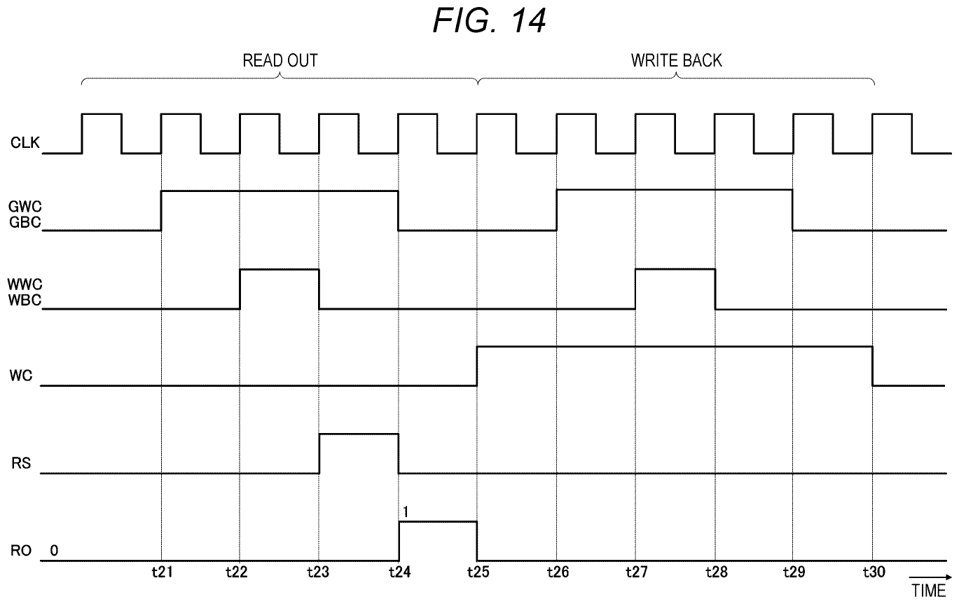

FIG. 14 is a timing chart illustrating a readout timing in the high resistance state of the storage device according to the first embodiment.

In this figure, the control signal WC is set to a low level (from t21 to t24). Then, when the switching signal GWC rises (t21), the gate voltage Vgw of the PMOS transistor 112 is set to the voltage Vg2. Furthermore, when the switching signal GBC rises (t21), the gate voltage Vgb of the NMOS transistor 115 is set to the voltage Vg3.

Next, when the switching signal WWC rises (t22), the word line voltage VWLs of the selected word line SWL is set to Vw/2. Furthermore, when the switching signal WBC rises (t22), the bit line voltage VBLs of the selected bit line SBL is set to −Vw/2.

Next, when the switching signal WWC falls (t23), the word line voltage VWLs of the selected word line SWL is set to 0. Furthermore, when the switching signal WBC falls (t23), the bit line voltage VBLs of the selected bit line SBL is set to 0. Here, in a case where the current Ia flowing through the selected bit line SBL changes, the read signal RS rises (t23), and ‘1’ is output as the read output RO (t24).

Next, when the switching signal GWC falls (t24), the gate voltage Vgw of the PMOS transistor 112 is set to 0. Furthermore, when the switching signal GBC falls (t24), the gate voltage Vgb of the NMOS transistor 115 is set to 0.

Here, when ‘1’ is output as the read output RO, the high resistance state changes to the low resistance state from the selected cell SMC. Therefore, write back of the selected cell SMC is performed, and the selected cell SMC is returned to the high resistance state. At this time, in order to perform the high-resistance writing on the selected cell SMC, the control signal WC is set to a high level (from t25 to t30). Then, when the switching signal GWC rises (t26), the gate voltage Vgw of the PMOS transistor 112 is set to the voltage Vg1. Furthermore, when the switching signal GBC rises (t26), the gate voltage Vgb of the NMOS transistor 115 is set to the voltage Vg3.

Next, when the switching signal WWC rises (t27), the word line voltage VWLs of the selected word line SWL is set to Vw/2. Furthermore, when the switching signal WBC rises (t27), the bit line voltage VBLs of the selected bit line SBL is set to −Vw/2.

Next, when the switching signal WWC falls (t28), the word line voltage VWLs of the selected word line SWL is set to 0. Furthermore, when the switching signal WBC falls (t28), the bit line voltage VBLs of the selected bit line SBL is set to 0.

Next, when the switching signal GWC falls (t29), the gate voltage Vgw of the PMOS transistor 112 is set to 0. Furthermore, when the switching signal GBC falls (t29), the gate voltage Vgb of the NMOS transistor 115 is set to 0.

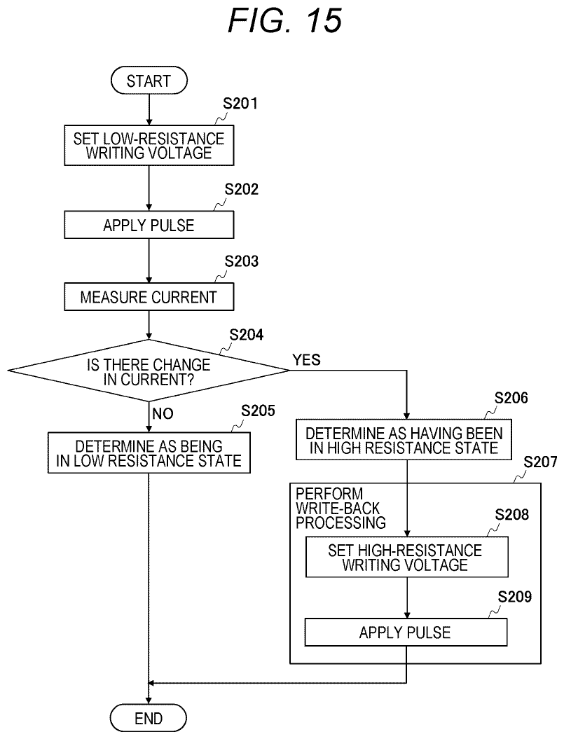

FIG. 15 is a flowchart illustrating a readout method of the storage device according to the first embodiment.

In this figure, the storage device 100 sets a low-resistance writing voltage (S201). In the setting of the low-resistance writing voltage, the gate voltage Vgw of the PMOS transistor 112 is set to the voltage Vg2. At this time, the control signal WC in FIG. 13 is set to a low level.

Next, the storage device 100 applies a voltage pulse to the selected word line SWL and the selected bit line SBL (S202). In the application of the voltage pulse, over the application period, the word line voltage VWLs of the selected word line SWL is set to Vw/2, and the bit line voltage VBLs of the selected bit line SBL is set to −Vw/2.

Next, the readout circuit 109 measures the current Ia flowing through the selected bit line SBL (S203). Then, the readout circuit 109 determines whether or not the current Ia flowing through the selected bit line SBL has changed (S204). In a case where the current Ia flowing through the selected bit line SBL does not change, the selected cell SMC is determined to be in the low resistance state (S205). Whereas, in a case where the current Ia flowing through the selected bit line SBL has changed, the selected cell SMC is determined to have been in the high resistance state (S206).

Next, the storage device 100 performs write-back processing on the selected cell SMC (S207). In the write-back processing of the selected cell SMC, the storage device 100 sets a high-resistance writing voltage (S208). In the setting of the high-resistance writing voltage, the gate voltage Vgw of the PMOS transistor 112 is set to the voltage Vg1. At this time, the control signal WC in FIG. 14 is set to a high level.

Next, the storage device 100 applies a voltage pulse to the selected word line SWL and the selected bit line SBL (S209). In the application of the voltage pulse, over the application period, the word line voltage VWLs of the selected word line SWL is set to Vw/2, and the bit line voltage VBLs of the selected bit line SBL is set to −Vw/2.

Note that, in the embodiment described above, a method of performing low-resistance writing on the selected cell SMC and determining the resistance state of the selected cell SMC on the basis of a change in the current Ia at that time has been taken as an example. Whereas, high-resistance writing may be performed on the selected cell SMC, and a resistance state of the selected cell SMC may be determined on the basis of a change in the current Ia at that time.

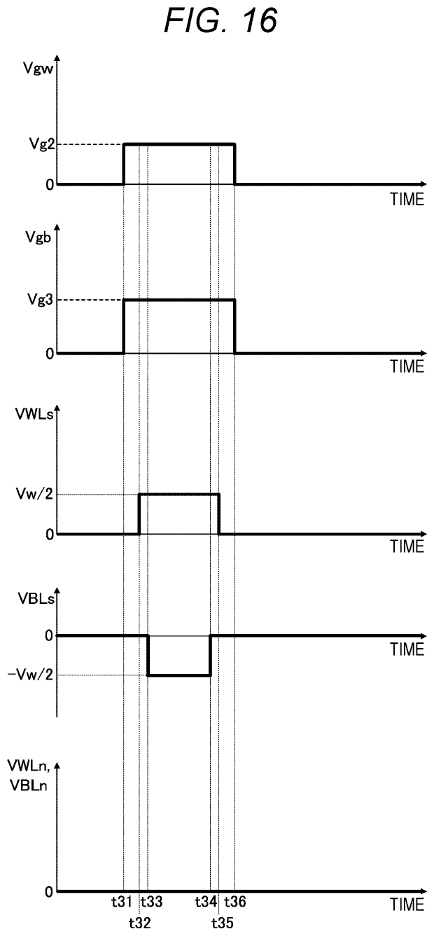

FIG. 16 is a diagram illustrating a modification of voltage waveforms of individual units at the time of low-resistance writing in the storage device according to the first embodiment.

In this figure, at the time of low-resistance writing, the word line voltage VWLn of a non-selected word line and the bit line voltage VBLn of a non-selected bit line are set to 0. Then, the gate voltage Vgw of the PMOS transistor 112 is set to the voltage Vg2, and the gate voltage Vgb of the NMOS transistor 115 is set to the voltage Vg3 (t31).

Next, the word line voltage VWLs of the selected word line SWL is set to Vw/2 (t32), and then the bit line voltage VBLs of the selected bit line SBL is set to −Vw/2 (t33).

Next, the bit line voltage VBLs of the selected bit line SBL is set to 0 (t34), and then the word line voltage VWLs of the selected word line SWL is set to 0 (t35).

Next, the gate voltage Vgw of the PMOS transistor 112 is set to 0, and the gate voltage Vgb of the NMOS transistor 115 is set to 0 (t36).

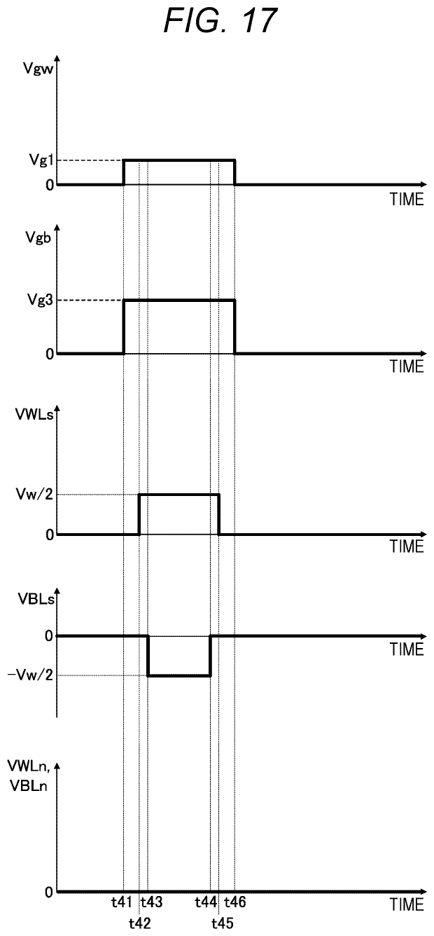

FIG. 17 is a diagram illustrating a modification of voltage waveforms of individual units at the time of high-resistance writing in the storage device according to the first embodiment.

In this figure, at the time of high-resistance writing, the word line voltage VWLn of a non-selected word line and the bit line voltage VBLn of a non-selected bit line are set to 0. Then, the gate voltage Vgw of the PMOS transistor 112 is set to the voltage Vg1, and the gate voltage Vgb of the NMOS transistor 115 is set to the voltage Vg3 (t41).

Next, the word line voltage VWLs of the selected word line SWL is set to Vw/2 (t42), and then the bit line voltage VBLs of the selected bit line SBL is set to −Vw/2 (t43).

Next, the bit line voltage VBLs of the selected bit line SBL is set to 0 (t44), and then the word line voltage VWLs of the selected word line SWL is set to 0 (t45).

Next, the gate voltage Vgw of the PMOS transistor 112 is set to 0, and the gate voltage Vgb of the NMOS transistor 115 is set to 0 (t46).

In the method of making a pulse width of the bit line voltage VBLs shorter than a pulse width of the word line voltage VWLs, if pulse width control of the bit line voltage VBLs is performed such that a write error rate of a in FIG. 3 becomes 0, there is no need to perform pulse width control of the word line voltage VWLs. Therefore, the pulse width control can be facilitated as compared with the method of equalizing the pulse width of the bit line voltage VBLs and the pulse width of the word line voltage VWLs in FIG. 6. Note that, the pulse width of the word line voltage VWLs may be shorter than the pulse width of the bit line voltage VBLs.

Furthermore, in the embodiment of FIGS. 16 and 17, the case has been described in which the pulse width of the word line voltage VWLs of the selected word line SWL and the pulse width of the bit line voltage VBLs of the selected bit line SBL are different from each other. However, it suffices that the pulse of the word line voltage VWLs of the selected word line SWL temporally overlaps at least partially with the pulse of the bit line voltage VBLs of the selected bit line SBL. For example, in a case where the pulse width of the word line voltage VWLs of the selected word line SWL is equal to the pulse width of the bit line voltage VBLs of the selected bit line SBL, the pulse of the word line voltage VWLs may be temporally shifted from the pulse of the bit line voltage VBLs. At this time, time during which the pulse of the word line voltage VWLs of the selected word line SWL overlaps at least partially with the pulse of the bit line voltage VBLs of the selected bit line SBL is set such that a write error rate becomes 0 as illustrated in “a” of FIG. 3.

As described above, in the first embodiment, the word line WL is connected to one end of the magnetoresistive effect element 111, and the bit line BL is connected to another end of the magnetoresistive effect element 111. Then, writing is performed on the selected cell SMC on the basis of a divided voltage of the write voltage Vw on the selected word line side. As a result, it is possible to achieve the memory cell MC capable of reversing magnetization on the basis of voltage drive without providing, in the memory cell MC, a selector element for selecting the memory cell MC, and necessity of current drive for reversing magnetization can be eliminated. Therefore, it is possible to achieve a large capacity and low power consumption while achieving cost reduction of the storage device 100.

### 2. Second Embodiment

In the first embodiment described above, resistance of the word line WL is controlled such that a reversing voltage applied to the magnetoresistive effect element 111 becomes equal in accordance with a resistance state of writing on the magnetoresistive effect element 111. In this second embodiment, resistance of a bit line BL is controlled such that a reversing voltage applied to a magnetoresistive effect element 111 becomes equal in accordance with a resistance state of writing on the magnetoresistive effect element 111.

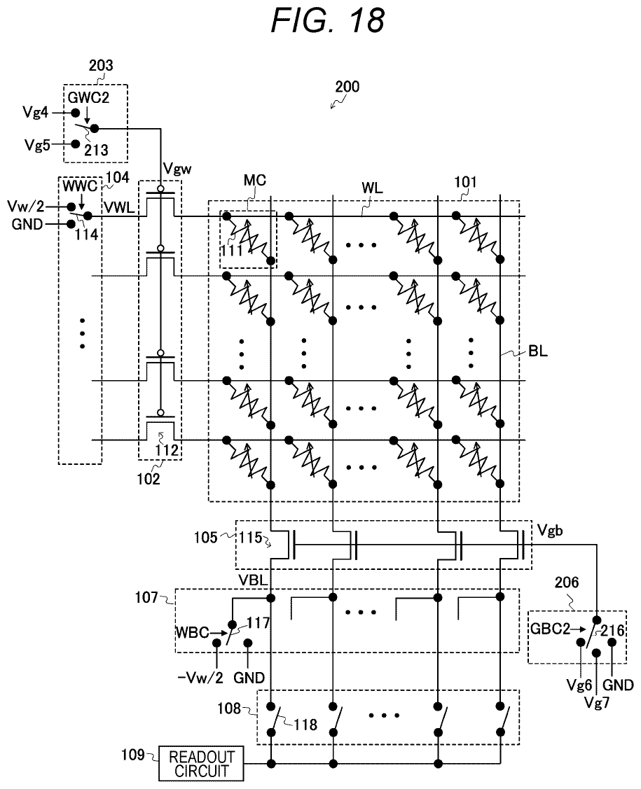

FIG. 18 is a diagram illustrating a configuration example of a storage device according to the second embodiment.

In this figure, a storage device 200 includes gate voltage switching units 203 and 206 instead of the gate voltage switching units 103 and 106 of the first embodiment described above. Other configurations of the storage device 200 of the second embodiment are similar to the configurations of the storage device 100 of the first embodiment described above.

The gate voltage switching unit 203 switches a gate voltage Vgw between voltages Vg4 and Vg5. The voltage Vg4 is set such that each PMOS transistor 112 is turned on, and the voltage Vg5 is set such that each PMOS transistor 112 is turned off.

The gate voltage switching unit 203 includes a conduction state control switch 213. The conduction state control switch 213 switches between the voltages Vg4 and Vg5 on the basis of a switching signal GWC2. At this time, the switching signal GWC2 can cause the conduction state control switch 213 to select the voltage Vg5 at a time of non-writing and non-reading, and select the voltage Vg4 at a time of writing or reading. The conduction state control switch 213 may include a MOS transistor.

The gate voltage switching unit 206 switches a gate voltage Vgb between voltages Vg6, Vg7, and GND. The voltage Vg6 is set such that a cell voltage applied to the magnetoresistive effect element 111 is equal to a reversing voltage in a case where the magnetoresistive effect element 111 is subjected to high-resistance writing. The voltage Vg7 is set such that a cell voltage applied to the magnetoresistive effect element 111 is equal to a reversing voltage in a case where the magnetoresistive effect element 111 is subjected to low-resistance writing.

The gate voltage switching unit 206 includes a resistance state control switch 216. The resistance state control switch 216 switches between the voltages Vg6, Vg7, and GND on the basis of a switching signal GBC2. At this time, the switching signal GBC2 can cause the resistance state control switch 216 to select GND at a time of non-writing and non-reading. The switching signal GBC2 can cause the resistance state control switch 216 to select the voltage Vg6 at the time of high-resistance writing and select the voltage Vg7 at the time of low-resistance writing. The resistance state control switch 216 may include a MOS transistor.

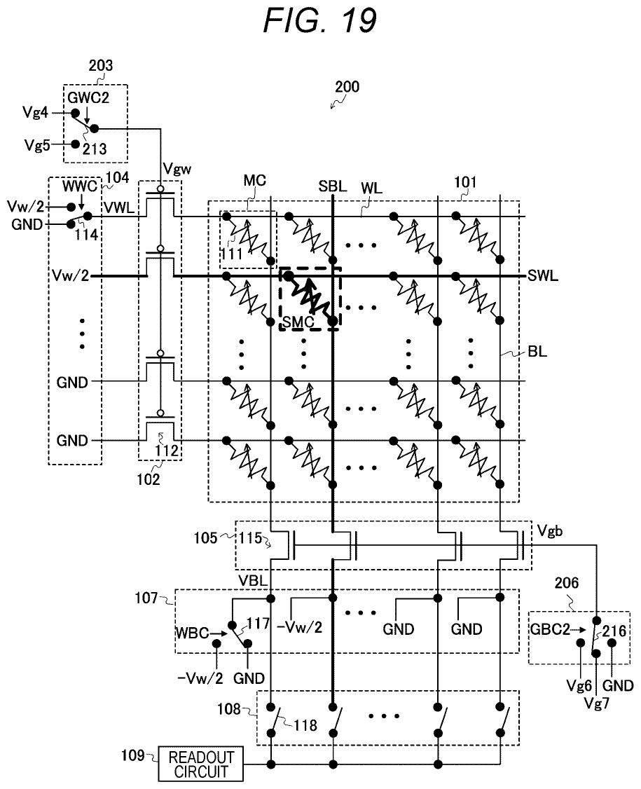

FIG. 19 is a diagram illustrating a selection example of a memory cell at the time of low-resistance writing in the storage device according to the second embodiment.

In this figure, it is assumed that a selected cell SMC has been designated at the time of low-resistance writing. At this time, a word line voltage VWL of the selected word line SWL is set to Vw/2, and a bit line voltage VBL of a selected bit line SBL is set to −Vw/2. The gate voltage Vgw of each PMOS transistor 112 is set to the voltage Vg4. At this time, each PMOS transistor 112 is turned on.

The gate voltage Vgb of each NMOS transistor 115 is set to the voltage Vg7. At this time, the write voltage Vw is divided into a voltage to be applied to ON-resistance of the NMOS transistor 115 connected to the selected bit line SBL and a cell voltage Vc to be applied to the selected cell SMC. Then, the gate voltage Vgb is set such that the cell voltage Vc applied to the selected cell SMC in the high resistance state coincides with a reversing voltage when the write voltage Vw is divided at the ON-resistance of the NMOS transistor 115.

Here, in a case where the selected cell SMC is in the high resistance state at the time of low-resistance writing, since the reversing voltage is applied to the selected cell SMC, the selected cell SMC transitions from the high resistance state to the low resistance state. Whereas, in a case where the selected cell SMC is in the low resistance state at the time of low-resistance writing, a voltage dividing ratio of the write voltage Vw to the ON-resistance of the NMOS transistor 115 increases as compared with the case where the selected cell SMC is in the high resistance state. Therefore, the cell voltage Vc applied to the selected cell SMC becomes smaller than the reversing voltage, and the low resistance state of the selected cell SMC is maintained due to the perpendicular magnetic anisotropy of the selected cell SMC.

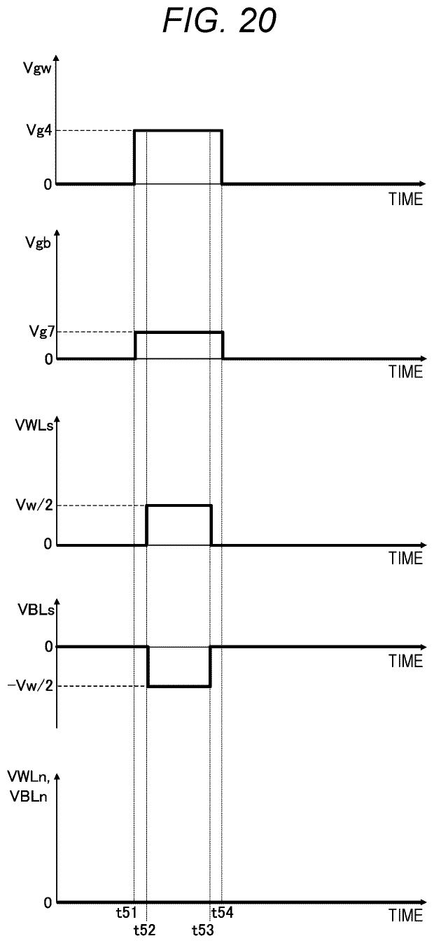

FIG. 20 is a diagram illustrating voltage waveforms of individual units at the time of low-resistance writing in the storage device according to the second embodiment.

In this figure, at the time of low-resistance writing, a word line voltage VWLn of a non-selected word line and a bit line voltage VBLn of a non-selected bit line are set to 0. Then, the gate voltage Vgw of the PMOS transistor 112 is set to the voltage Vg4, and the gate voltage Vgb of the NMOS transistor 115 is set to the voltage Vg7 (t51). At this time, the ON-resistance of the NMOS transistor 115 is set such that the cell voltage Vc applied to the selected cell SMC in the high resistance state coincides with the reversing voltage when the write voltage Vw is divided between the ON-resistance and the selected cell SMC in the high resistance state. Furthermore, the PMOS transistor 112 is turned on, and the memory cell array 101 and a word line driver 104 are conducted via a word line WL.

Next, a word line voltage VWLs of the selected word line SWL is set to Vw/2, and a bit line voltage VBLs of the selected bit line SBL is set to −Vw/2 (t52). Here, the write voltage Vw supplied via the selected word line SWL and the selected bit line SBL is divided into a voltage to be applied to the ON-resistance of the NMOS transistor 115 connected to the selected bit line SBL and the cell voltage Vc to be applied to the selected cell SMC. At this time, the cell voltage Vc applied to the selected cell SMC in the high resistance state coincides with the reversing voltage, and the selected cell SMC transitions from the high resistance state to the low resistance state.

Next, the word line voltage VWLs of the selected word line SWL is set to 0, and the bit line voltage VBLs of the selected bit line SBL is set to 0 (t53).

Next, the gate voltage Vgw of the PMOS transistor 112 is set to 0, and the gate voltage Vgb of the NMOS transistor 115 is set to 0 (t54).

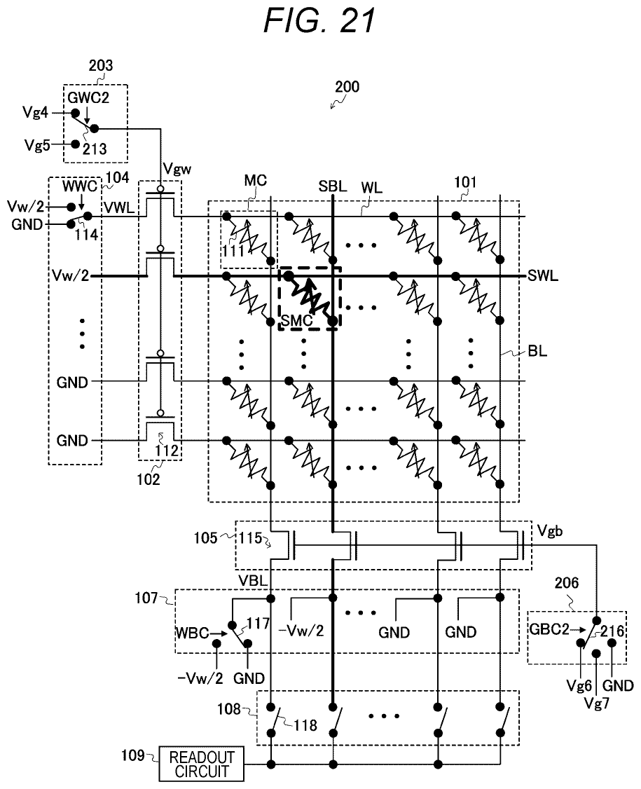

FIG. 21 is a diagram illustrating a selection example of a memory cell at the time of high-resistance writing in the storage device according to the second embodiment.

In this figure, it is assumed that the selected cell SMC has been designated at the time of high-resistance writing. At this time, the word line voltage VWL of the selected word line SWL is set to Vw/2, and the bit line voltage VBL of the selected bit line SBL is set to −Vw/2. The gate voltage Vgw of each PMOS transistor 112 is set to the voltage Vg4. At this time, each PMOS transistor 112 is turned on.

The gate voltage Vgb of each NMOS transistor 115 is set to the voltage Vg6. At this time, the write voltage Vw is divided into a voltage to be applied to the ON-resistance of the NMOS transistor 115 connected to the selected bit line SBL and the cell voltage Vc to be applied to the selected cell SMC. Then, the gate voltage Vgb is set such that the cell voltage Vc applied to the selected cell SMC in the low resistance state coincides with a reversing voltage when the write voltage Vw is divided at the ON-resistance of the NMOS transistor 115.

Here, in a case where the selected cell SMC is in the low resistance state at the time of high-resistance writing, since the reversing voltage is applied to the selected cell SMC, the selected cell SMC transitions from the low resistance state to the high resistance state. Whereas, in a case where the selected cell SMC is in the high resistance state at the time of high-resistance writing, a voltage dividing ratio of the write voltage Vw to the ON-resistance of the NMOS transistor 115 decreases as compared with the case where the selected cell SMC is in the low resistance state. For this reason, the cell voltage Vc applied to the selected cell SMC becomes larger than the reversing voltage, and an in-plane rotation component appears due to an in-plane magnetic anisotropy of the selected cell SMC. However, this rotation component does not contribute to reversing of the magnetization direction, so that the high resistance state of the selected cell SMC is maintained.

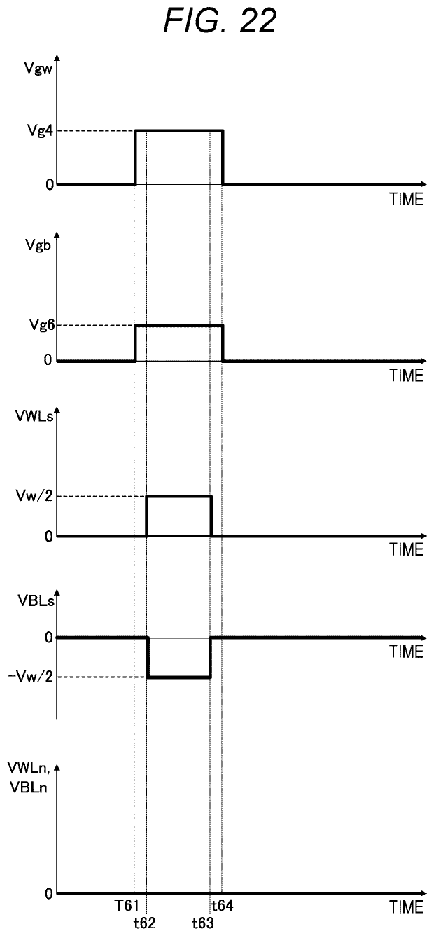

FIG. 22 is a diagram illustrating voltage waveforms of individual units at the time of high-resistance writing in the storage device according to the second embodiment.

In this figure, at the time of high-resistance writing, the word line voltage VWLn of a non-selected word line and the bit line voltage VBLn of a non-selected bit line are set to 0. Then, the gate voltage Vgw of the PMOS transistor 112 is set to the voltage Vg4, and the gate voltage Vgb of the NMOS transistor 115 is set to the voltage Vg6 (t61). At this time, the ON-resistance of the NMOS transistor 115 is set such that the cell voltage Vc applied to the selected cell SMC in the low resistance state coincides with the reversing voltage when the write voltage Vw is divided between the ON-resistance and the selected cell SMC in the low resistance state. Furthermore, the PMOS transistor 112 is turned on, and the memory cell array 101 and the word line driver 104 are conducted via the word line WL.

Next, the word line voltage VWLs of the selected word line SWL is set to Vw/2, and the bit line voltage VBLs of the selected bit line SBL is set to −Vw/2 (t62). Here, the write voltage Vw supplied via the selected word line SWL and the selected bit line SBL is divided into a voltage to be applied to the ON-resistance of the NMOS transistor 115 connected to the selected bit line SBL and the cell voltage Vc to be applied to the selected cell SMC. At this time, the cell voltage Vc applied to the selected cell SMC in the low resistance state coincides with the reversing voltage, and the selected cell SMC transitions from the low resistance state to the high resistance state.

Next, the word line voltage VWLs of the selected word line SWL is set to 0, and the bit line voltage VBLs of the selected bit line SBL is set to 0 (t63).

Next, the gate voltage Vgw of the PMOS transistor 112 is set to 0, and the gate voltage Vgb of the NMOS transistor 115 is set to 0 (t64).

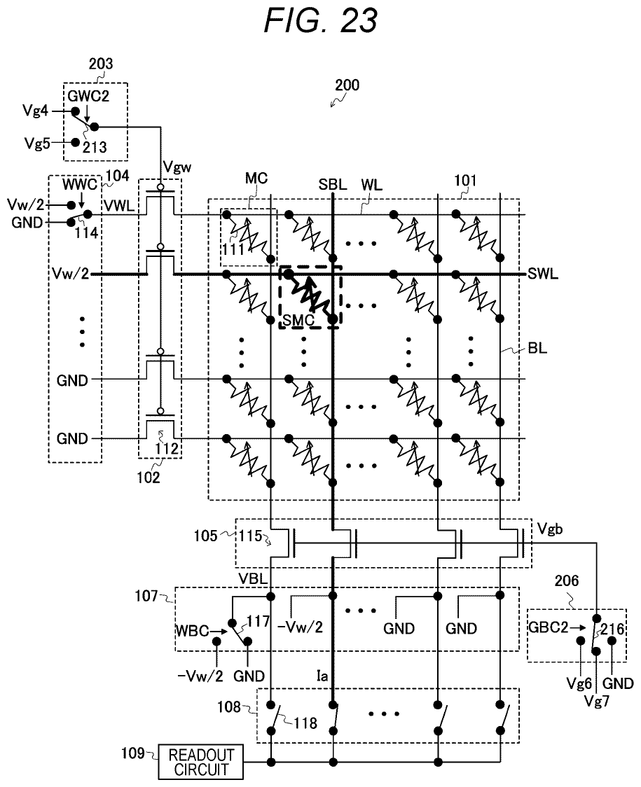

FIG. 23 is a diagram illustrating a selection example of a memory cell at a time of reading of the storage device according to the second embodiment.

In this figure, it is assumed that the selected cell SMC has been designated at the time of reading. At this time, the selected bit line SBL is connected to a readout circuit 109 via a column switch 118. Furthermore, the word line voltage VWL of the selected word line SWL is set to Vw/2, and the bit line voltage VBL of the selected bit line SBL is set to −Vw/2. Furthermore, the gate voltage Vgb of each NMOS transistor 115 is set to the voltage Vg7, and the gate voltage Vgw of each PMOS transistor 112 is set to the voltage Vg4. At this time, low-resistance writing is performed on the selected cell SMC.

The readout circuit 109 measures a current Ia flowing through the selected bit line SBL at the time of low-resistance writing on the selected cell SMC. Here, in a case where the selected cell SMC is in the high resistance state, when the low-resistance writing on the selected cell SMC is performed, the current Ia flowing through the selected bit line SBL increases. Whereas, in a case where the selected cell SMC is in the low resistance state, the current Ia flowing through the selected bit line SBL does not change even if the low-resistance writing on the selected cell SMC is performed. Therefore, the readout circuit 109 can determine that the selected cell SMC is in the low resistance state in a case where the current Ia flowing through the selected bit line SBL does not change, and can determine that the selected cell SMC has been in the high resistance state in a case where the current Ia flowing through the selected bit line SBL increases. Here, if the low-resistance writing is performed when the selected cell SMC is in the high resistance state, the resistance state of the selected cell SMC changes, and data stored in the selected cell SMC is destructed. Therefore, when it is determined that the selected cell SMC has been in the high resistance state, the high-resistance writing is performed on the selected cell SMC, and original data is written back to the selected cell SMC.

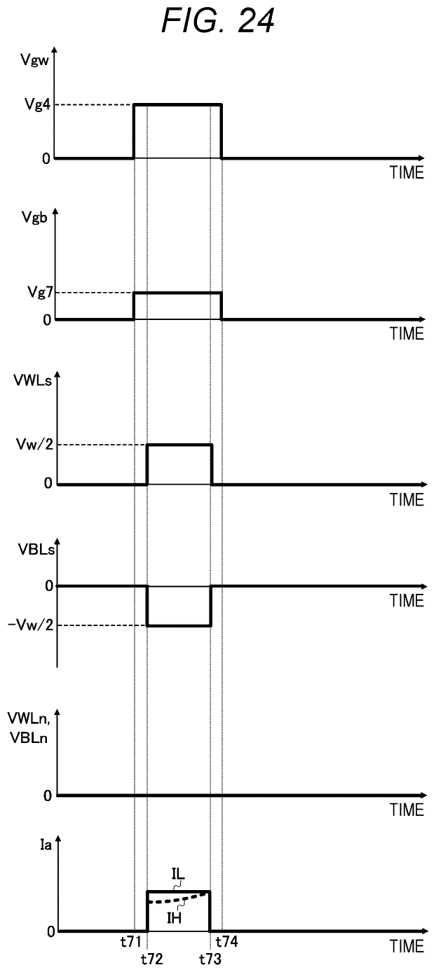

FIG. 24 is a diagram illustrating voltage waveforms of individual units at the time of reading of the storage device according to the second embodiment.

In this figure, at the time of reading, the word line voltage VWLn of a non-selected word line and the bit line voltage VBLn of a non-selected bit line are set to 0. Then, the gate voltage Vgw of the PMOS transistor 112 is set to the voltage Vg4, and the gate voltage Vgb of the NMOS transistor 115 is set to the voltage Vg7 (t71).

Next, the word line voltage VWLs of the selected word line SWL is set to Vw/2, and the bit line voltage VBLs of the selected bit line SBL is set to −Vw/2 (t72). At this time, the readout circuit 109 measures the current Ia flowing through the selected bit line SBL. Here, in a case where the selected cell SMC is in the high resistance state, in a case where the low-resistance writing on the selected cell SMC is performed, the current Ia flowing through the selected bit line SBL increases (IH). Whereas, in a case where the selected cell SMC is in the low resistance state, the current Ia flowing through the selected bit line SBL does not change (IL) even if the low-resistance writing on the selected cell SMC is performed. At this time, the readout circuit 109 determines that the selected cell SMC is in the low resistance state in a case where the current Ia flowing through the selected bit line SBL does not change, and determines that the selected cell SMC has been in the high resistance state in a case where the current Ia flowing through the selected bit line SBL increases.

Next, the word line voltage VWLs of the selected word line SWL is set to 0, and the bit line voltage VBLs of the selected bit line SBL is set to 0 (t73).

Next, the gate voltage Vgw of the PMOS transistor 112 is set to 0, and the gate voltage Vgb of the NMOS transistor 115 is set to 0 (t74).

As described above, in the second embodiment, the word line WL is connected to one end of the magnetoresistive effect element 111, and the bit line BL is connected to another end of the magnetoresistive effect element 111. Then, writing is performed on the selected cell SMC on the basis of a divided voltage of the write voltage Vw on the selected bit line side. As a result, it is possible to achieve the memory cell MC capable of reversing magnetization on the basis of voltage drive without providing, in the memory cell MC, a selector element for selecting the memory cell MC, and it is possible to reduce power consumption while simplifying the configuration of the memory cell MC.

### 3. Third Embodiment

In the first embodiment described above, low-resistance writing is performed in a case where low-resistance writing is commanded, and high-resistance writing is performed in a case where low-resistance writing is not commanded. In this third embodiment, a resistance state of a magnetoresistive effect element 111 is initialized, and high-resistance writing is performed in a case where high-resistance writing is commanded.

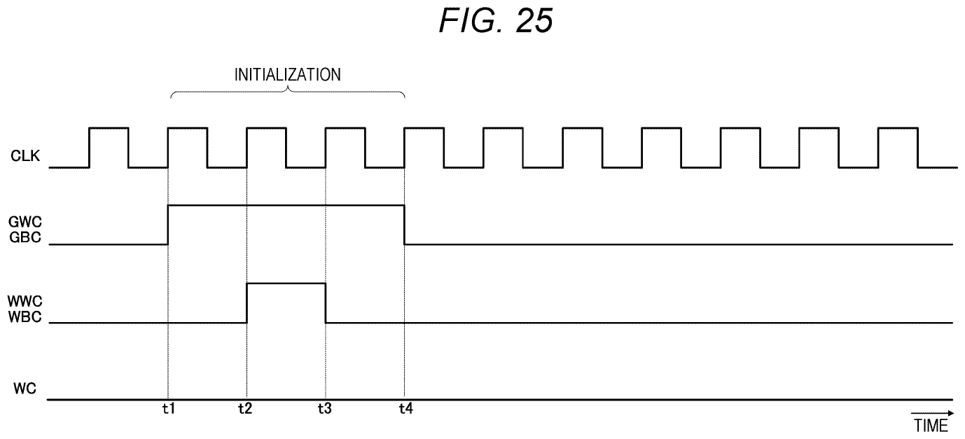

FIG. 25 is a timing chart illustrating a low-resistance write timing of a storage device according to the third embodiment.

In this figure, the low-resistance write timing of the third embodiment is similar to the low-resistance write timing of the first embodiment described above. However, in the low-resistance writing of the third embodiment, a selected cell is initialized. In this initialization, the selected cell is set to the low resistance state.

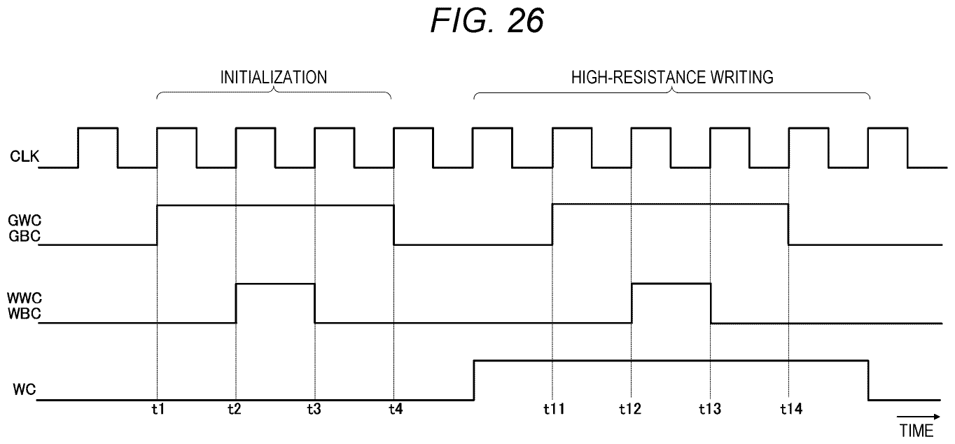

FIG. 26 is a timing chart illustrating a high-resistance write timing of the storage device according to the third embodiment.

In this figure, in the high-resistance writing of the third embodiment, the initialization of FIG. 25 is performed, and then the high-resistance writing is performed. The high-resistance write timing of the third embodiment is similar to the high-resistance write timing of the first embodiment described above.

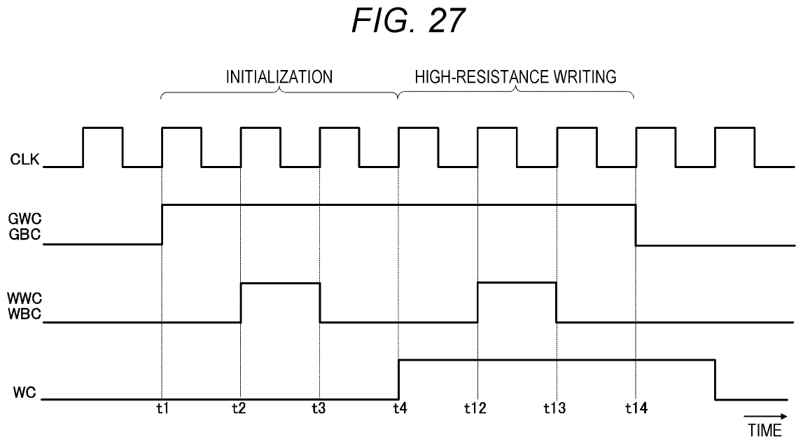

FIG. 27 is a timing chart illustrating a modification of the high-resistance write timing of the storage device according to the third embodiment.

In this figure, in the modification of the high-resistance writing of the third embodiment, the initialization of FIG. 25 is performed, and then the high-resistance writing is performed. However, in the modification of the high-resistance writing of the third embodiment, the high-resistance writing is performed immediately after the initialization. That is, in the high-resistance write timing in FIG. 26, switching signals GWC and GBC are caused to fall after the initialization, and then are raised again at the time of high-resistance writing. Whereas, in the high-resistance write timing in FIG. 27, the high-resistance writing is performed without causing the switching signals GWC and GBC to fall after the initialization. At this time, after switching signals WWC and WBC fall (t3), a control signal WC is raised (t4), and then the switching signals WWC and WBC are raised again (t12). In the method of FIG. 26, processing from the time t4 to the time t12 takes time of three clocks, whereas in the method of FIG. 27, the processing from the time t4 to the time t12 can be performed in time of one clock.

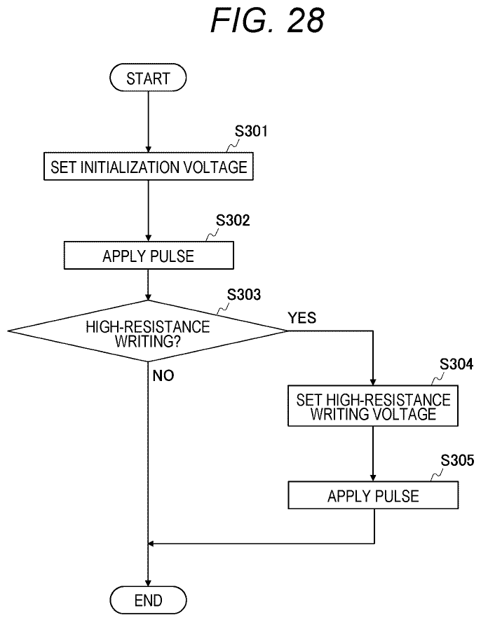

FIG. 28 is a flowchart illustrating a writing method of the storage device according to the third embodiment.

In this figure, a storage device 100 sets an initialization voltage (S301). The initialization voltage can be set similarly to a low-resistance writing voltage.

Next, the storage device 100 applies a voltage pulse to a selected word line SWL and the selected bit line SBL (S302). In the application of the voltage pulse, over the application period, a word line voltage VWLs of the selected word line SWL is set to Vw/2, and a bit line voltage VBLs of the selected bit line SBL is set to −Vw/2.

Next, the storage device 100 determines whether or not to be high-resistance writing (S303). In a case of low-resistance writing, the storage device 100 ends the processing. Whereas, in a case of the high-resistance writing, the storage device 100 sets a high-resistance writing voltage (S304).

Next, the storage device 100 applies a voltage pulse to the selected word line SWL and the selected bit line SBL (S305). In the application of the voltage pulse, over the application period, the word line voltage VWLs of the selected word line SWL is set to Vw/2, and the bit line voltage VBLs of the selected bit line SBL is set to −Vw/2.

In this way, in the third embodiment described above, a resistance state of the magnetoresistive effect element 111 is initialized, and high-resistance writing is performed in a case where the high-resistance writing is commanded. As a result, in a case where low-resistance writing is commanded, the low-resistance writing after the initialization of the resistance state of the magnetoresistive effect element 111 can be omitted.

Note that the writing method of the third embodiment described above may be applied to the storage device 100 of the first embodiment described above, or may be applied to the storage device 200 of the second embodiment described above.

### 4. Fourth Embodiment

In the first embodiment described above, resistance of the word line WL is controlled such that a reversing voltage applied to the magnetoresistive effect element 111 becomes equal in accordance with a resistance state of the magnetoresistive effect element 111. In this fourth embodiment, a memory cell MC in which resistance of a word line WL is controlled such that a reversing voltage applied to a magnetoresistive effect element 111 becomes equal in accordance with a resistance state of the magnetoresistive effect element 111 is applied to a multiply and accumulation (MAC) calculation.

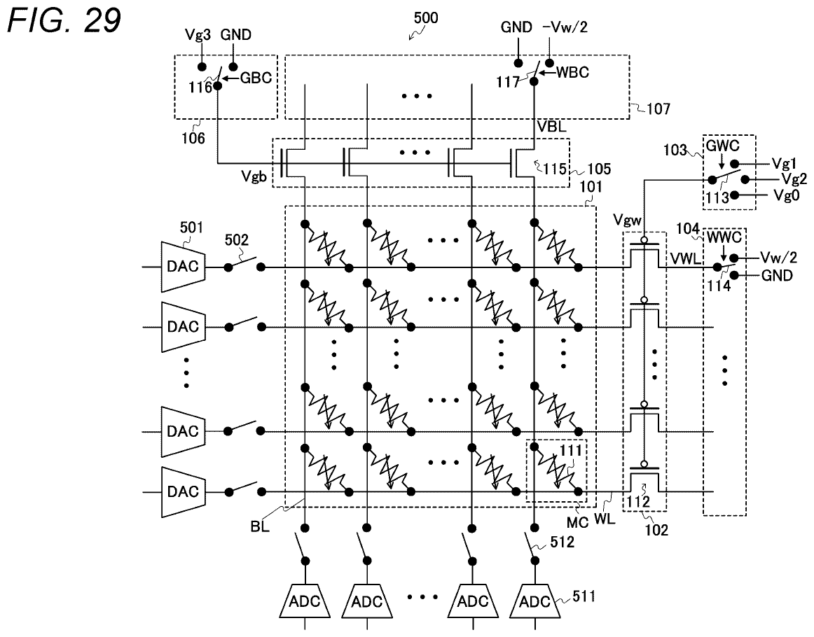

FIG. 29 is a diagram illustrating a configuration example of a processing device according to the fourth embodiment.

In this figure, in a processing device 500, a digital-to-analog (DA) converter 501 and an analog-to-digital (AD) converter 511 are added to the storage device 100 of the first embodiment described above. Other configurations of the processing device 500 of the fourth embodiment are similar to the configurations of the storage device 100 of the first embodiment described above.

The DA converter 501 performs DA-conversion on digital data, and outputs a DA-converted value to the word line WL via a switch 502. The DA converter 501 is provided for every row.

The AD converter 511 performs AD-conversion on a current flowing through each bit line BL, and outputs an AD-converted value via a switch 512. The AD converter 511 is provided for every column.

Here, an AD-converted value of each column output from each AD converter 511 can indicate, for every column, a MAC calculation result with, as a coefficient, a resistance state of the magnetoresistive effect element 111 connected to the word line WL selected via the switch 502. For example, each memory cell MC may store weights between nodes of a neural network in the magnetoresistive effect element 111, and a memory cell array 101 may perform MAC on the basis of inputs and weights of the neural network.

For writing into the magnetoresistive effect element 111 in a resistance state corresponding to the coefficient that is used for the MAC calculation, voltage waveforms similar to those in FIGS. 6 and 8 can be used. Furthermore, a timing and a flow of writing into the magnetoresistive effect element 111 in a resistance state corresponding to the coefficient that is used for the MAC calculation can be set similarly tp FIGS. 9 and 10.

Note that, in the MAC calculation, the word line WL may be input (high potential) and the bit line BL may be output, or vice versa. Furthermore, in writing, the bit line BL may be set to a high potential and the word line WL may be set to a low potential, or vice versa. However, from the viewpoint of the VCMA effect and disturbance, it is desirable that a relationship between a high potential and a low potential of the bit line BL and the word line WL be opposite to each other on a high potential side of the MAC calculation and a high potential side of writing. For example, the word line WL side may be set to a high potential in the MAC calculation, and the bit line BL side may be set to a high potential in the writing.

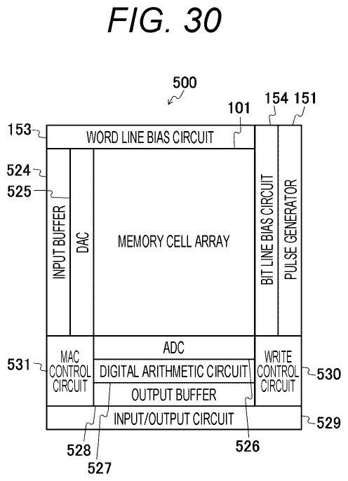

FIG. 30 is a block diagram illustrating a first example of an overall configuration of the processing device according to the fourth embodiment.

In this figure, the processing device 500 includes a memory cell array 101, a word line bias circuit 153, a bit line bias circuit 154, a pulse generator 151, an input buffer 524, a DA conversion unit 525, and an AD conversion unit 526. Furthermore, the processing device 500 includes a digital arithmetic circuit 527, an output buffer 528, an input/output circuit 529, a write control circuit 530, and a MAC control circuit 531.

The input buffer 524 temporarily holds input data input to the DA conversion unit 525. The DA conversion unit 525 includes the DA converter 501 for every row. The AD conversion unit 526 includes the AD converter 511 for every column.

The digital arithmetic circuit 527 performs digital arithmetic operation on the basis of the AD-converted value output from AD converter 526. The digital calculation may be threshold determination of the AD-converted value output from the AD conversion unit 526. The output buffer 528 temporarily holds an output from the digital arithmetic circuit 527. The input/output circuit 529 inputs input data to be used for the MAC calculation and outputs a MAC calculation result.

The write control circuit 530 performs write control on the magnetoresistive effect element 111 such that a resistance state corresponding to a coefficient that is used for the MAC calculation is set for the magnetoresistive effect element 111. The MAC control circuit 531 controls the MAC calculation using a resistance state of the magnetoresistive effect element 111 as a coefficient. At this time, the MAC control circuit 531 can perform on/off control of the switches 502 and 512 in accordance with the coefficient that is used for the MAC calculation.

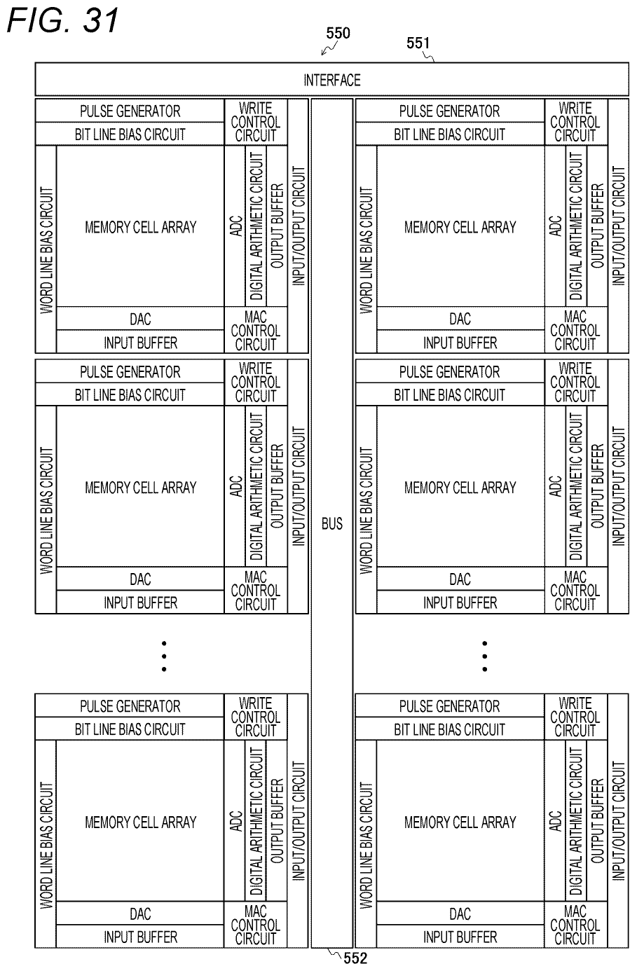

FIG. 31 is a block diagram illustrating a second example of an overall configuration of the processing device according to the fourth embodiment.

In this figure, the processing device 550 includes a plurality of memory cell arrays 101. The memory cell arrays 101 may be arranged in a matrix in a row direction and a column direction. Furthermore, the processing device 550 includes the word line bias circuit 153, the bit line bias circuit 154, the pulse generator 151, the input buffer 524, the DA conversion unit 525, and the AD conversion unit 526, for every memory cell array 101. Furthermore, the processing device 550 includes the digital arithmetic circuit 527, the output buffer 528, the input/output circuit 529, the write control circuit 530, and the MAC control circuit 531, for every memory cell array 101.

The input/output circuit 529 provided for every memory cell array 101 is connected to a bus 552. The bus 552 is connected to an interface 551. The interface 551 inputs input data to be used for the MAC calculation to the input/output circuit 529 via the bus 552, and outputs a MAC calculation result output from each input/output circuit 529 to an outside.

At this time, the processing device 550 can store weights between nodes of a multilayer neural network in each memory cell array 101 for every layer. Then, the MAC calculation result of each layer may be transferred between the memory cell arrays 101 via the bus 552, and the MAC calculation may be continuously performed.

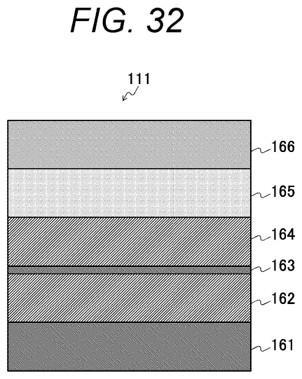

FIG. 32 is a cross-sectional view illustrating a first configuration example of a magnetoresistive effect element according to the fourth embodiment.

In this figure, the magnetoresistive effect element 111 has a structure in which a tunnel barrier layer 163 is sandwiched between a pin layer 162 and a free layer 164. At this time, the tunnel barrier layer 163 is stacked on the pin layer 162, and the free layer 164 is stacked on the tunnel barrier layer 163. A horizontal magnetic field generating layer 165 may be stacked on the free layer 164. The horizontal magnetic field generating layer 165 applies a magnetic field in a horizontal direction of the magnetoresistive effect element 111.

The pin layer 162 may be stacked on a base layer 161. A cap layer 166 may be stacked on the horizontal magnetic field generating layer 165.

As the base layer 161, for example, a layer including a noble metal or a transition metal element such as Cr, Ta, Ru, Au, Ag, Cu, Al, Ti, V, Mo, Zr, Hf, Re, W, Pt, Pd, Ir, or Rh, and a stacked structure thereof can be used. Furthermore, the base layer 161 can also be made containing a conductive nitride such as TiN. For example, the base layer 161 can be made containing a film for controlling a crystal orientation of the pin layer 162 and improving an adhesion strength for a lower electrode.

The cap layer 166 prevents diffusion of metal from a wiring member. This cap layer 166 can be made containing a metal such as Cr, Ta, Ru, Au, Ag, Cu, Al, Ti, V, Mo, Zr, Hf, Re, W, Pt, Pd, Ir, or Rh. Furthermore, the cap layer 166 can be made by a layer including an alloy containing these elements or a transition metal element. Furthermore, the cap layer 166 can also be made by stacking them. Furthermore, the cap layer 166 can also be made containing a conductive nitride such as TiN.

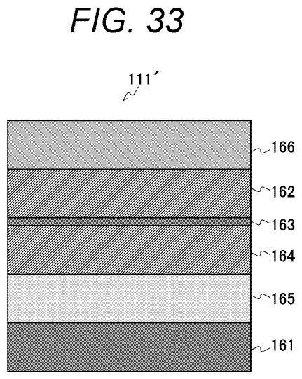

FIG. 33 is a cross-sectional view illustrating a second configuration example of the magnetoresistive effect element according to the fourth embodiment.

In this figure, in a magnetoresistive effect element 111′, the tunnel barrier layer 163 is stacked on the free layer 164, and the pin layer 162 is stacked on the tunnel barrier layer 163. The free layer 164 is stacked on the horizontal magnetic field generating layer 165. The horizontal magnetic field generating layer 165 is stacked on the base layer 161. The cap layer 166 is stacked on the pin layer 162.

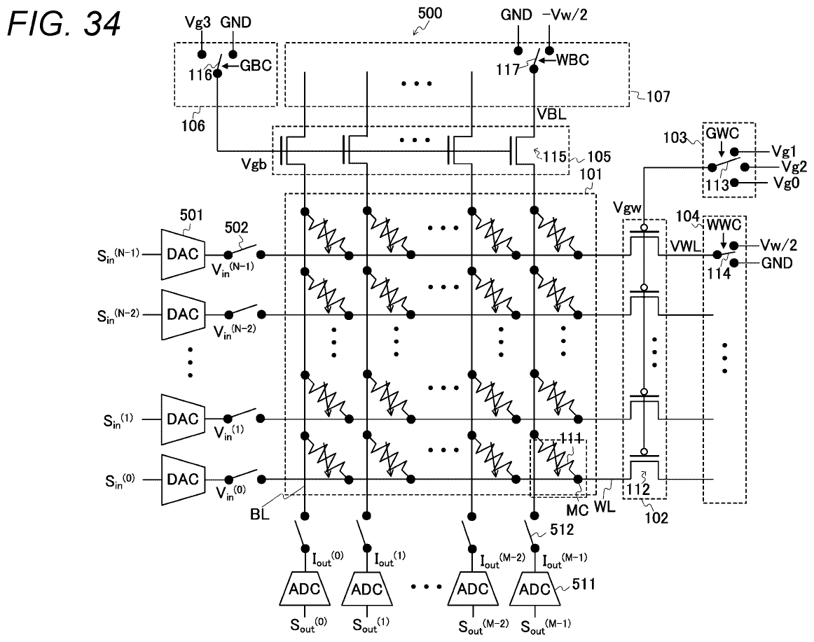

FIG. 34 is a diagram illustrating an input/output example of a signal of the processing device according to the fourth embodiment. Note that, in this figure, the number of rows is N (N is a positive integer), and the number of columns is M (M is a positive integer).

In this figure, N pieces of input data Sᵢₙ⁽ⁱ⁾ (i=0, . . . , N−1) are input to the respective DA converters 501 for every row. A bit depth and the like of each piece of input data Sᵢₙ⁽ⁱ⁾ (i=0, . . . , N−1) can be freely set.

Each piece of input data Sᵢₙ⁽ⁱ⁾ (i=0, . . . , N−1) is subjected to DA conversion for every row in each DA converter 501, and a DA-converted value Vᵢₙ(i) (i=0, . . . , N−1) is input to the word line WL for every row via the switch 502.

In a case where the resistance state of the magnetoresistive effect element 111 at each cross point of the word line WL and the bit line BL is high resistance, a small current flows through the magnetoresistive effect element 111 to the bit line BL. Whereas, in a case where the resistance state of the magnetoresistive effect element 111 at each cross point of the word line WL and the bit line BL is low resistance, a large current flows through the magnetoresistive effect element 111 to the bit line BL.

At this time, a current obtained by adding, for every column, currents flowing in the individual magnetoresistive effect elements 111 for every row flows through each bit line BL, and a current Tₒᵤₜ^{(j)} (j=0, . . . , M−1) is input to each AD converter 511 for every column via the switch 512.

Then, each current Tₒᵤₜ^{(j)} (j=0, . . . , M−1) is subjected to AD conversion for every column in each AD converter 511, and an AD-converted value Sₒᵤₜ^{(j)} (j=0, . . . , M−1) thereof is output from the AD converter 511 for every column. At this time, the memory cell array 101 can achieve MAC calculation using, as a coefficient, a resistance state of the magnetoresistive effect element 111 at each cross point. In this MAC calculation, when a resistance value of the magnetoresistive effect element 111 at each cross point is R_{i,j}, the current Tₒᵤₜ^{(j)} (j=0, . . . , M−1) can be given by the following equation.

$${I}_{out}^{( j )} = {\sum }_{í = 0}^{N} \frac{1}{{R}_{i , j}} * {V}_{i n}^{( i )} \qquad [ Math . 1 ]$$

At this time, a weight of the MAC calculation can be given with 1/R_{i, j}. The resistance value R_{i,j} takes mutually different values in the high resistance state and the low resistance state of the magnetoresistive effect element 111.

The processing device 500 may output an AD-converted value Sₒᵤₜ^{(j)} (j=0, . . . , M−1) for every column, or may output a converted value Tₒᵤₜ^{(j)} (j=0, . . . , M−1) via an activation function f ( ). At this time, the digital arithmetic circuit 527 can generate f(Sₒᵤₜ^{(j)}) obtained by converting the AD-converted value Sₒᵤₜ^{(j)} (j=0, . . . , M−1) with the activation function f ( ) and output the converted value Tₒᵤₜ^{(j)}=f(Sₒᵤₜ^{(j)}).

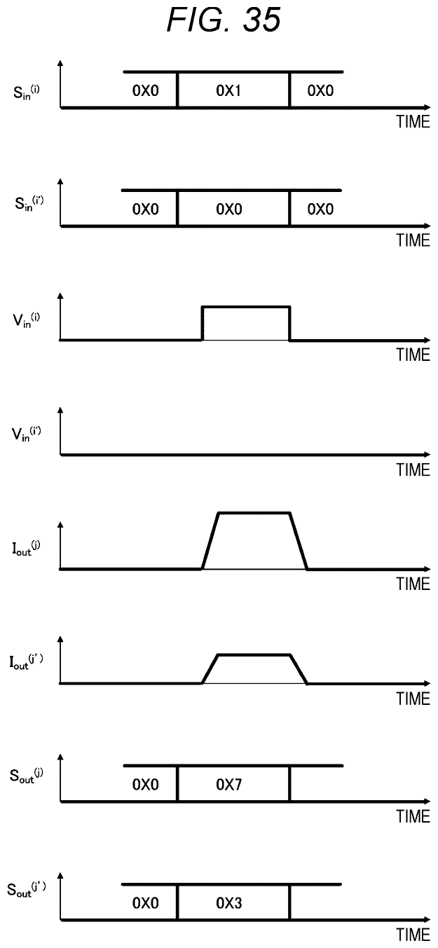

FIG. 35 is a diagram illustrating an example of input/output data and voltage waveforms of individual units at the time of MAC calculation of the processing device according to the fourth embodiment. Note that, in this figure, the input data Sᵢₙ⁽ⁱ⁾ and Sᵢₙ^{(I′)} and the AD-converted values Sₒᵤₜ^{(j)} and Sₒᵤₜ^{(j′)} are indicated in 16 decimal numbers.

In this figure, the input data Sᵢₙ⁽ⁱ⁾ and Sᵢₙ^{(I′)} of the i-th row and the i′-th row are input to the respective DA converters 501. The input data Sᵢₙ⁽ⁱ⁾ and Sᵢₙ^{(I′)} of the i-th row and the i′-th row are subjected to DA conversion for every row in the respective DA converters 501, and DA-converted values Vᵢₙ⁽ⁱ⁾ and Vᵢₙ^{(i′)} are input to the word lines WL for every row via the respective switches 502.

A current corresponding to a resistance state flows through each magnetoresistive effect element 111 at each cross point of the word line WL and the bit line BL, and currents Iₒᵤₜ^{(j)} and Tₒᵤₜ^{(j′)} flow through the individual bit lines BL. The currents Tₒᵤₜ^{(j)} and Iₒᵤₜ^{(j′)} are obtained by adding, for every row, currents flowing through the magnetoresistive effect elements 111 for every column.

Then, the currents Tₒᵤₜ^{(j)} and Iₒᵤₜ^{(j′)} flowing through the individual bit lines BL are input to the respective AD converter 511 via the switches 512 for every column. In the respective AD converter 511, the currents Tₒᵤₜ^{(j)} and Iₒᵤₜ^{(j′)} are subjected to AD-conversion for every column, and the AD-converted values Sₒᵤₜ^{(j)} and Sₒᵤₜ^{(j′)} are output from the AD converters 511 for every column.

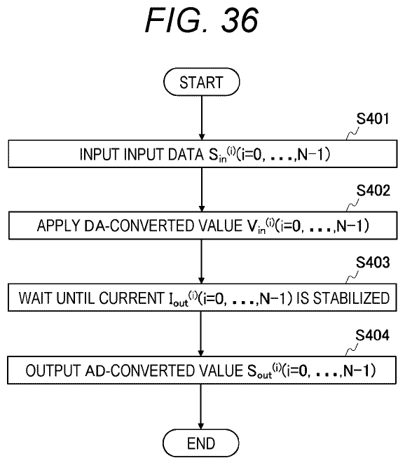

FIG. 36 is a flowchart illustrating an example of a MAC calculation method of the processing device according to the fourth embodiment.

In this figure, N pieces of input data Sᵢₙ⁽ⁱ⁾ (i=0, . . . , N−1) are input to the respective DA converters 501 for every row (S401). At this time, the MAC control circuit 531 inputs N pieces of input data Sᵢₙ⁽ⁱ⁾ (i=0, . . . , N−1) to the respective DA converters 501 via the input buffer 524.

Next, each DA converter 501 performs DA conversion on each piece of input data Sᵢₙ⁽ⁱ⁾ (i=0, . . . , N−1) for every row, and applies the DA-converted value Vᵢₙ⁽ⁱ⁾ (i=0, . . . , N−1) to the word line WL for every row via the switch 502 (S402). At this time, the current Tₒᵤₜ^{(j)} (j=0, . . . , M−1) flows through the bit line BL. The current Tₒᵤₜ^{(j)} is obtained by adding, for every column, currents flowing for every row in accordance with a resistance state of the magnetoresistive effect element 111 at each cross point of the word line WL and the bit line BL.

Here, since the current Tₒᵤₜ^{(j)} (j=0, . . . , M−1) flowing through the bit line BL varies depending on, for example, a wiring capacitance or the like, the processing waits until the current Iₒᵤₜ^{(j)} (j=0, . . . , M−1) flowing through the bit line BL is stabilized (S403).

Next, each AD converter 511 performs AD conversion on the current Tₒᵤₜ^{(j)} (j=0, . . . , M−1) flowing through each bit line BL for every column, and outputs the AD-converted value Sₒᵤₜ^{(j)} (j=0, . . . , M−1) for every column (S404).

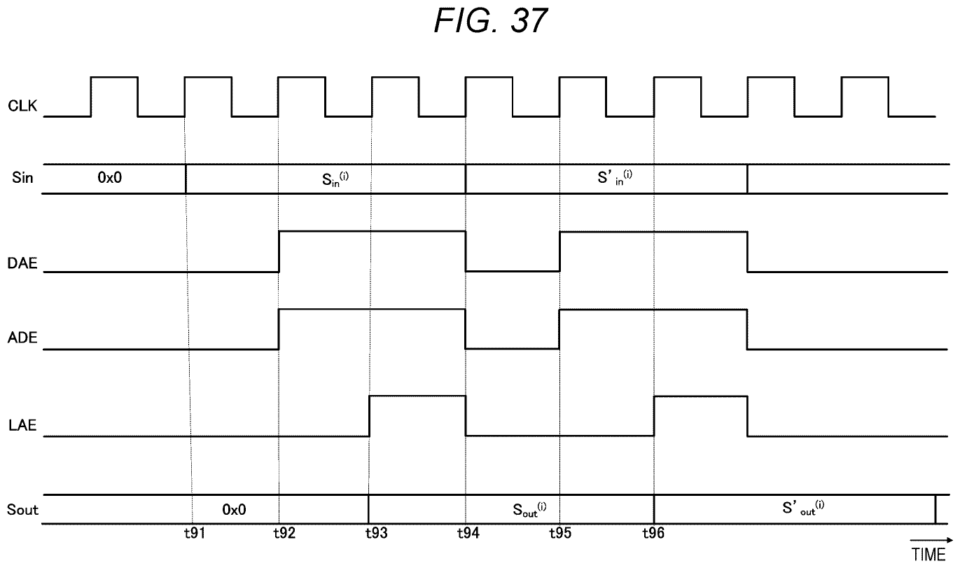

FIG. 37 is a timing chart illustrating a MAC calculation timing of the processing device according to the fourth embodiment.

In this figure, the MAC control circuit 531 inputs N pieces of input data Sᵢₙ⁽ⁱ⁾ to the input buffer 524 (time t91).

Next, the MAC control circuit 531 raises a DA enable signal DAE and an AD enable signal ADE (time t92). At this time, in each DA converter 501, the input data Sᵢₙ⁽ⁱ⁾ is subjected to DA conversion, and the DA-converted value Vᵢₙ⁽ⁱ⁾ is input to the word line WL via the switch 502. Then, the current Tₒᵤₜ^{(j)} flows through the bit line BL. The current Tₒᵤₜ^{(j)} is obtained by adding, for every column, currents flowing for every row in accordance with a resistance state of the magnetoresistive effect element 111 at each cross point of the word line WL and the bit line BL. At this time, in each AD converter 511, the current Iₒᵤₜ^{(j)} flowing through each bit line BL is subjected to AD conversion, and an AD-converted value Sₒᵤₜ^{(j)} is output for every column.

Next, when the current Tₒᵤₜ^{(j)} flowing through the bit line BL is stabilized, the MAC control circuit 531 raises a latch enable signal LAE (time t93). At this time, the AD-converted value Sₒᵤₜ^{(j)} output from each AD converter 511 is taken in and held in the output buffer 528. Note that, this figure has illustrated an example in which it takes time corresponding to one clock until the current Tₒᵤₜ^{(j)} flowing through the bit line BL is stabilized.

When the MAC calculation on the N pieces of input data Sᵢₙ⁽ⁱ⁾ is completed, the MAC control circuit 531 performs the MAC calculation on the next N pieces of input data S_{in′}⁽ⁱ⁾ (from time t94 to time t96).

Note that the processing device 500 may set a timing and a flow of writing into the magnetoresistive effect element 111 in a resistance state corresponding to a coefficient that is used for the MAC calculation, similarly to those in FIGS. 25 to 28.

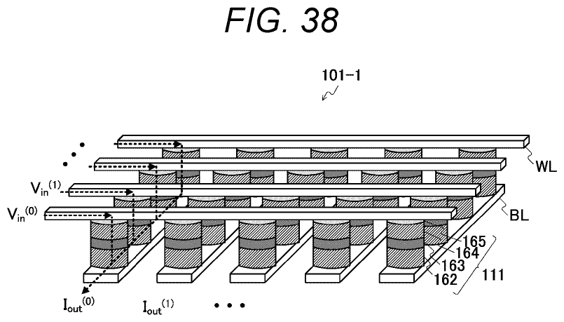

FIG. 38 is a perspective view illustrating an example of a memory cell array according to the fourth embodiment.

In this figure, in a memory cell array 101-1, the magnetoresistive effect elements 111 are arranged in a matrix in a row direction and a column direction. In each magnetoresistive effect element 111, the pin layer 162, the tunnel barrier layer 163, the free layer 164, and the horizontal magnetic field generating layer 165 are sequentially stacked.

In the memory cell array 101-1, the word line WL is provided for every row and the bit line BL is provided for every column such that an upper and lower sides of each magnetoresistive effect element 111 are sandwiched. Each magnetoresistive effect element 111 can be disposed at a cross point of each word line WL and each bit line BL. At this time, the DA-converted value Vᵢₙ⁽ⁱ⁾ (i=0, . . . , N−1) obtained by performing DA conversion on the input data Sᵢₙ⁽ⁱ⁾ (i=0, . . . , N−1) is input for every word line WL, and the current Iₒᵤₜ^{(j)} (j=0, . . . , M−1) is output for every bit line BL.

In this way, in the above-described fourth embodiment, the memory cell MC in which resistance of the word line WL is controlled such that a reversing voltage applied to the magnetoresistive effect element 111 becomes equal in accordance with a resistance state of the magnetoresistive effect elements 111 is applied to the MAC calculation. As a result, the MAC calculation can be performed in the memory cell array 101-1 by inputting the input data Sᵢₙ⁽ⁱ⁾ (i=0, . . . , N−1) for every word line WL. Therefore, since it is not necessary to separately provide an adder, a multiplier, and a register in order to achieve the MAC calculation, an increase in a circuit scale can be suppressed.

### 5. Fifth Embodiment

In the above-described fourth embodiment, the memory cell MC in which resistance of the word line WL is controlled such that a reversing voltage applied to the magnetoresistive effect element 111 becomes equal in accordance with a resistance state of the magnetoresistive effect element 111 is applied to MAC calculation. In this fifth embodiment, a memory cell MC in which resistance of a bit line BL is controlled such that a reversing voltage applied to a magnetoresistive effect element 111 becomes equal in accordance with a resistance state of the magnetoresistive effect element 111 is applied to MAC calculation.

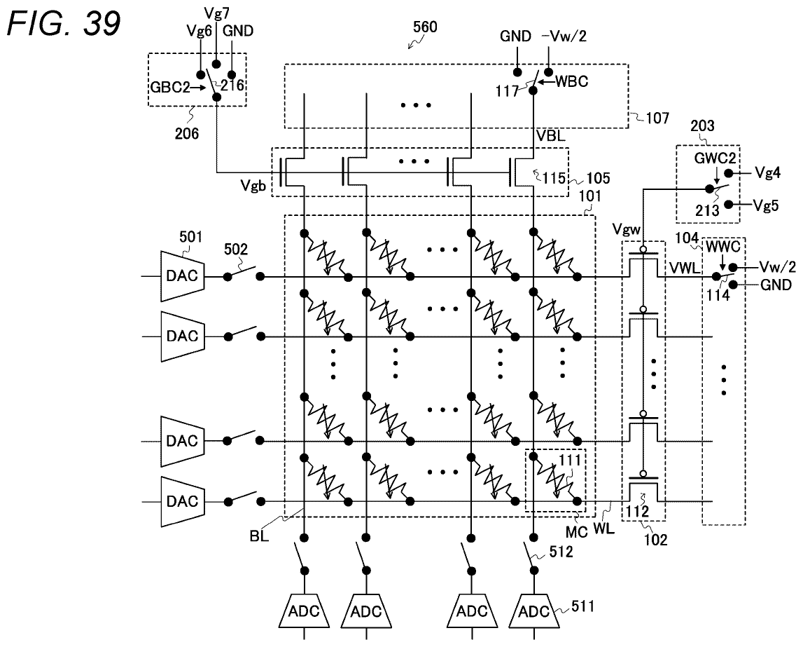

FIG. 39 is a diagram illustrating a configuration example of a processing device according to the fifth embodiment.

In this figure, in a processing device 560, a DA converter 501 and an AD converter 511 are added to the storage device 200 of the second embodiment described above. Other configurations of the processing device 560 of the fifth embodiment are similar to the configurations of the storage device 200 of the second embodiment described above.

Here, an AD-converted value of each column output from each AD converter 511 can indicate, for every column, a MAC calculation result with, as a coefficient, a resistance state of the magnetoresistive effect element 111 connected to a word line WL selected via the switch 502.

In the processing device 560, for writing into the magnetoresistive effect element 111 in a resistance state corresponding to the coefficient that is used for the MAC calculation, voltage waveforms similar to those in FIGS. 20 and 22 can be used. Furthermore, in the processing device 560, a timing and a flow of writing into the magnetoresistive effect element 111 in a resistance state corresponding to a coefficient that is used for the MAC calculation may be set similarly to those in FIGS. 9 and 10, or may be set similarly to those in FIGS. 25 to 28. Furthermore, in the processing device 560, a calculation timing and a flow in MAC calculation can be set similarly to FIGS. 36 and 37. Furthermore, in the processing device 560, a structure of a memory cell array 101 can be configured similarly to the memory cell array 101-1 of FIG. 38.

In this way, in the above-described fifth embodiment, the memory cell MC in which resistance of the bit line BL is controlled such that a reversing voltage applied to the magnetoresistive effect element 111 becomes equal in accordance with a resistance state of the magnetoresistive effect element 111 is applied to MAC calculation. As a result, the MAC calculation can be performed in the memory cell array 101-1 by inputting input data Sᵢₙ⁽ⁱ⁾ (i=0, . . . , N−1) for every word line WL. Therefore, since it is not necessary to separately provide an adder, a multiplier, and a register in order to achieve the MAC calculation, an increase in a circuit scale can be suppressed.

### 6. Sixth Embodiment

In the fourth embodiment described above, the memory cell array provided with the word line and the bit line has a one-layer structure, and the memory cell array is applied to the MAC calculation. In this sixth embodiment, a memory cell array to be applied to MAC calculation has a two-layer structure, and a word line and a bit line are alternately provided for every layer of the memory cell array.

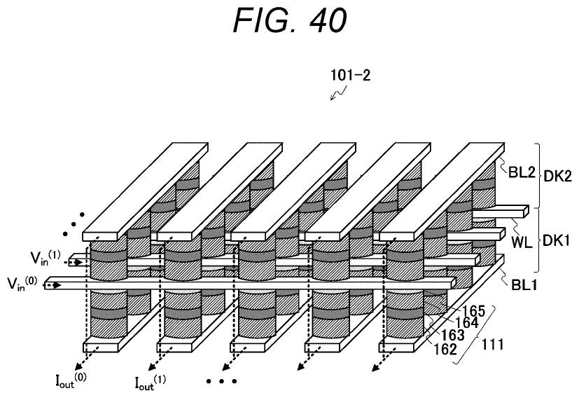

FIG. 40 is a perspective view illustrating an example of a memory cell array according to the sixth embodiment.

In this figure, in a memory cell array 101-2, the memory cell array 101-1 of the above-described fourth embodiment is stacked in two layers. At this time, the memory cell array 101-2 includes the memory cell array 101-1 for each of decks DK1 and DK2, and the deck DK2 is stacked on the deck DK1. However, in the memory cell array 101-2, a word line WL and bit lines BL1 and BL2 are alternately provided for every decks DK1 and DK2. At this time, the word line WL is shared by the decks DK1 and DK2.

Here, two magnetoresistive effect elements 111 disposed at a cross point of the word line WL and the bit lines BL1 and BL2 are connected in parallel to each other. In the MAC calculation, since a voltage is applied to the word line WL, a pin layer 162, a tunnel barrier layer 163, a free layer 164, and a horizontal magnetic field generating layer 165 are desirably stacked in this order so that disturbance does not occur. Writing on the magnetoresistive effect element 111 is performed in each of the decks DK1 and DK2. At this time, in the writing on the deck DK2, the word line WL has a low potential, and the bit line BL2 has a high potential.

In the MAC calculation, a DA-converted value Vᵢₙ⁽ⁱ⁾ (i=0, . . . , N−1) obtained by DA-conversion on input data Sᵢₙ⁽ⁱ⁾ (i=0, . . . , N−1) is input for every word line WL. Then, a current flowing for every row is added for every column in accordance with a resistance state of the magnetoresistive effect element 111 at each cross point of the word line WL and the bit lines BL1 and BL2, and the current flows to the bit lines BL1 and BL2. Then, a current Tₒᵤₜ^{(j)} (j=0, . . . , M−1) obtained by adding currents flowing through the individual bit lines BL1 and BL2 for every column is output from the bit line BL1 for every column.

At this time, the memory cell array 101-2 can achieve MAC calculation using, as a coefficient, a resistance state of parallel connection of the two magnetoresistive effect elements 111 at each cross point. In this MAC calculation, when a resistance value of the magnetoresistive effect element 111 of the deck DK1 at each cross point is R_{i,j}^{[0]}, and a resistance value of the magnetoresistive effect element 111 of the deck DK2 at each cross point is R_{i,j}^{[1]}, the current Tₒᵤₜ^{(j)} (j=0, . . . , M−1) can be given by the following equation.

$${I}_{out}^{( j )} = {\sum }_{i = 0}^{N} ( \frac{1}{{R}_{i , j}^{[ 0 ]}} + \frac{1}{{R}_{i , j}^{[ 1 ]}} ) * {V}_{i n}^{( i )} \qquad [ Math . 2 ]$$

Here, the resistance value of the magnetoresistive effect element 111 of each of the decks DK1 and DK2 in the low resistance state is assumed to be R, and the resistance value in the high resistance state is assumed to be aR (a>1). Note that “a” can be set to a value within a range of 3 to 8. At this time, assuming that the resistance state of the magnetoresistive effect element 111 of each of the decks DK1 and DK2 is low resistance, resistance R (LL) at each cross point can be given by the following equation.

$$\frac{1}{R ( LL )} = \frac{1}{{R}_{i , j}^{[ 0 ]}} + \frac{1}{{R}_{i , j}^{[ 1 ]}} = \frac{2}{R} \qquad [ Math . 3 ]$$

Assuming that the resistance state of one of the magnetoresistive effect elements 111 of the individual decks DK1 and DK2 is low resistance and the resistance state of another is high resistance, the resistance R (LH) at each cross point can be given by the following equation.

$$\frac{1}{R ( LH )} = \frac{1}{{R}_{i , j}^{[ 0 ]}} + \frac{1}{{R}_{i , j}^{[ 1 ]}} = \frac{1 + a}{aR} \qquad [ Math . 4 ]$$

Assuming that the resistance state of the magnetoresistive effect element 111 of each of the decks DK1 and DK2 is high resistance, resistance R (HH) at each cross point can be given by the following equation.

$$\frac{1}{R ( HH )} = \frac{1}{{R}_{i , j}^{[ 0 ]}} + \frac{1}{{R}_{i , j}^{[ 1 ]}} = \frac{2}{a R} \qquad [ Math . 5 ]$$

Currents I (LL), I (LH), and I (HH) flowing in respective resistances R (LL), R (LH), and R (HH) at each cross point with respect to a voltage V can be given by the following equation.

$$I ( L L ) = \frac{V}{R ( LL )} , I ( L H ) = \frac{V}{R ( LH )} , I ( HH ) = \frac{V}{R ( HH )} \qquad [ Math . 6 ]$$

At this time, a ratio of these currents I (LL), I (LH), and I (HH) can be given by the following formula.

$$\frac{I ( LL )}{I ( HH )} = a , \frac{I ( LH )}{I ( HH )} = \frac{1 + a}{2} , \frac{I ( HH )}{I ( HH )} = 1 \qquad [ Math . 7 ]$$

Therefore, parallel connection of the magnetoresistive effect elements 111 at each cross point can represent the resistance of three values. For example, if a=4 is satisfied, the current I (HH) flows in the resistance R (HH), the current I (LL)=4*I (HH) flows in the resistance R (LL), and the current I (LH)=2.5*I (HH), which is in a middle of these, flows in the resistance R (LH). At this time, an output can be equally divided, and the resistance of three values can be expressed.

Furthermore, a resistance ratio between the high resistance state and the low resistance state of the magnetoresistive effect element 111 is assumed to be “a”, and a resistance ratio of each of the magnetoresistive effect elements 111 of each of the decks DK1 and DK2 is assumed to be “b” (b>1). Note that, for example, “b” can be adjusted by changing a thickness of each magnetoresistive effect element 111. At this time, in the deck DK2, a resistance value in the low resistance state is bR, a resistance value in the high resistance state is abR, and a ratio of the currents I (LL), I (LH), I (HL), and I (HH) can be given by the following formula.

$$\frac{I ( LL )}{I ( HH )} = a , \frac{I ( LH )}{I ( HH )} = \frac{1 + a b}{1 + b} , \frac{I ( HL )}{I ( HH )} = \frac{a + b}{1 + b} , \frac{I ( HH )}{I ( HH )} = 1 \qquad [ Math . 8 ]$$

For example, a=4 and b=2 are satisfied. At this time, the current I (HH) flows in the resistance R (HH), the current I (LL)=4*I (HH) flows in the resistance R (LL), the current I (LH)=3*I (HH) flows in the resistance R (LH), and the current I (HL)=2*I (HH) flows in the resistance R (HL). At this time, the output can be equally divided, and the resistance of four values can be expressed.

Note that, the memory cell array 101-2 may be applied to the memory cell array 101 of the first embodiment described above, or may be applied to the memory cell array 101 of the second embodiment described above.

In the memory cell array 101-2, a timing and a flow of writing into the magnetoresistive effect element 111 in a resistance state corresponding to a coefficient that is used for the MAC calculation may be set similarly to those in FIGS. 9 and 10, or may be set similarly to those in FIGS. 25 to 28. A calculation timing and a flow in MAC calculation can be set similarly to FIGS. 36 and 37.

In a case where the memory cell array 101-2 is applied to the memory cell array 101 according to the first embodiment described above, for writing into the magnetoresistive effect element 111 in a resistance state corresponding to the coefficient that is used for the MAC calculation, voltage waveforms similar to those in FIGS. 6 and 8 can be used.

In a case where the memory cell array 101-2 is applied to the memory cell array 101 according to the second embodiment described above, for writing into the magnetoresistive effect element 111 in a resistance state corresponding to the coefficient that is used for the MAC calculation, voltage waveforms similar to those in FIGS. 20 and 22 can be used.

As described above, in the above-described sixth embodiment, the memory cell array 101-2 to be applied to the MAC calculation has a two-layer structure, and the word line WL and the bit lines BL1 and BL2 are alternately provided for every layers of the memory cell array 101-2. As a result, it becomes possible to perform the MAC calculation on the basis of a value stored in the magnetoresistive effect element 111 while ternarizing the stored value at each cross point of the word line WL and the bit lines BL1 and BL2. Therefore, it is possible to improve calculation performance while suppressing an increase in a plane size of the MAC calculation device.

### 7. Seventh Embodiment

In the above-described sixth embodiment, the memory cell array 101-2 to be applied to the MAC calculation has a two-layer structure, and the word line WL and the bit lines BL1 and BL2 are alternately provided for every layers of the memory cell array 101-2. In this seventh embodiment, a memory cell array to be applied to MAC calculation has a three-layer structure, and a word line and a bit line are alternately provided for every layer of the memory cell array.

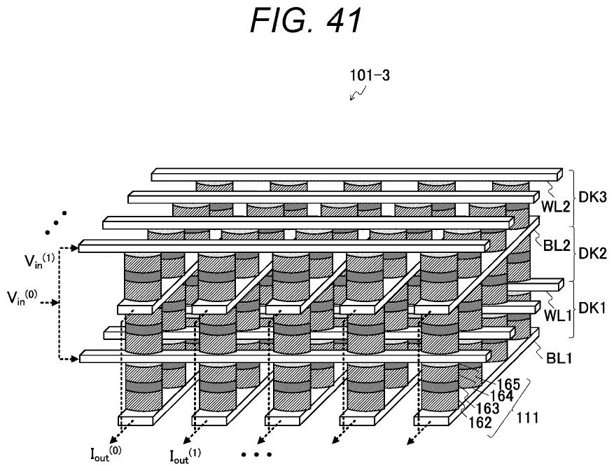

FIG. 41 is a perspective view illustrating an example of a memory cell array according to the seventh embodiment.

In this figure, in a memory cell array 101-3, the memory cell array 101-1 of the above-described fourth embodiment is stacked in three layers. At this time, the memory cell array 101-3 includes the memory cell array 101-1 for each of decks DK1 to DK3, the deck DK2 is stacked on the deck DK1, and the deck DK3 is stacked on the deck DK2. However, in the memory cell array 101-3, word lines WL1 and WL2 and bit lines BL1 and BL2 are alternately provided for every decks DK1 to DK3. At this time, the word line WL1 is shared by the decks DK1 and DK2, and the bit line BL2 is shared by the decks DK2 and DK3.

Here, three magnetoresistive effect elements 111 disposed at a cross point of the word lines WL1 and WL2 and the bit lines BL1 and BL2 are connected in parallel to each other. In the MAC calculation, since a voltage is applied to the word line WL, a pin layer 162, a tunnel barrier layer 163, a free layer 164, and a horizontal magnetic magnetic field generating layer 165 of the deck DK3 are desirably stacked in this order so that disturbance does not occur. Writing on the magnetoresistive effect element 111 is performed in each of the decks DK1 to DK3. At this time, in the writing on the deck DK3, the word line WL2 has a low potential, and the bit line BL2 has a high potential.

In the MAC calculation, a DA-converted value Vᵢₙ⁽ⁱ⁾ (i=0, . . . , N−1) obtained by DA-conversion on input data Sᵢₙ⁽ⁱ⁾ (i=0, . . . , N−1) is input to the word lines WL1 and WL2 for every row. Then, a current flowing for every row is added for every column in accordance with a resistance state of the magnetoresistive effect element 111 at each cross point of the word lines WL1 and WL2 and the bit lines BL1 and BL2, and the current flows to bit lines BL1 and BL2. Then, a current Iₒᵤₜ^{(j)} (j=0, . . . , M−1) obtained by adding currents flowing through the individual bit lines BL1 and BL2 for every column is output from the bit line BL1 for every column.

At this time, the memory cell array 101-3 can achieve MAC calculation using, as a coefficient, a resistance state of parallel connection of the three magnetoresistive effect elements 111 at each cross point. In this MAC calculation, when the resistance value of the magnetoresistive effect element 111 of each of the decks DK1 to DK3 at each cross point is R_{i,j}^{[k]} (k=0, 1, 2), a current Tₒᵤₜ^{(j)} (j=0, . . . , M−1) can be given by the following equation.

$${I}_{out}^{( j )} = {\sum }_{i = 0}^{N} ( {\sum }_{k = 0}^{2} \frac{1}{{R}_{i , j}^{[ k ]}} ) * {V}_{in}^{( i )} \qquad [ Math . 9 ]$$

A ratio between the low resistance state and the high resistance state of the magnetoresistive effect element 111 of each of the decks DK1 to DK3 is assumed to be a (a>1). A resistance ratio of the magnetoresistive effect elements 111 of the deck DK2 and the deck DK1 is assumed to be b₂, and a resistance ratio of the magnetoresistive effect elements 111 of the deck DK3 and the deck DK1 is assumed to be b₃. At this time, if a=4, b₂=2, and b₃=4 are satisfied, an output can be equally divided, and the resistance of eight values can be expressed.

Note that, the memory cell array 101-3 may be applied to the memory cell array 101 of the first embodiment described above, or may be applied to the memory cell array 101 of the second embodiment described above.

In the memory cell array 101-3, a timing and a flow of writing into the magnetoresistive effect element 111 in a resistance state corresponding to a coefficient that is used for the MAC calculation may be set similarly to those in FIGS. 9 and 10, or may be set similarly to those in FIGS. 25 to 28. A calculation timing and a flow in MAC calculation can be set similarly to FIGS. 36 and 37.

In a case where the memory cell array 101-3 is applied to the memory cell array 101 according to the first embodiment described above, for writing into the magnetoresistive effect element 111 in a resistance state corresponding to the coefficient that is used for the MAC calculation, voltage waveforms similar to those in FIGS. 6 and 8 can be used.

In a case where the memory cell array 101-3 is applied to the memory cell array 101 according to the second embodiment described above, for writing into the magnetoresistive effect element 111 in a resistance state corresponding to the coefficient that is used for the MAC calculation, voltage waveforms similar to those in FIGS. 20 and 22 can be used.

As described above, in the above-described seventh embodiment, the memory cell array 101-3 to be applied to the MAC calculation has a three-layer structure, and the word lines WL1 and WL2 and the bit lines BL1 and BL2 are alternately provided for every layers of the memory cell array 101-3. As a result, it becomes possible to perform the MAC calculation on the basis of a value stored in the magnetoresistive effect element 111 while multi-valuing the stored value at each cross point of the word lines WL1 and WL2 and the bit lines BL1 and BL2. Therefore, it is possible to improve calculation performance while suppressing an increase in a plane size of the MAC calculation device.

### 8. Eighth Embodiment

In the above-described seventh embodiment, the memory cell array 101-3 to be applied to the MAC calculation has a three-layer structure, and the word lines WL1 and WL2 and the bit lines BL1 and BL2 are alternately provided for every layers of the memory cell array 101-3. In this eighth embodiment, a memory cell array to be applied to MAC calculation has a three-layer structure, and a word line and a bit line are provided for every layer of the memory cell array.

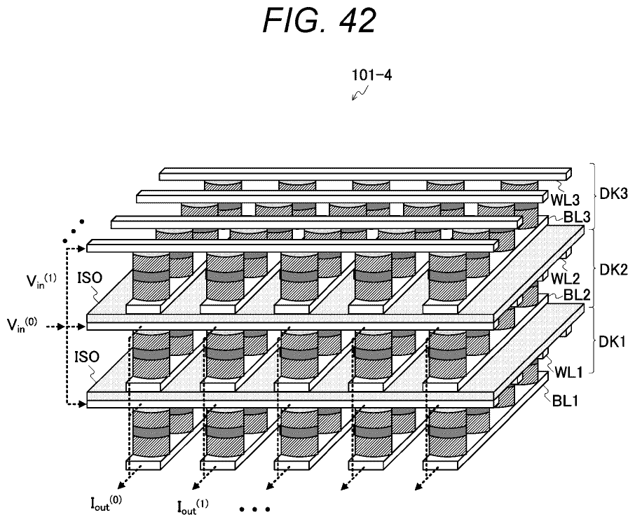

FIG. 42 is a perspective view illustrating an example of a memory cell array according to the eighth embodiment.

In this figure, in a memory cell array 101-4, the memory cell array 101-1 of the above-described fourth embodiment is stacked in three layers. At this time, the memory cell array 101-4 includes the memory cell array 101-1 for each of decks DK1 to DK3, the deck DK2 is stacked on the deck DK1, and the deck DK3 is stacked on the deck DK2. Between the decks DK1 and DK2 and between the decks DK2 and DK3, a separation layer ISO is provided. The separation layer ISO can be made containing, for example, an insulator such as SiO₂.

Here, three magnetoresistive effect elements 111 disposed at a cross point of word lines WL1 to WL3 and the bit lines BL1 to BL3 are connected in parallel to each other. In the MAC calculation, since a voltage is applied from the word lines WL1 to WL3, a pin layer 162, a tunnel barrier layer 163, a free layer 164, and a horizontal magnetic field generating layer 165 of each of the decks DK1 to DK3 are desirably stacked in this order so that disturbance does not occur. Writing on the magnetoresistive effect element 111 is performed in each of the decks DK1 to DK3.

In the MAC calculation, a DA-converted value Vᵢₙ⁽ⁱ⁾ (i=0, . . . , N−1) obtained by DA-conversion on input data Sᵢₙ⁽ⁱ⁾ (i=0, . . . , N−1) is input to the word lines WL1 to WL3 for every row. Then, a current flowing for every row is added for every column in accordance with a resistance state of the magnetoresistive effect element 111 at each cross point of the word lines WL1 to WL3 and the bit lines BL1 to BL3, and the current flows to the bit lines BL1 to BL3. Then, a current Iₒᵤₜ^{(j)} (j=0, . . . , M−1) obtained by adding currents flowing through the individual bit lines BL1 to BL3 for every column is output from the bit line BL1 for every column.

Note that, the memory cell array 101-4 may be applied to the memory cell array 101 of the first embodiment described above, or may be applied to the memory cell array 101 of the second embodiment described above.

In the memory cell array 101-4, a timing and a flow of writing into the magnetoresistive effect element 111 in a resistance state corresponding to a coefficient that is used for the MAC calculation may be set similarly to those in FIGS. 9 and 10, or may be set similarly to those in FIGS. 25 to 28. A calculation timing and a flow in MAC calculation can be set similarly to FIGS. 36 and 37.

In a case where the memory cell array 101-4 is applied to the memory cell array 101 according to the first embodiment described above, for writing into the magnetoresistive effect element 111 in a resistance state corresponding to the coefficient that is used for the MAC calculation, voltage waveforms similar to those in FIGS. 6 and 8 can be used.

In a case where the memory cell array 101-4 is applied to the memory cell array 101 according to the second embodiment described above, for writing into the magnetoresistive effect element 111 in a resistance state corresponding to the coefficient that is used for the MAC calculation, voltage waveforms similar to those in FIGS. 20 and 22 can be used.

As described above, in the above-described eighth embodiment, the memory cell array 101-4 to be applied to the MAC calculation has a three-layer structure, and the word lines WL1 to WL3 and the bit lines BL1 to BL3 are individually provided for every layers of the memory cell array 101-4. As a result, it becomes possible to perform the MAC calculation on the basis of a value stored in the magnetoresistive effect elements 111 while multi-valuing the stored value at each cross point of the word lines WL1 to WL3 and the bit lines BL1 to BL3. Therefore, it is possible to improve calculation performance while suppressing an increase in a plane size of the MAC calculation device.

### 9. Ninth Embodiment

In the above-described seventh embodiment, the memory cell array 101-3 to be applied to the MAC calculation has a three-layer structure, and the word lines WL1 and WL2 and the bit lines BL1 and BL2 are alternately provided for every layers of the memory cell array 101-3. In this ninth embodiment, a memory cell array to be applied to MAC calculation has a four-layer structure, and a word line and a bit line are alternately provided for every layer of the memory cell array.

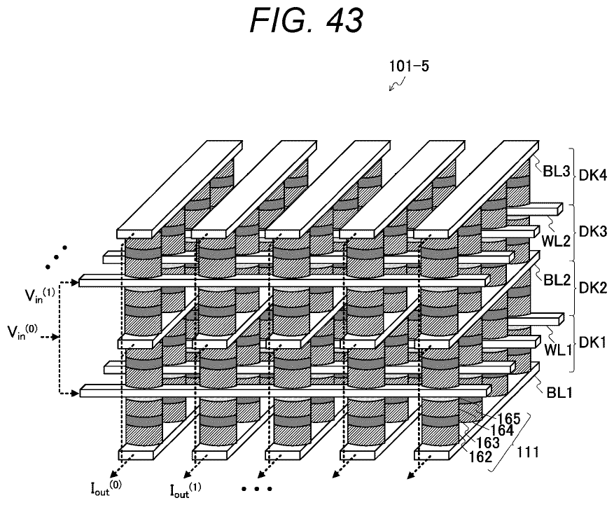

FIG. 43 is a perspective view illustrating an example of a memory cell array according to the ninth embodiment.

In this figure, in a memory cell array 101-5, the memory cell array 101-1 of the above-described fourth embodiment is stacked in four layers. At this time, the memory cell array 101-5 includes the memory cell array 101-1 for each of decks DK1 to DK4, the deck DK2 is stacked on the deck DK1, the deck DK3 is stacked on the deck DK2, and the deck DK4 is stacked on the deck DK3. However, in the memory cell array 101-5, word lines WL1 and WL2 and bit lines BL1 to BL3 are alternately provided for every decks DK1 to DK4. At this time, the word line WL1 is shared by the decks DK1 and DK2, the bit line BL2 is shared by the decks DK2 and DK3, and the word line WL2 is shared by the decks DK3 and DK4.

Here, four magnetoresistive effect elements 111 disposed at a cross point of the word lines WL1 and WL2 and the bit lines BL1 to BL3 are connected in parallel to each other. In the MAC calculation, since a voltage is applied to the word lines WL1 and WL2, a pin layer 162, a tunnel barrier layer 163, a free layer 164, and a horizontal magnetic field generating layer 165 of the deck DK4 are desirably stacked in this order so that disturbance does not occur. Writing on the magnetoresistive effect element 111 is performed in each of the decks DK1 to DK4. At this time, in the writing on the deck DK4, the word line WL2 has a low potential, and the bit line BL3 has a high potential.

In the MAC calculation, a DA-converted value Vᵢₙ⁽ⁱ⁾ (i=0, . . . , N−1) obtained by DA-conversion on input data Sᵢₙ⁽ⁱ⁾ (i=0, . . . , N−1) is input to the word lines WL1 and WL2 for every row. Then, a current flowing for every row is added for every column in accordance with a resistance state of the magnetoresistive effect element 111 at each cross point of the word lines WL1 and WL2 and the bit lines BL1 to BL3, and the current flows to the bit lines BL1 to BL3. Then, a current Tₒᵤₜ^{(j)} (j=0, . . . , M−1) obtained by adding currents flowing through the individual bit lines BL1 to BL3 for every column is output from the bit line BL1 for every column.

At this time, the memory cell array 101-5 can achieve MAC calculation using, as a coefficient, a resistance state of parallel connection of the four magnetoresistive effect elements 111 at each cross point. In this MAC calculation, when the resistance value of the magnetoresistive effect element 111 of each of the decks DK1 to DK4 at each cross point is R_{i,j}^{[k]} (k=0, 1, 2.3), the current Tₒᵤₜ^{(j)} (j=0, . . . , M−1) can be given by the following equation.

$${I}_{out}^{( j )} = {\sum }_{i = 0}^{N} ( {\sum }_{k = 0}^{3} \frac{1}{{R}_{i , j}^{[ k ]}} ) * {V}_{in}^{( i )} \qquad [ Math . 10 ]$$

A ratio between the low resistance state and the high resistance state of the magnetoresistive effect element 111 of each of the decks DK1 to DK3 is assumed to be a (a>1). A resistance ratio of the magnetoresistive effect elements 111 of the deck DK2 and the deck DK1 is assumed to be b₂, a resistance ratio of the magnetoresistive effect elements 111 of the deck DK3 and the deck DK1 is assumed to be b₃, and a resistance ratio of the magnetoresistive effect elements 111 of the deck DK4 and the deck DK1 is assumed to be b₄. At this time, if a=4, b₂=2, b₃=4, and b₄=8 are satisfied, an output can be equally divided, and the resistance of sixteen values can be expressed.

Note that, the memory cell array 101-5 may be applied to the memory cell array 101 of the first embodiment described above, or may be applied to the memory cell array 101 of the second embodiment described above.

In the memory cell array 101-5, a timing and a flow of writing into the magnetoresistive effect element 111 in a resistance state corresponding to a coefficient that is used for the MAC calculation may be set similarly to those in FIGS. 9 and 10, or may be set similarly to those in FIGS. 25 to 28. A calculation timing and a flow in MAC calculation can be set similarly to FIGS. 36 and 37.

In a case where the memory cell array 101-5 is applied to the memory cell array 101 according to the first embodiment described above, for writing into the magnetoresistive effect element 111 in a resistance state corresponding to the coefficient that is used for the MAC calculation, voltage waveforms similar to those in FIGS. 6 and 8 can be used.

In a case where the memory cell array 101-5 is applied to the memory cell array 101 according to the second embodiment described above, for writing into the magnetoresistive effect element 111 in a resistance state corresponding to the coefficient that is used for the MAC calculation, voltage waveforms similar to those in FIGS. 20 and 22 can be used.

As described above, in the above-described ninth embodiment, the memory cell array 101-5 to be applied to the MAC calculation has a four-layer structure, and the word lines WL1 and WL2 and the bit lines BL1 to BL3 are alternately provided for every layers of the memory cell array 101-5. As a result, it becomes possible to perform the MAC calculation on the basis of a value stored in the magnetoresistive effect elements 111 while multi-valuing the stored value at each cross point of the word lines WL1 and WL2 and the bit lines BL1 to BL3. Therefore, it is possible to improve calculation performance while suppressing an increase in a plane size of the MAC calculation device.

### 10. Tenth Embodiment

In the above-described eighth embodiment, the memory cell array 101-4 to be applied to the MAC calculation has a three-layer structure, and the word lines WL1 to WL3 and the bit lines BL1 to BL3 are individually provided for every layers of the memory cell array 101-4. In this tenth embodiment, a memory cell array to be applied to MAC calculation has a four-layer structure, and a word line and a bit line are individually provided for every layer of the memory cell array.

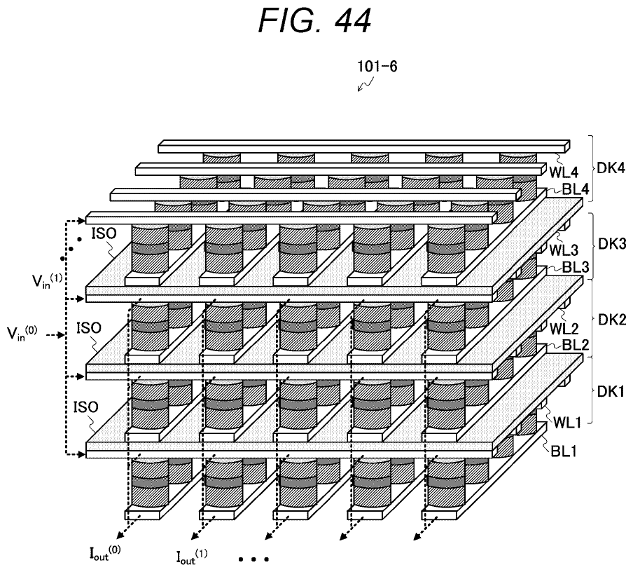

FIG. 44 is a perspective view illustrating an example of a memory cell array according to the tenth embodiment.

In this figure, in a memory cell array 101-6, the memory cell array 101-1 of the above-described fourth embodiment is stacked in four layers. At this time, the memory cell array 101-6 includes the memory cell array 101-1 for each of decks DK1 to DK4, the deck DK2 is stacked on the deck DK1, the deck DK3 is stacked on the deck DK2, and the deck DK4 is stacked on the deck DK3. Between the decks DK1 and DK2, between the decks DK2 and DK3, and between the decks DK3 and DK4, a separation layer ISO is provided.

Here, four magnetoresistive effect elements 111 disposed at a cross point of word lines WL1 to WL4 and bit lines BL1 to BL4 are connected in parallel to each other. In the MAC calculation, since a voltage is applied from the word lines WL1 to WL4, a pin layer 162, a tunnel barrier layer 163, a free layer 164, and a horizontal magnetic field generating layer 165 of each of the decks DK1 to DK4 are desirably stacked in this order so that disturbance does not occur. Writing on the magnetoresistive effect element 111 is performed in each of the decks DK1 to DK4.

In the MAC calculation, a DA-converted value Vᵢₙ⁽ⁱ⁾ (i=0, . . . , N−1) obtained by DA-conversion on input data Sᵢₙ⁽ⁱ⁾ (i=0, . . . , N−1) is input to the word lines WL1 to WL4 for every row. Then, a current flowing for every row is added for every column in accordance with a resistance state of the magnetoresistive effect element 111 at each cross point of the word lines WL1 to WL4 and the bit lines BL1 to BL4, and the current flows to the bit lines BL1 to BL4. Then, a current Iₒᵤₜ^{(j)} (j=0, . . . , M−1) obtained by adding currents flowing through the individual bit lines BL1 to BL4 for every column is output from each bit line BL1 for every column.

Note that, the memory cell array 101-6 may be applied to the memory cell array 101 of the first embodiment described above, or may be applied to the memory cell array 101 of the second embodiment described above.

In the memory cell array 101-6, a timing and a flow of writing into the magnetoresistive effect element 111 in a resistance state corresponding to a coefficient that is used for the MAC calculation may be set similarly to those in FIGS. 9 and 10, or may be set similarly to those in FIGS. 25 to 28. A calculation timing and a flow in MAC calculation can be set similarly to FIGS. 36 and 37.

In a case where the memory cell array 101-6 is applied to the memory cell array 101 according to the first embodiment described above, for writing into the magnetoresistive effect element 111 in a resistance state corresponding to the coefficient that is used for the MAC calculation, voltage waveforms similar to those in FIGS. 6 and 8 can be used.

In a case where the memory cell array 101-6 is applied to the memory cell array 101 according to the second embodiment described above, for writing into the magnetoresistive effect element 111 in a resistance state corresponding to the coefficient that is used for the MAC calculation, voltage waveforms similar to those in FIGS. 20 and 22 can be used.

As described above, in the above-described tenth embodiment, the memory cell array 101-6 to be applied to the MAC calculation has a four-layer structure, and the word lines WL1 to WL4 and the bit lines BL1 to BL4 are individually provided for every layers of the memory cell array 101-6. As a result, it becomes possible to perform the MAC calculation on the basis of a value stored in the magnetoresistive effect elements 111 while multi-valuing the stored value at each cross point of the word lines WL1 to WL4 and the bit lines BL1 to BL4. Therefore, it is possible to improve calculation performance while suppressing an increase in a plane size of the MAC calculation device.

### 11. Eleventh Embodiment

In the above-described ninth embodiment, the memory cell array 101-5 to be applied to the MAC calculation has a four-layer structure, and the word lines WL1 and WL2 and the bit lines BL1 to BL3 are alternately provided for every layers of the memory cell array 101-5. In this eleventh embodiment, a memory cell array to be applied to the MAC calculation has a six-layer structure, and a word line and a bit line are alternately provided for every layer of the memory cell array.

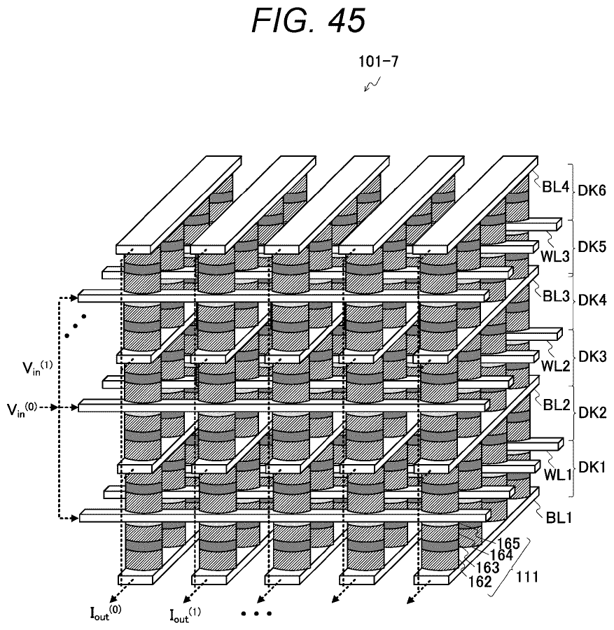

FIG. 45 is a perspective view illustrating an example of a memory cell array according to the eleventh embodiment.

In this figure, in a memory cell array 101-7, the memory cell array 101-1 of the above-described fourth embodiment is stacked in six layers. At this time, the memory cell array 101-7 includes the memory cell array 101-1 for each of decks DK1 to DK6. Then, the deck DK2 is stacked on the deck DK1, the deck DK3 is stacked on the deck DK2, the deck DK4 is stacked on the deck DK3, the deck DK5 is stacked on the deck DK4, and the deck DK6 is stacked on the deck DK5. However, in the memory cell array 101-7, word lines WL1 to WL3 and bit lines BL1 to BL4 are alternately provided for every decks DK1 to DK6. At this time, the word line WL1 is shared by the decks DK1 and DK2, the bit line BL2 is shared by the decks DK2 and DK3, and the word line WL2 is shared by the decks DK3 and DK4. Furthermore, the bit line BL3 is shared by the decks DK4 and DK5, and the word line WL3 is shared by the decks DK5 and DK6.

Here, six magnetoresistive effect elements 111 disposed at a cross point of the word lines WL1 to WL3 and the bit lines BL1 to BL4 are connected in parallel to each other. In the MAC calculation, since a voltage is applied to the word lines WL1 to WL3, a pin layer 162, a tunnel barrier layer 163, a free layer 164, and a horizontal magnetic field generating layer 165 of the deck DK6 are desirably stacked in this order so that disturbance does not occur. Writing on the magnetoresistive effect element 111 is performed in each of the decks DK1 to DK6. At this time, in the writing on the deck DK6, the word line WL2 has a low potential, and the bit line BL3 has a high potential.

In the MAC calculation, a DA-converted value Vᵢₙ⁽ⁱ⁾ (i=0, . . . , N−1) obtained by DA-conversion on input data Sᵢₙ⁽ⁱ⁾ (i=0, . . . , N−1) is input to the word lines WL1 to WL3 for every row. Then, a current flowing for every row is added for every column in accordance with a resistance state of the magnetoresistive effect element 111 at each cross point of the word lines WL1 to WL3 and the bit lines BL1 to BL4, and the current flows to the bit lines BL1 to BL4. Then, a current Iₒᵤₜ^{(j)} (j=0, . . . , M−1) obtained by adding currents flowing through the individual bit lines BL1 to BL4 for every column is output from the bit line BL1 for every column.

At this time, the memory cell array 101-7 can achieve MAC calculation using, as a coefficient, a resistance state of parallel connection of the six magnetoresistive effect elements 111 at each cross point. In this MAC calculation, when the resistance value of the magnetoresistive effect element 111 of each of the decks DK1 to DK6 at each cross point is R_{i,j}^{[k]} (k=0, 1, 2, 3, 4, 5), a current Tₒᵤₜ^{(j)} (j=0, . . . , M−1) can be given by the following equation.

$${I}_{out}^{( j )} = {\sum }_{i = 0}^{N} ( {\sum }_{k = 0}^{5} \frac{1}{{R}_{i , j}^{[ k ]}} ) * {V}_{in}^{( i )} \qquad [ Math . 11 ]$$

A ratio between the low resistance state and the high resistance state of the magnetoresistive effect element 111 of each of the decks DK1 to DK6 is assumed to be a (a>1). A resistance ratio of the magnetoresistive effect elements 111 of the deck DK2 and the deck DK1 is assumed to be b₂, a resistance ratio of the magnetoresistive effect elements 111 of the deck DK3 and the deck DK1 is assumed to be b₃, and a resistance ratio of the magnetoresistive effect elements 111 of the deck DK4 and the deck DK1 is assumed to be b₄. Furthermore, a resistance ratio of the magnetoresistive effect elements 111 of the deck DK5 and the deck DK1 is assumed to be bs, and a resistance ratio of the magnetoresistive effect elements 111 of the deck DK6 and the deck DK1 is assumed to be b₄. At this time, if a=4, b₂=2, b₃=4, b₄=8, b₅=16, and b₆=32 are satisfied, an output can be equally divided, and the resistance of 64 values can be expressed.

Note that, the memory cell array 101-7 may be applied to the memory cell array 101 of the first embodiment described above, or may be applied to the memory cell array 101 of the second embodiment described above.

In the memory cell array 101-7, a timing and a flow of writing into the magnetoresistive effect element 111 in a resistance state corresponding to a coefficient that is used for the MAC calculation may be set similarly to those in FIGS. 9 and 10, or may be set similarly to those in FIGS. 25 to 28. A calculation timing and a flow in MAC calculation can be set similarly to FIGS. 36 and 37.

In a case where the memory cell array 101-7 is applied to the memory cell array 101 according to the first embodiment described above, for writing into the magnetoresistive effect element 111 in a resistance state corresponding to the coefficient that is used for the MAC calculation, voltage waveforms similar to those in FIGS. 6 and 8 can be used.

In a case where the memory cell array 101-7 is applied to the memory cell array 101 according to the second embodiment described above, for writing into the magnetoresistive effect element 111 in a resistance state corresponding to the coefficient that is used for the MAC calculation, voltage waveforms similar to those in FIGS. 20 and 22 can be used.

As described above, in the above-described eleventh embodiment, the memory cell array 101-7 to be applied to the MAC calculation has a six-layer structure, and the word lines WL1 to WL3 and the bit lines BL1 to BL4 are alternately provided for every layers of the memory cell array 101-7. As a result, it becomes possible to perform the MAC calculation on the basis of a value stored in the magnetoresistive effect elements 111 while multi-valuing the stored value at each cross point of the word lines WL1 to WL3 and the bit lines BL1 to BL4. Therefore, it is possible to improve calculation performance while suppressing an increase in a plane size of the MAC calculation device.

### 12. Twelfth Embodiment

In the above-described tenth embodiment, the memory cell array 101-6 to be applied to the MAC calculation has a four-layer structure, and the word lines WL1 to WL4 and the bit lines BL1 to BL4 are individually provided for every layers of the memory cell array 101-6. In this twelfth embodiment, a memory cell array to be applied to MAC calculation has a six-layer structure, and a word line and a bit line are individually provided for every layer of the memory cell array.

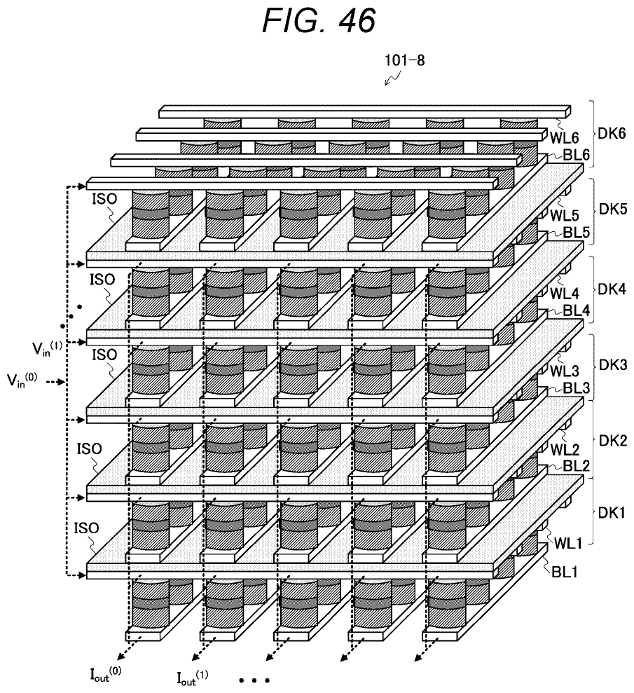

FIG. 46 is a perspective view illustrating an example of a memory cell array according to the twelfth embodiment.

In this figure, in a memory cell array 101-8, the memory cell array 101-1 of the above-described fourth embodiment is stacked in six layers. At this time, the memory cell array 101-8 includes the memory cell array 101-1 for each of decks DK1 to DK6, the deck DK2 is stacked on the deck DK1, the deck DK3 is stacked on the deck DK2, and the deck DK4 is stacked on the deck DK3. Furthermore, the deck DK5 is stacked on the deck DK4, and the deck DK6 is stacked on the deck DK5. Between the decks DK1 and DK2, between the decks DK2 and DK3, between the decks DK3 and DK4, between the decks DK4 and DK5, and between the decks DK5 and DK6, a separation layer ISO is provided.

Here, six magnetoresistive effect elements 111 disposed at a cross point of word lines WL1 to WL6 and bit lines BL1 to BL6 are connected in parallel to each other. In the MAC calculation, since a voltage is applied from the word lines WL1 to WL6, a pin layer 162, a tunnel barrier layer 163, a free layer 164, and a horizontal magnetic field generating layer 165 of each of the decks DK1 to DK6 are desirably stacked in this order so that disturbance does not occur. Writing on the magnetoresistive effect element 111 is performed in each of the decks DK1 to DK6.

In the MAC calculation, a DA-converted value Vᵢₙ⁽ⁱ⁾ (i=0, . . . , N−1) obtained by DA-conversion on input data Sᵢₙ⁽ⁱ⁾ (i=0, . . . , N−1) is input to the word lines WL1 to WL6 for every row. Then, a current flowing for every row is added for every column in accordance with a resistance state of the magnetoresistive effect element 111 at each cross point of the word lines WL1 to WL6 and the bit lines BL1 to BL6, and the current flows to the bit lines BL1 to BL6. Then, a current Iₒᵤₜ^{(j)} (j=0, . . . , M−1) obtained by adding currents flowing through the individual bit lines BL1 to BL6 for every column is output from the bit line BL1 for every column.

Note that, the memory cell array 101-8 may be applied to the memory cell array 101 of the first embodiment described above, or may be applied to the memory cell array 101 of the second embodiment described above.

In the memory cell array 101-8, a timing and a flow of writing into the magnetoresistive effect element 111 in a resistance state corresponding to a coefficient that is used for the MAC calculation may be set similarly to those in FIGS. 9 and 10, or may be set similarly to those in FIGS. 25 to 28. A calculation timing and a flow in MAC calculation can be set similarly to FIGS. 36 and 37.

In a case where the memory cell array 101-8 is applied to the memory cell array 101 according to the first embodiment described above, for writing into the magnetoresistive effect element 111 in a resistance state corresponding to the coefficient that is used for the MAC calculation, voltage waveforms similar to those in FIGS. 6 and 8 can be used.

In a case where the memory cell array 101-8 is applied to the memory cell array 101 according to the second embodiment described above, for writing into the magnetoresistive effect element 111 in a resistance state corresponding to the coefficient that is used for the MAC calculation, voltage waveforms similar to those in FIGS. 20 and 22 can be used.

As described above, in the above-described twelfth embodiment, the memory cell array 101-8 to be applied to the MAC calculation has a six-layer structure, and the word lines WL1 to WL6 and the bit lines BL1 to BL6 are individually provided for every layers of the memory cell array 101-8. As a result, it becomes possible to perform the MAC calculation on the basis of a value stored in the magnetoresistive effect elements 111 while multi-valuing the stored value at each cross point of the word lines WL1 to WL6 and the bit lines BL1 to BL6. Therefore, it is possible to improve calculation performance while suppressing an increase in a plane size of the MAC calculation device.

Note that, in the above-described fourth to twelfth embodiments, an example in which the memory cell array is applied to the MAC calculation has been described, but the memory cell array may be applied to calculations other than the MAC calculation.

Note that, in the fifth to twelfth embodiments described above, an example has been described in which the stacked structure of the memory cell array is applied to the processing device 500, but the stacked structure of the memory cell array may be applied to the storage devices 100 to 300 of the first to third embodiments described above.

### 13. Thirteenth Embodiment

In the above-described fourth embodiment, the memory cell MC provided with the magnetoresistive effect element 111 having the VCMA effect is applied to the MAC calculation. In this thirteenth embodiment, a memory cell MC provided with a magnetoresistive effect element 111 having a VCMA effect is applied to MAC calculation of a neural network.

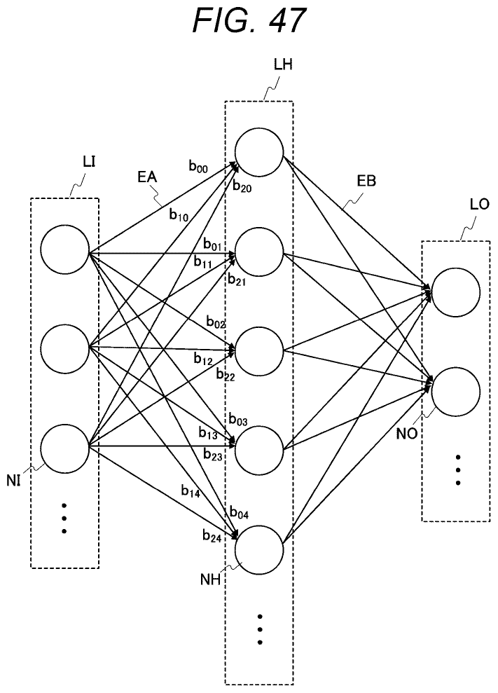

FIG. 47 is a diagram illustrating an example of a neural network to which a processing device according to the thirteenth embodiment is applied.

In this figure, the neural network includes an input layer LI, an intermediate layer LH, and an output layer LO. The input layer LI includes a node NI, the intermediate layer LH includes a node NH, and the output layer LO includes a node NO. The node NI is coupled to the node NH via an edge EA, and the node NH is coupled to the node NO via an edge EB.

In a learning stage of the neural network, a weight is set to each of the edges EA and EB of the neural network. For example, in each edge EA, weights b₀₀ to b₀₄, . . . , b₁₀ to b₁₄, . . . , b₂₀ to b₂₄, . . . are set for every pair of the node NI and the node NH. The weights b₀₀ to b₀₄, . . . , b₁₀ to b₁₄, . . . , b₂₀ to b₂₄, . . . can be set on the basis of a resistance state of the magnetoresistive effect element 111 at each cross point of the memory cell array 101.

In an inference stage of the neural network, data input to each node NI of the input layer LI is weighted by the weight of each edge EA and then input to each node NH of the intermediate layer LH, and inputs to each node NH are added for every node NH to become a value of each node NH. The value of each node NH of the intermediate layer LH is subjected to nonlinear conversion with an activation function (for example, a sigmoid function), weighted by the weight of each edge EB, and then input to each node NO of the output layer LO, and inputs to each node NO are added for every node NO to become a value of each node NO.

At this time, a DA-converted value Vᵢₙ⁽ⁱ⁾ (i=0, . . . , N−1) obtained by DA-conversion on input data Sᵢₙ⁽ⁱ⁾ (i=0, . . . , N−1) is input to the input layer LI. Then, as an output from the intermediate layer LH of the neural network, a MAC calculation result can be obtained using, as a weight, a resistance state of the magnetoresistive effect element 111 at each cross point of the memory cell array 101.

Note that, in the above-described thirteenth embodiment, an example has been described in which the MAC calculation using the memory cell array is applied to the neural network, but the MAC calculation using the memory cell array may be applied to a device other than the neural network. For example, the MAC calculation using the memory cell array may be applied to a graphics processing unit (GPU) or a digital signal processor (DSP).

### 14. First Application Example

The above-described embodiments may be applied to an imaging device. The imaging device may be applied to a digital still camera or a video camera, may be applied to an electronic device such as a smartphone or a mobile phone having an imaging function, or may be applied to an authentication device having an image sensor, a drone, or an electric vehicle (EV).

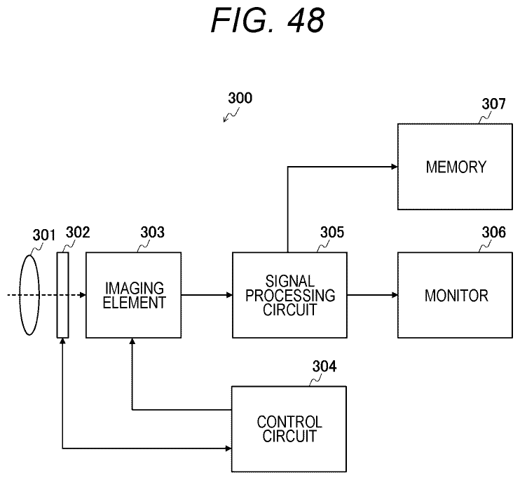

FIG. 48 is a block diagram illustrating an example of a schematic configuration of an imaging device.

In this figure, an imaging device 300 includes an optical system 301, a shutter device 302, an imaging element 303, a control circuit (drive circuit) 304, a signal processing circuit 305, a monitor 306, and a memory 307. The imaging device 300 can capture a still image and a moving image.

The optical system 301 includes one or a plurality of lenses. This optical system 301 guides light (incident light) from a subject to the imaging element 303, and forms an image on a light receiving surface of the imaging element 303.

The shutter device 302 is disposed between the optical system 301 and the imaging element 303. The shutter device 302 controls a light irradiation period and a light shielding period for the imaging element 303 under the control of the control circuit 304.

The imaging element 303 accumulates signal charges for a certain period in accordance with light formed on the light receiving surface via the optical system 301 and the shutter device 302. The signal charges accumulated in the imaging element 303 are transferred in response to a drive signal (timing signal) supplied from the control circuit 304.

The control circuit 304 outputs a drive signal to control a transfer operation of the imaging element 303 and a shutter operation of the shutter device 302, to drive the imaging element 303 and the shutter device 302.

The signal processing circuit 305 performs various types of signal processing on the signal output from the imaging element 303. An image (image data) obtained by performing the signal processing with the signal processing circuit 305 is supplied to the monitor 306 and the memory 307.

The monitor 306 displays a moving image or a still image captured by the imaging element 303, on the basis of the image data supplied from the signal processing circuit 305. As the monitor 306, for example, a panel type display device such as a liquid crystal panel or an organic electro luminescence (EL) panel is used.

The memory 307 stores the image data supplied from the signal processing circuit 305, that is, image data of a moving image or a still image captured by the imaging element 303. The memory 307 may include the storage device 100 or 200 of the above-described embodiments as a nonvolatile memory.

In the imaging device 300, by using the storage device 100 or 200 of the above-described embodiments as the memory 307, it is possible to achieve a large capacity and low power consumption while achieving cost reduction.

### 15. Second Application Example

The above-described embodiments may be applied to a distance measuring device. The distance measuring device may be a distance image sensor or a laser distance measuring device.

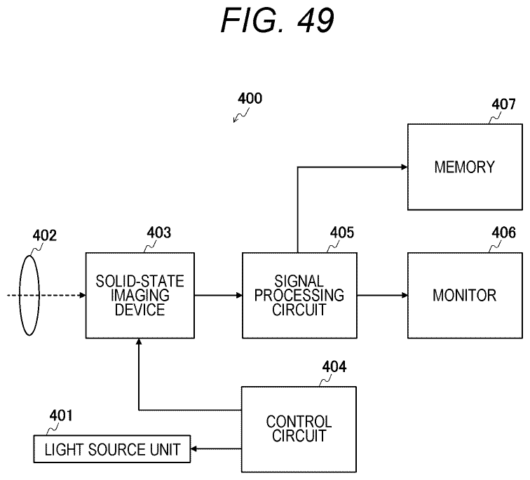

FIG. 49 is a block diagram illustrating an example of a schematic configuration of a distance measuring device.

In this figure, a distance measuring device 400 includes a light source unit 401, an optical system 402, a solid-state imaging device (imaging element) 403, a control circuit (drive circuit) 404, a signal processing circuit 405, a monitor 406, and a memory 407. The distance measuring device 400 can acquire a distance image according to a distance to a subject, by projecting light from the light source unit 401 toward the subject and receiving light (modulated light or pulsed light) reflected on a surface of the subject.

The light source unit 401 projects light toward the subject. As the light source unit 401, for example, a vertical cavity surface emitting laser (VCSEL) array which emits laser light as a surface light source or a laser diode array in which laser diodes are arranged on a line is used. Note that the laser diode array is supported by a predetermined drive unit (not illustrated), and is scanned in a direction perpendicular to an arrangement direction of the laser diodes.

The optical system 402 includes one or a plurality of lenses. This optical system 402 guides light (incident light) from a subject to the solid-state imaging device 403, and forms an image on a light receiving surface (sensor unit) of the solid-state imaging device 403.

The solid-state imaging device 403 accumulates signal charges in accordance with light formed on a light receiving surface via the optical system 402. A distance signal indicating a distance obtained from a light reception signal (APD OUT) output from this solid-state imaging device 403 is supplied to the signal processing circuit 405. As the solid-state imaging device 403, for example, a solid-state imaging element such as an image sensor is used.

The control circuit 404 outputs a drive signal (control signal) for controlling operations of the light source unit 401, the solid-state imaging device 403, and the like, to drive the light source unit 401, the solid-state imaging device 403, and the like.

The signal processing circuit 405 performs various types of signal processing on a distance signal supplied from the solid-state imaging device 403. For example, the signal processing circuit 405 performs image processing (for example, histogram processing, peak detection processing, and the like) of constructing a distance image on the basis of the distance signal. An image (image data) obtained by performing the signal processing with the signal processing circuit 405 is supplied to the monitor 406 and the memory 407.

The monitor 406 displays a distance image captured by the imaging element 303 on the basis of the image data supplied from the signal processing circuit 405. As the monitor 406, for example, a panel type display device such as a liquid crystal panel or an organic EL panel is used.

The memory 407 stores image data supplied from the signal processing circuit 405, that is, image data of a distance image captured by the imaging element 303. The memory 407 may include the storage device 100 or 200 of the above-described embodiment as a nonvolatile memory.

In the distance measuring device 400, by using the storage device 100 or 200 of the above-described embodiments as the memory 407, it is possible to achieve a large capacity and low power consumption while achieving cost reduction.

### 16. Third Application Example

The above-described embodiments may be applied to a game device. The game device may be a portable game device or a stationary game device. The game device may be a game dedicated device or an electronic device such as a smartphone or a personal computer in which a game application is installed.

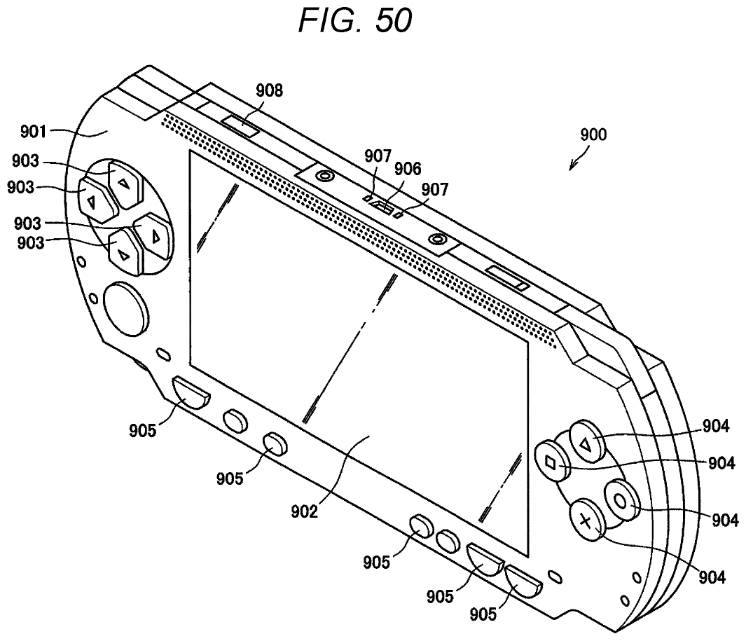

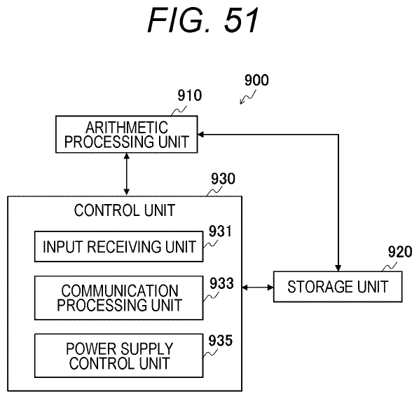

FIG. 50 is a perspective view illustrating an example of an external configuration of a game device, and FIG. 51 is a block diagram illustrating an example of a schematic configuration of the game device.

In FIG. 50, a game device 900 has an appearance in which each configuration is disposed inside and outside an outer casing 901 formed in a horizontally long flat shape, for example. At this time, a player can hold both ends of the outer casing 901 with both hands.

On a front surface of the outer casing 901, a display panel 902 is provided at a central portion in a longitudinal direction. Furthermore, operation keys 903 and 904 are provided on the left and right sides of the display panel 902 so as to be spaced apart from each other in a circumferential direction. Furthermore, operation keys 905 are provided at a lower end portion of the front surface of the outer casing 901. The operation keys 903, 904, and 905 function as a direction key, a determination key, and the like, and are used for selection of menu items displayed on the display panel 902, progress of a game, and the like.

On an upper surface of the outer casing 901, a connection terminal 906 for connection with an external device, a power supply terminal 907, a light receiving window 908 for infrared communication with the external device, and the like are provided.

In FIG. 51, the game device 900 includes an arithmetic processing unit 910 including a central processing unit (CPU), a storage unit 920 which stores various types of information, and a control unit 930 which controls each configuration of the game device 900. Power is supplied to the arithmetic processing unit 910 and the control unit 930 from, for example, a battery (not illustrated) or the like.

The arithmetic processing unit 910 generates a menu screen that allows a user to set various types of information or select an application. Furthermore, the arithmetic processing unit 910 executes the application selected by the user.

The storage unit 920 holds various types of information set by the user. The storage unit 920 may include the storage device 100 or 200 of the above-described embodiments as a nonvolatile memory.

The control unit 930 includes an input receiving unit 931, a communication processing unit 933, and a power supply control unit 935. The input receiving unit 931 detects a state of the operation keys 903, 904, and 905, for example. Furthermore, the communication processing unit 933 performs communication processing between with an external device. The power supply control unit 935 controls power supplied to each unit of the game device 900.

In the game device 900, by using the storage device 100 or 200 of the above-described embodiment as the storage unit 920, it is possible to achieve a large capacity and low power consumption while achieving cost reduction.

Note that the storage device 100 or 200 of the above-described embodiments may be mounted on the same semiconductor chip together with a semiconductor circuit included an arithmetic device or the like, to constitute a semiconductor device (System on a Chip).

Furthermore, the storage device 100 or 200 of the above-described embodiments can be mounted on various electronic devices on which a memory (storage unit) can be mounted as described above. For example, in addition to the imaging device 300 and the game device 900, the storage device 100 or 200 of the above-described embodiments may be mounted on various electronic devices such as a notebook personal computer (PC), a mobile device (for example, a smartphone, a tablet PC, or the like), a personal digital assistant (PDA), a wearable device, and a music device. For example, the storage device 100 or 200 of the above-described embodiments may be used as various memories such as a storage.

Note that the above-described embodiments show examples for embodying the present technology, and the matters in the embodiments and the matters specifying the invention in the claims have a corresponding relationship with each other. Similarly, the matters specifying the invention in the claims and the matters with the same names in the embodiments of the present technology have correspondence relationships. However, the present technology is not limited to the embodiments, and can be embodied by applying various modifications to the embodiments without departing from the scope of the present technology. Furthermore, effects described in the present specification are merely examples and are not limited, and other effects may be provided.

Note that the present technology may also have the following configuration.
(1) A storage device including:
a memory cell provided with a magnetoresistive effect element;
a word line connected to one end of the magnetoresistive effect element; and
a bit line connected to another end of the magnetoresistive effect element.
(2) The storage device according to (1) above, in which
the magnetoresistive effect element has a voltage controlled magnetic anisotropy (VCMA) effect.
(3) The storage device according to (2) above, in which
the VCMA effect is nonlinear.
(4) The storage device according to (3) above, in which
the VCMA effect has a region having a smaller inclination at a point where a cell voltage applied to the magnetoresistive effect element is low than an inclination at a point where the cell voltage is high.
(5) The storage device according to any one of (1) to (4) above, further including:
a driver configured to apply a reversing voltage for reversing a magnetization direction of the magnetoresistive effect element on the basis of the VCMA effect.
(6) The storage device according to (5) above, in which
the driver switches a voltage applied to the memory cell such that a reversing voltage is applied to a selected cell while a non-reversing voltage is applied to a non-selected cell, in which the non-reversing voltage does not reverse a magnetization direction of the magnetoresistive effect element.
(7) The storage device according to any one of (1) to (6) above, further including:
a resistance control circuit configured to control resistance between the word line and the bit line such that cell voltages applied to the magnetoresistive effect element are equal to each other between when the magnetoresistive effect element transitions from a high resistance state to a low resistance state and when the magnetoresistive effect element transitions from a low resistance state to a high resistance state.
(8) The storage device according to (7) above, in which
the resistance control circuit includes a field effect transistor whose ON-resistance changes on the basis of a gate voltage.
(9) The storage device according to (8) above, in which
the field effect transistor is provided for each of the word line.
(10) The storage device according to (8) above, in which
the field effect transistor is provided for each of the bit line.
(11) The storage device according to any one of (8) to (10) above, further including:
a gate voltage switching unit configured to switch between a first gate voltage and a second gate voltage, the first gate voltage being applied to the field effect transistor in a case where the magnetoresistive effect element is subjected to low-resistance writing, the second gate voltage being applied to the field effect transistor in a case where the magnetoresistive effect element is subjected to high-resistance writing.
(12) The storage device according to (5) above, in which
the driver includes:
a word line driver configured to apply a word line voltage of X/(X+Y) of a write voltage applied between the word line and the bit line to the word line connected to a selected cell, in which X and Y are values that do not cause reversal of a magnetization direction of the magnetoresistive effect element; and
a bit line driver configured to apply a bit line voltage having a polarity opposite to the word line voltage and being Y/(X+Y) of the write voltage, to the bit line connected to the selected cell.
(13) The storage device according to (12) above, in which
the word line driver applies a word line voltage of ½ of the write voltage to the word line connected to a selected cell, and
the bit line driver applies a bit line voltage having a polarity opposite to the word line voltage and being ½ of the write voltage, to the bit line connected to the selected cell.
(14) The storage device according to (12) or (13) above, further including:
a control circuit configured to control an application timing of the word line voltage applied to the word line connected to the selected cell and an application timing of the bit line voltage applied to the bit line connected to the selected cell, to at least partially overlap with each other.
(15) The storage device according to (14) above, in which
in a case where the magnetoresistive effect element is subjected to low-resistance writing,
the gate voltage switching unit applies the first gate voltage to the field effect transistor,
the word line driver applies a word line voltage of ½ of the write voltage to the word line connected to the selected cell, and
the bit line driver applies a bit line voltage having a polarity opposite to the word line voltage and being ½ of the write voltage, to the bit line connected to the selected cell.
(16) The storage device according to (14) above, in which
in a case where the magnetoresistive effect element is subjected to high-resistance writing,
the gate voltage switching unit applies the second gate voltage to the field effect transistor,
the word line driver applies a word line voltage of ½ of the write voltage to the word line connected to the selected cell, and
the bit line driver applies a bit line voltage having a polarity opposite to the word line voltage and being ½ of the write voltage, to the bit line connected to the selected cell.
(17) The storage device according to (14) above, further including:
a readout circuit configured to detect data stored in the selected cell on the basis of a current flowing through the bit line connected with the selected cell.
(18) The storage device according to (17) above, in which
in a case of reading data from the selected cell,
the gate voltage switching unit applies the first gate voltage to the field effect transistor,
the word line driver applies a word line voltage of ½ of the write voltage to the word line connected to the selected cell,
the bit line driver applies a bit line voltage having a polarity opposite to the word line voltage and being ½ of the write voltage, to the bit line connected to the selected cell, and
the readout circuit measures a change in a current flowing through the bit line connected with the selected cell,
determines that data read from the selected cell is 0 in a case where the current flowing through the bit line does not change, and
determines that data read from the selected cell is 1 in a case where the current flowing through the bit line increases, and
in a case where the data read from the selected cell is determined to be 1,
the gate voltage switching unit applies the second gate voltage to the field effect transistor,
the word line driver applies a word line voltage of ½ of the write voltage to the word line connected to the selected cell, and
the bit line driver applies a bit line voltage having a polarity opposite to the word line voltage and being ½ of the write voltage, to the bit line connected to the selected cell.
(19) The storage device according to any one of (1) to (18) above, further including:
a stacked structure of a memory cell array in which the memory cells are arranged in a matrix in a row direction and a column direction.
(20) The storage device according to (19) above, in which
the word line and the bit line are provided for every layer of the memory cell array.
(21) The storage device according to (19) above, in which
the word line and the bit line are alternately provided for every layer of the memory cell array.
(22) A processing device including:
a memory cell in which a magnetoresistive effect element having a VCMA effect is provided, and a resistive state is transitioned on the basis of voltage application in which cell voltages are substantially equal in the resistance states different from each other;
a word line connected to one end of the magnetoresistive effect element;
a bit line connected to another end of the magnetoresistive effect element; and
a processing unit configured to perform processing on the basis of a value stored in the memory cell.
(23) The processing device according to (22) above, in which
the processing unit includes an analog to digital (AD) converter configured to convert, into a digital value, a current flowing through the bit line via a memory cell selected via the word line.
(24) The processing device according to (23) above, in which
the AD converter converts, into a digital value, a total value of a current flowing through the bit line via each of a plurality of layers of memory cells selected via the word line.
(25) The processing device according to (23) or (24) above, in which
each of the memory cells stores a weight between nodes of a neural network, and
the memory cell array performs multiplication and accumulation (MAC) on the basis of an input of the neural network and the weight.
(26) The processing device according to any one of (22) to (25) above, further including:
a memory cell array in which the memory cells are arranged in a matrix in a row direction and a column direction, in which
the memory cell array is stacked.
(27) The processing device according to (26) above, in which
the word line and the bit line are provided for every layer of the memory cell array.
(28) The processing device according to (26) above, in which
the word line and the bit line are alternately provided for every layer of the memory cell array.

### REFERENCE SIGNS LIST

100, 200 Storage device
101 Memory cell array
111 Magnetoresistive effect element
102 Word line resistance control circuit
112 PMOS transistor
MC Memory cell
BL Bit line
WL Word line
103, 106 Gate voltage switching unit
104 Word line driver
114, 117 Voltage selector switch
113 Resistance state control switch
105 Bit line conduction circuit
115 NMOS transistor
116 Conduction state control switch
107 Bit line driver
108 Column selector
118 Column switch
109 Readout circuit

1. A storage device comprising:
a memory cell provided with a magnetoresistive effect element;
a word line connected to one end of the magnetoresistive effect element; and
a bit line connected to another end of the magnetoresistive effect element.

2. The storage device according to claim 1, wherein
the magnetoresistive effect element has a voltage controlled magnetic anisotropy (VCMA) effect.

3. The storage device according to claim 2, wherein
the VCMA effect is nonlinear.

4. The storage device according to claim 3, wherein
the VCMA effect has a region having a smaller inclination at a point where a cell voltage applied to the magnetoresistive effect element is low than an inclination at a point where the cell voltage is high.

5. The storage device according to claim 1, further comprising:
a driver configured to apply a reversing voltage for reversing a magnetization direction of the magnetoresistive effect element on a basis of the VCMA effect.

6. The storage device according to claim 5, wherein
the driver switches a voltage applied to the memory cell such that a reversing voltage is applied to a selected cell while a non-reversing voltage is applied to a non-selected cell, wherein the non-reversing voltage does not reverse a magnetization direction of the magnetoresistive effect element.

7. The storage device according to claim 6, further comprising:
a resistance control circuit configured to control resistance between the word line and the bit line such that cell voltages applied to the magnetoresistive effect element are equal to each other between when the magnetoresistive effect element transitions from a high resistance state to a low resistance state and when the magnetoresistive effect element transitions from a low resistance state to a high resistance state.

8. The storage device according to claim 7, wherein
the resistance control circuit includes a field effect transistor whose ON-resistance changes on a basis of a gate voltage.

9. The storage device according to claim 8, wherein
the field effect transistor is provided for each of the word line.

10. The storage device according to claim 8, wherein
the field effect transistor is provided for each of the bit line.

11. The storage device according to claim 8, further comprising:
a gate voltage switching unit configured to switch between a first gate voltage and a second gate voltage, the first gate voltage being applied to the field effect transistor in a case where the magnetoresistive effect element is subjected to low-resistance writing, the second gate voltage being applied to the field effect transistor in a case where the magnetoresistive effect element is subjected to high-resistance writing.

12. The storage device according to claim 11, wherein
the driver includes:
a word line driver configured to apply a word line voltage of X/(X+Y) of a write voltage applied between the word line and the bit line to the word line connected to a selected cell, wherein X and Y are values that do not cause reversal of a magnetization direction of the magnetoresistive effect element; and
a bit line driver configured to apply a bit line voltage having a polarity opposite to the word line voltage and being Y/(X+Y) of the write voltage, to the bit line connected to the selected cell.

13. The storage device according to claim 12, wherein
the word line driver applies a word line voltage of ½ of the write voltage to the word line connected to a selected cell, and
the bit line driver applies a bit line voltage having a polarity opposite to the word line voltage and being ½ of the write voltage, to the bit line connected to the selected cell.

14. The storage device according to claim 12, further comprising:
a control circuit configured to control an application timing of the word line voltage applied to the word line connected to the selected cell and an application timing of the bit line voltage applied to the bit line connected to the selected cell, to at least partially overlap with each other.

15. The storage device according to claim 14, wherein
in a case where the magnetoresistive effect element is subjected to low-resistance writing,
the gate voltage switching unit applies the first gate voltage to the field effect transistor,
the word line driver applies a word line voltage of ½ of the write voltage to the word line connected to the selected cell, and
the bit line driver applies a bit line voltage having a polarity opposite to the word line voltage and being ½ of the write voltage, to the bit line connected to the selected cell.

16. The storage device according to claim 14, wherein
in a case where the magnetoresistive effect element is subjected to high-resistance writing,
the gate voltage switching unit applies the second gate voltage to the field effect transistor,
the word line driver applies a word line voltage of ½ of the write voltage to the word line connected to the selected cell, and
the bit line driver applies a bit line voltage having a polarity opposite to the word line voltage and being ½ of the write voltage, to the bit line connected to the selected cell.

17. The storage device according to claim 14, further comprising:
a readout circuit configured to detect data stored in the selected cell on a basis of a current flowing through the bit line connected with the selected cell.

18. The storage device according to claim 17, wherein
in a case of reading data from the selected cell,
the gate voltage switching unit applies the first gate voltage to the field effect transistor,
the word line driver applies a word line voltage of ½ of the write voltage to the word line connected to the selected cell,
the bit line driver applies a bit line voltage having a polarity opposite to the word line voltage and being ½ of the write voltage, to the bit line connected to the selected cell, and
the readout circuit measures a change in a current flowing through the bit line connected with the selected cell,
determines that data read from the selected cell is 0 in a case where the current flowing through the bit line does not change, and
determines that data read from the selected cell is 1 in a case where the current flowing through the bit line increases, and
in a case where the data read from the selected cell is determined to be 1,
the gate voltage switching unit applies the second gate voltage to the field effect transistor,
the word line driver applies a word line voltage of ½ of the write voltage to the word line connected to the selected cell, and
the bit line driver applies a bit line voltage having a polarity opposite to the word line voltage and being ½ of the write voltage, to the bit line connected to the selected cell.

19. The storage device according to claim 1, further comprising:
a stacked structure of a memory cell array in which the memory cells are arranged in a matrix in a row direction and a column direction.

20. The storage device according to claim 1, wherein
the word line and the bit line are provided for every layer of the memory cell array.

21. The storage device according to claim 1, wherein
the word line and the bit line are alternately provided for every layer of the memory cell array.

22. A processing device comprising:
a memory cell in which a magnetoresistive effect element having a VCMA effect is provided, and a resistive state is transitioned on a basis of voltage application in which cell voltages are substantially equal in the resistance states different from each other;
a word line connected to one end of the magnetoresistive effect element;
a bit line connected to another end of the magnetoresistive effect element; and
a processing unit configured to perform processing on a basis of a value stored in the memory cell.

23. The processing device according to claim 22, wherein
the processing unit includes an analog to digital (AD) converter configured to convert, into a digital value, a current flowing through the bit line via a memory cell selected via the word line.

24. The processing device according to claim 23, wherein
the AD converter converts, into a digital value, a total value of a current flowing through the bit line via each of a plurality of layers of memory cells selected via the word line.

25. The processing device according to claim 23, wherein
the memory cell stores a weight between nodes of a neural network, and
the memory cell array performs multiplication and accumulation (MAC) on a basis of an input of the neural network and the weight.

26. The processing device according to claim 22, further comprising:
a memory cell array in which the memory cells are arranged in a matrix in a row direction and a column direction, wherein
the memory cell array is stacked.

27. The processing device according to claim 26, wherein
the word line and the bit line are provided for every layer of the memory cell array.

28. The processing device according to claim 26, wherein
the word line and the bit line are alternately provided for every layer of the memory cell array.
